(19) United States
(12) Patent Application Publication
(10) Pub. No.: US 2024/0329529 A1
(43) Pub. Date: Oct. 3, 2024

(54) RESIST COMPOSITION AND PATTERN FORMING PROCESS

(71) Applicant: Shin-Etsu Chemical Co., Ltd., Tokyo (JP)

(72) Inventor: Jun Hatakeyama, Joetsu-shi (JP)

(73) Assignee: Shin-Etsu Chemical Co., Ltd., Tokyo (JP)

(21) Appl. No.: 18/602,587

(22) Filed: Mar. 12, 2024

(30) Foreign Application Priority Data
Mar. 23, 2023 (JP) 2023-046978
Oct. 6, 2023 (JP) 2023-174063

(51) Int. Cl. G03F 7/038; G03F 7/004; G03F 7/20; G03F 7/32

(52) U.S. Cl. CPC G03F 7/0387; G03F 7/0045; G03F 7/0048; G03F 7/0382; G03F 7/2006; G03F 7/325

(57) ABSTRACT

The resist composition exhibits a higher resolution and smaller edge roughness than those of a conventional organic solvent development type negative resist composition. Provided is a resist composition comprising a base polymer containing a polymer including a repeat unit having a carboxy group substituted with an acid labile group and a repeat unit having a maleimide group in a side chain.

### CROSS-REFERENCE TO RELATED APPLICATIONS

This non-provisional application claims priority under 35 U.S.C. § 119(a) on Patent Application Nos. 2023-046978 and 2023-174063 filed in Japan on Mar. 23, 2023 and Oct. 6, 2023, respectively, the entire contents of which are hereby incorporated by reference.

### TECHNICAL FIELD

The present invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using extreme ultraviolet (EUV) having a wavelength of 13.5 nm has been implemented in a mass scale. Studies are made on the application of EUV lithography to 3-nm node devices of the next generation and 2-nm node devices of the next-but-one generation.

A negative tone pattern forming process by organic solvent development has been studied (Non-Patent Document 1). A first chemically amplified resist composition in which an acid generator is added to polystyrene substituted with a tert-butoxycarbonyl group forms a negative tone pattern with an organic solvent by anisole, and using this pattern, 1 M-DRAM by exposure using KrF excimer laser light has been produced by IBM.

Thereafter, for a long time, in patterning using a resist composition for KrF lithography or a resist composition for ArF lithography, a positive tone pattern has been formed with an alkaline developer. This is because an alkaline developer is cheaper than a developer of an organic solvent, and a positive tone resist pattern can be stably formed by a filter that adsorbs a base substance to prevent generation of a surface poorly soluble layer due to deactivation of an acid catalyst, which has been a problem in formation of a positive tone resist pattern.

In DUV exposure using interference, finer holes can be formed in a negative tone pattern. Double patterning for resolving a pitch finer than an exposure wavelength has been performed, and a negative pattern formation by organic solvent development has attracted attention again (Patent Document 1).

In EUV have a wavelength shorter than DUV by on digit or more, a negative tone pattern not have a higher contrast in an optical image. However, organic solvent development has an advantage of having fewer development defects due to the characteristic of low swelling, and there is a demand for forming a dark pattern with fewer mask defects when an isolated left pattern is formed, so that organic solvent development has attracted attention even in EUV exposure.

As compared with the alkali development, the organic solvent development has a problem in that the dissolution contrast of a resist film is low and the resolution is poor. In order to increase the dissolution contrast of a resist film in organic solvent development, a resist composition containing, as a base polymer, a polymer including a repeat unit having oxirane or oxetane in which crosslinking reaction proceeds by an acid in addition to a repeat unit having an acid labile group, has been proposed (Patent Document 2).

If not only deprotection reaction by acid catalytic reaction but also crosslinking reaction proceeds, the acid diffusion distance becomes long, and image blurs occur due to the extension of the diffusion length. It is necessary to develop an organic solvent development-type negative resist composition having low acid diffusion and a high dissolution contrast.

It is known that maleimide groups are dimerized by light irradiation (Non-Patent Document 2). In a monomer that generates a radical and has a maleimide group and an acrylic group in the same molecule, not only dimerization coupling between maleimide groups but also an acrylic moiety is polymerized by the radical generated by itself. A non-chemically amplified resist composition containing a crosslinkable polymer having a maleimide group in a side chain has been proposed (Patent Document 3).

### CITATION LIST

Patent Document 1: JP-A 2008-281974
Patent Document 2: JP 5772717
Patent Document 3: JP-A 2017-49374
Non-Patent Document 1: VLSI. Technol. Symp. p86-87 (1982)
Non-Patent Document 2: Toagosei Research Annual, 2002, No. 5, p11

### SUMMARY OF THE INVENTION

It is an object of the present invention to provide a resist composition which exhibits a higher resolution and smaller edge roughness than those of a conventional organic solvent development type negative resist composition, and a pattern forming process using the same.

The present inventors have conducted intensive studies for obtaining a negative tone pattern having high resolution and reduced edge roughness, which has been demanded in an organic solvent in recent years, and as a result, have found that it is extremely effective to use a polymer including a specific repeat unit as a base polymer of a resist composition.

The present inventors have further conducted intensive studies for suppressing acid diffusion to improve dissolution contrast in an organic solvent developer and reducing edge roughness, and as a result, have found that by using a polymer including a repeat unit containing a carboxy group substituted with an acid labile group for polarity change and a repeat unit having a maleimide group in a side chain as a base polymer of a resist composition, a negative tone resist pattern, which has a high dissolution rate contrast in organic solvent development, a high effect of suppressing acid diffusion, high resolution, and good pattern profile and edge roughness after exposure, can be obtained, thereby completing the present invention.

That is, the present invention provides the following resist composition and pattern forming process.
1. A resist composition comprising a base polymer containing a polymer including a repeat unit having a carboxy group substituted with an acid labile group and a repeat unit having a maleimide group in a side chain.
2. The resist composition according to 1, wherein the repeat unit having the carboxy group substituted with the acid labile group has the following formula (a1), and the repeat unit having the maleimide group in the side chain has the following formula (b):

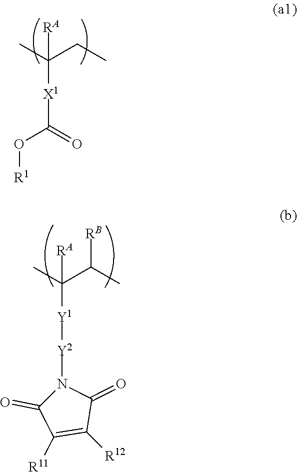

wherein R^{A} is each independently a hydrogen atom or a methyl group,
R^{B} is a hydrogen atom or a group that bonds together with Y¹ to form a C₈-C₁₄ ring with the carbon atom to which they are attached,
X¹ is a single bond, a phenylene group, a naphthylene group, or a C₁-C₁₆ linking group which contains at least one selected from an ester bond, an ether bond, and a lactone ring, the phenylene group, the naphthylene group, and the linking group may have at least one selected from a hydroxy group, a C₁-C₈ saturated hydrocarbyloxy group, and a C₂-C₈ saturated hydrocarbylcarbonyloxy group,
Y¹ is a single bond, a phenylene group, a naphthylene group, an ester bond, or an ether bond,
Y² is a single bond or a C₁-C₁₂ saturated hydrocarbylene group, the saturated hydrocarbylene group may have at least one selected from an ester bond, an amide bond, an ether bond, a lactone ring, and a urethane bond,
R¹ is an acid labile group,
R¹¹ and R¹² are each independently a hydrogen atom or a C₁-C₁₀ saturated hydrocarbyl group, the saturated hydrocarbyl group may contain an ether bond or a sulfide bond, and R¹¹ and R¹² may bond together to form a ring with the carbon atom to which they are attached.
3. The resist composition according to 1 or 2, further comprising an organic solvent.
4. The resist composition according to any one of 1 to 3, further comprising an acid generator.
5. The resist composition according to any one of 1 to 4, further comprising a quencher.
6. The resist composition according to any one of 1 to 5, further comprising a surfactant.
7. A pattern forming process comprising the steps of: applying the resist composition according to any one of 1 to 6 onto a substrate to form a resist film on the substrate; exposing the resist film to high-energy radiation; and developing the exposed resist film in an organic solvent developer.
8. The pattern forming process according to 7, wherein the organic solvent developer comprises one or more selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate.
9. The pattern forming process according to 7 or 8, wherein the substrate is a photomask blank.
10. The pattern forming process according to any one of 7 to 9, wherein the high-energy radiation is i-rays, ArF excimer laser light having a wavelength of 193 nm, KrF excimer laser light having a wavelength of 248 nm, EB, or EUV having a wavelength of 3 to 15 nm.

### Advantageous Effects of the Invention

A negative resist composition for organic solvent development of the present invention has a high dissolution contrast before and after exposure when a resist film is formed, a high resolution, a high effect of suppressing acid diffusion, a good pattern profile after exposure, a high effect of improving edge roughness and dimensional uniformity, exposure latitude, and excellent process adaptability. Therefore, the resist composition is particularly suitable as a micropatterning material for the fabrication of VLSIs or photomasks, or a patterning material for EUV exposure or ArF excimer laser exposure. The resist composition of the present invention can be applied not only to lithography for forming semiconductor circuits, but also to formation of mask circuit patterns, micromachines, thin-film magnetic head circuits, and the like.

### DETAILED DESCRIPTION OF THE INVENTION

### [Resist Composition]

A resist composition of the present invention comprises a base polymer containing a polymer (also referred to as the polymer A, hereinafter) including a repeat unit having a carboxy group substituted with an acid labile group (also referred to as the repeat unit a1, hereinafter) and a repeat unit having a maleimide group in a side chain (also referred to as the repeat unit b, hereinafter).

The repeat unit a1 preferably has the following formula (a1).

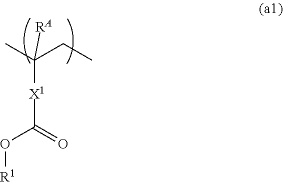

In formula (a1), R^{A} is each independently a hydrogen atom or a methyl group.

In formula (a1), X¹ is a single bond, a phenylene group, a naphthylene group, or a C₁-C₁₆ linking group which contains at least one selected from an ester bond, an ether bond, and a lactone ring, the phenylene group, the naphthylene group, and the linking group may have at least one selected from a hydroxy group, a C₁-C₈ saturated hydrocarbyloxy group, and a C₂-C₈ saturated hydrocarbylcarbonyloxy group.

In formula (a1), R¹ is an acid labile group.

Examples of the monomer from which repeat units a1 are derived are shown below, but not limited thereto. In the following formula, R^{A} and R¹ are as defined above.

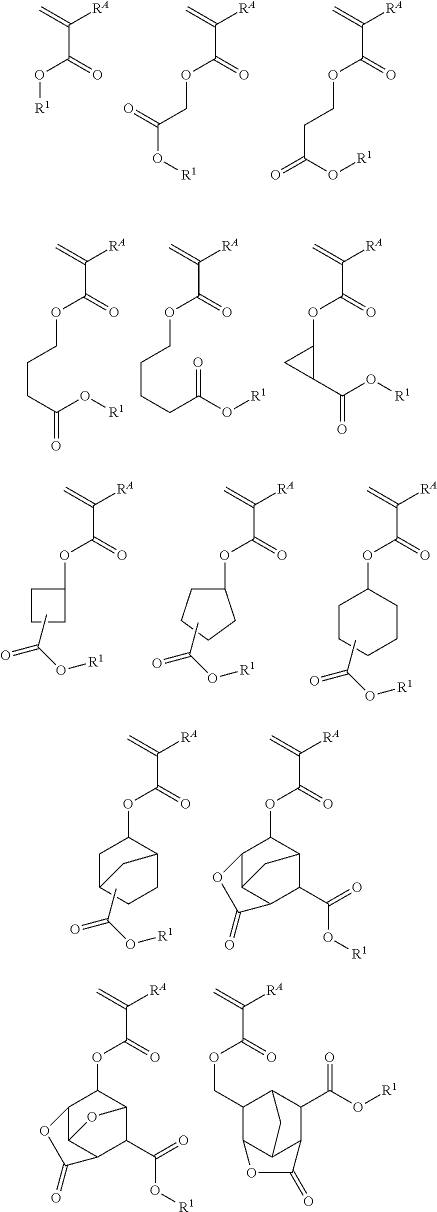

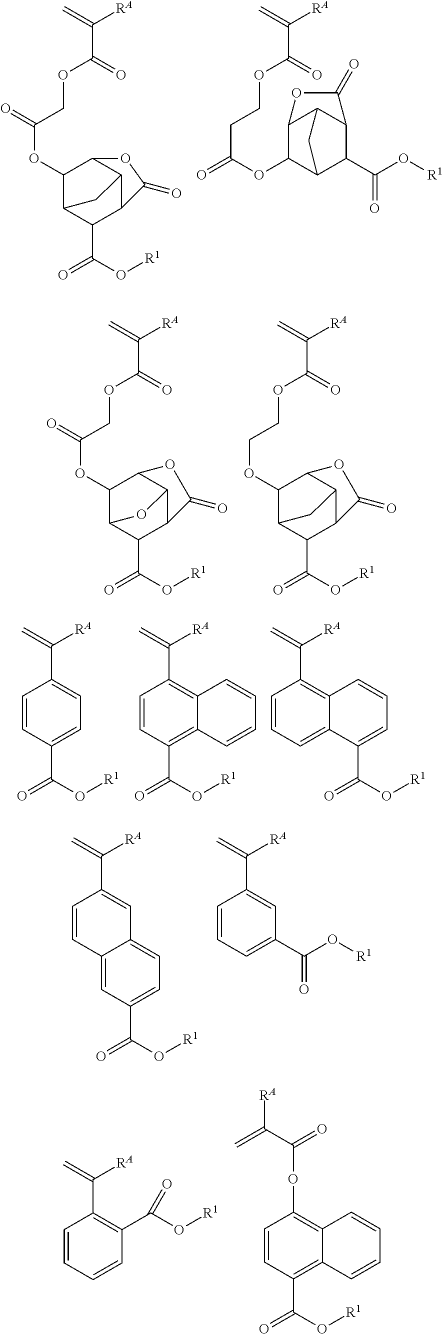

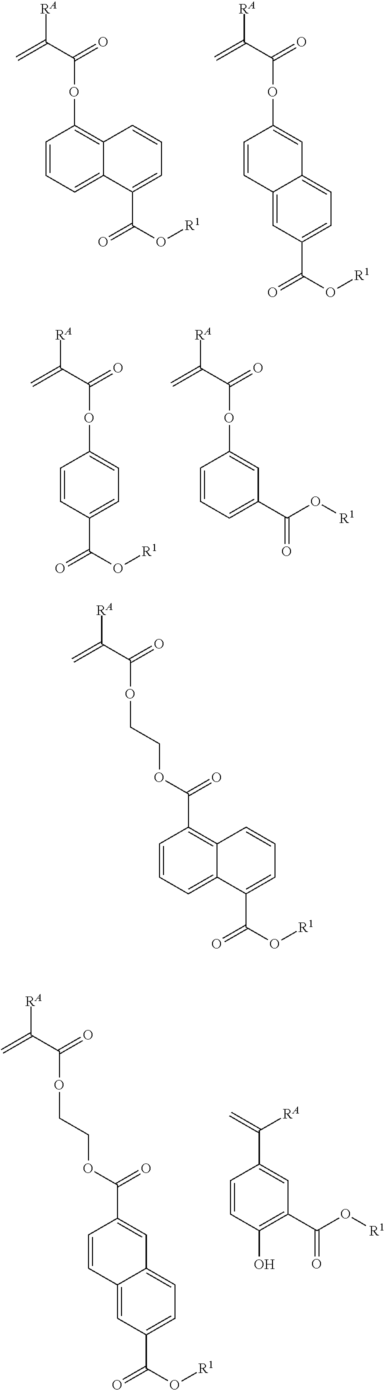

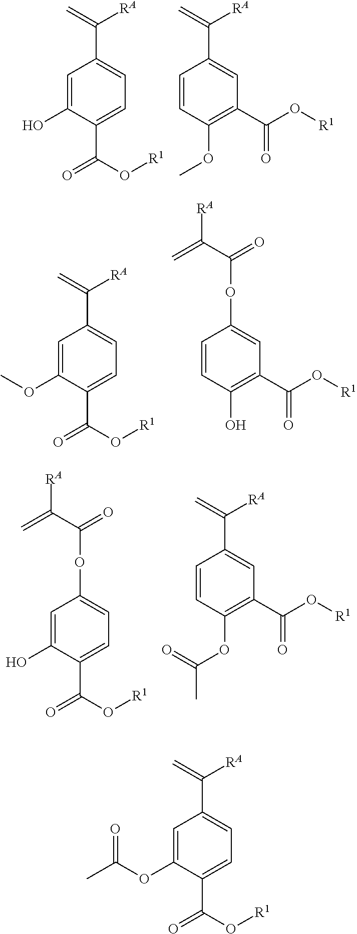

The polymer A may further include repeat units a2 having a hydroxy group substituted with an acid labile group.

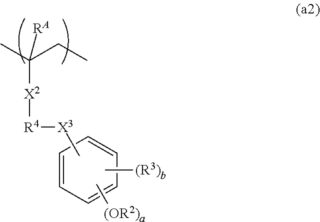

In formula (a2), R^{A} is each independently a hydrogen atom or a methyl group. X² is a single bond, an ester bond, or an amide bond. X³ is a single bond, an ether bond, or an ester bond. R² is an acid labile group. R³ is a fluorine atom, a trifluoromethyl group, a cyano group, or a C₁-C₆ saturated hydrocarbyl group. R⁴ is a single bond or a C₁-C₆ alkanediyl group, and the alkanediyl group may contain an ether bond or an ester bond. a is 1 or 2. b is an integer of 0 to 4. Provided that 1≤a+b≤5.

Examples of the monomer from which repeat units a2 are derived are shown below, but not limited thereto. In the following formula, R^{A} and R¹² are as defined above.

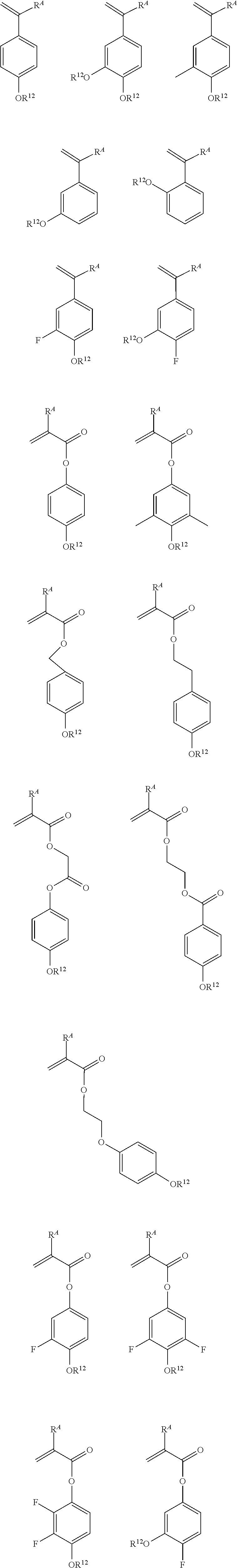

The acid labile group represented by R¹ and R² may be selected from a variety of such groups, for example, groups having the following formulae (AL-1) to (AL-3):

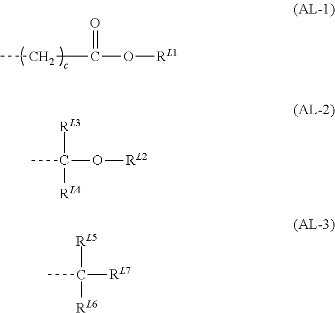

wherein the broken line denotes a point of attachment.

In formula (AL-1), c is an integer of 0 to 6. R^{L1} is C₄₋₂₀, preferably C₄-C₁₅ tertiary hydrocarbyl group, a trihydrocarbylsilyl group in which each hydrocarbyl group is a C₁-C₆ saturated hydrocarbyl group, a C₄-C₂₀ saturated hydrocarbyl group containing a carbonyl group, an ether bond, or an ester bond, or a group having formula (AL-3). The tertiary hydrocarbyl group refers to a group obtained by eliminating a hydrogen atom on a tertiary carbon atom from a hydrocarbon.

The tertiary hydrocarbyl group represented by R^{L1} may be Saturated or unsaturated and branched or cyclic. Specific examples thereof include a tert-butyl group, a tert-pentyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, and a 2-methyl-2-adamantyl group. Examples of the trihydrocarbylsilyl group include a trimethylsilyl group, a triethylsilyl group, and a dimethyl-tert-butylsilyl group. The saturated hydrocarbyl group containing a carbonyl group, an ether bond, or an ester bond may be straight, branched, or cyclic, but is preferably cyclic, and specific examples thereof include a 3-oxocyclohexyl group, a 4-methyl-2-oxooxan-4-yl group, a 5-methyl-2-oxooxolan-5-yl group, a 2-tetrahydropyranyl group, and a 2-tetrahydrofuranyl group.

Examples of the acid labile group having formula (AL-1) include a tert-butoxycarbonyl group, a tert-butoxycarbonylmethyl group, a tert-pentyloxycarbonyl group, a tert-pentyloxycarbonylmethyl group, a 1,1-diethylpropyloxycarbonyl group, a 1,1-diethylpropyloxycarbonylmethyl group, a 1-ethylcyclopentyloxycarbonyl group, a 1-ethylcyclopentyloxycarbonylmethyl group, a 1-ethyl-2-cyclopentenyloxycarbonyl group, a 1-ethyl-2-cyclopentenyloxycarbonylmethyl group, a 1-ethoxyethoxycarbonylmethyl group, a 2-tetrahydropyranyloxycarbonylmethyl group, and a 2-tetrahydrofuranyloxycarbonylmethyl group.

Examples of the acid labile group having formula (AL-1) further include groups having the following formulae (AL-1)-1 to (AL-1)-10.

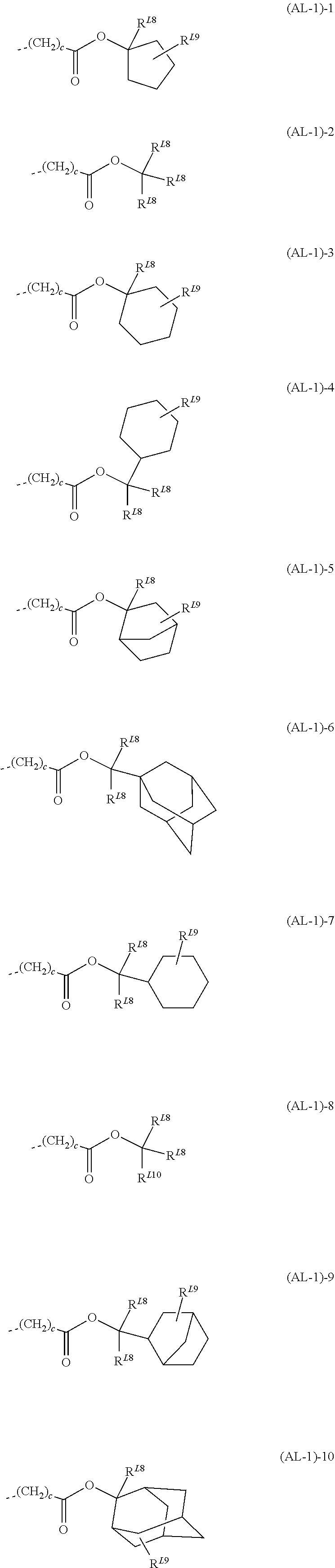

wherein the broken line denotes a point of attachment.

In formulae (AL-1)-1 to (AL-1)-10, c is as defined above. R^{L8} is each independently a C₁-C₁₀ saturated hydrocarbyl group or a C₆-C₂₀ aryl group. R^{L9} is a hydrogen atom or a C₁-C₁₀ saturated hydrocarbyl group. R^{L10} is a C₂-C₁₀ saturated hydrocarbyl group or a C₆-C₂₀ aryl group. The saturated hydrocarbyl group may be straight, branched, or cyclic.

In formula (AL-2), R^{L2} and R^{L3} are each independently a hydrogen atom or a C₁-C₁₈, preferably C₁-C₁₀ saturated hydrocarbyl group. The saturated hydrocarbyl group may be straight, branched, or cyclic, and specific examples thereof include a methyl group, an ethyl group, a n-propyl group, an isopropyl group, a n-butyl group, an isobutyl group, a sec-butyl group, a tert-butyl group, a cyclopentyl group, a cyclohexyl group, a 2-ethylhexyl group, and a n-octyl group.

In formula (AL-2), RN is a C₁-C₁₈, preferably C₁-C₁₀ hydrocarbyl group which may contain a heteroatom. The hydrocarbyl group may be saturated or unsaturated and straight, branched, or cyclic. Examples of the hydrocarbyl group include a C₁-C₁₈ saturated hydrocarbyl group, in which some of the hydrogen atoms may be substituted with a hydroxy group, an alkoxy group, an oxo group, an amino group, an alkylamino group, or the like. Examples of such a substituted saturated hydrocarbyl group are shown below.

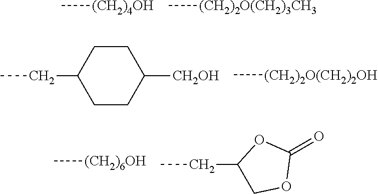

wherein the broken line denotes a point of attachment.

A pair of R^{L2} and R^{L3}, R^{L2} and RN, or R^{L3} and RN may bond together to form a ring with the carbon atom or carbon and oxygen atoms to which they are attached, and in this case, R^{L2} and R^{L3}, R^{L2} and RN, or R^{L3} and RN which form a ring are each independently a C₁-C₁₈, preferably C₁-C₁₀ alkanediyl group. The number of carbon atoms of the ring thus formed is preferably 3 to 10 and more preferably 4 to 10.

Of the acid labile groups having formula (AL-2), examples of straight or branched groups include those having the following formulae (AL-2)-1 to (AL-2)-69, but are not limited thereto. In the following formula, the broken line denotes a point of attachment.

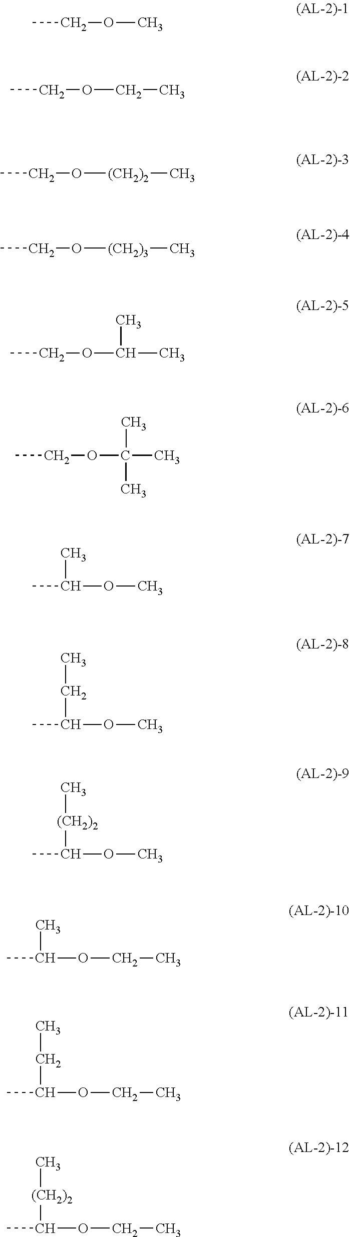

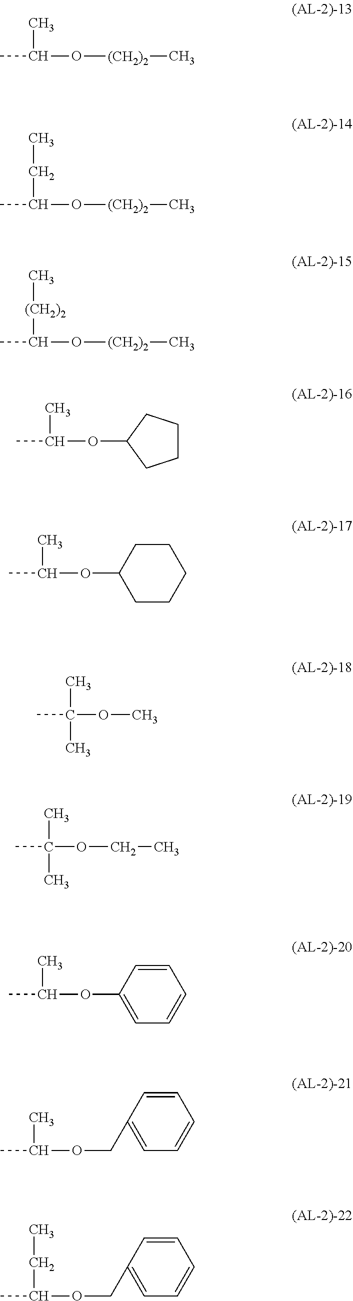

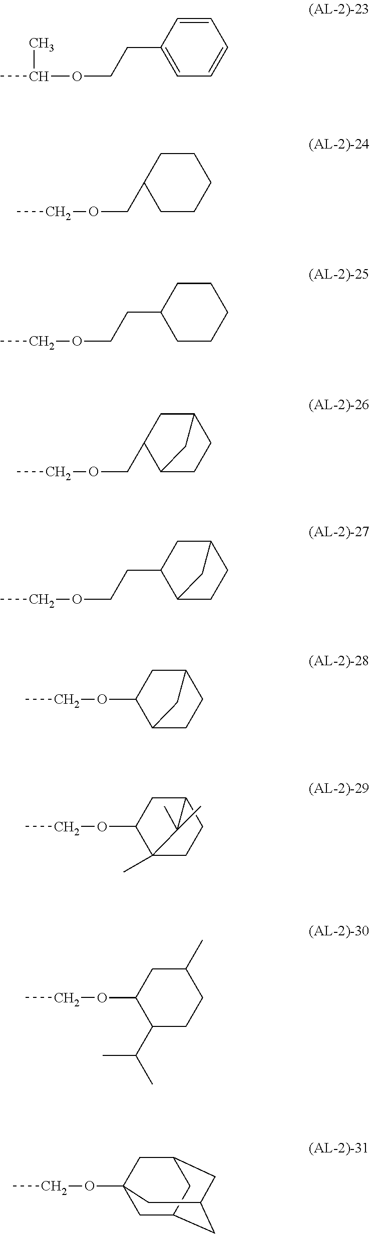

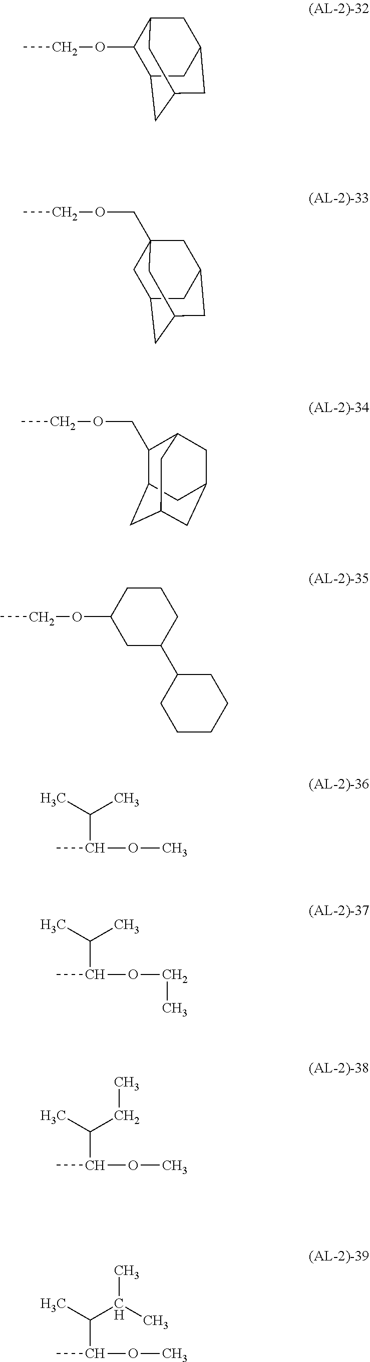

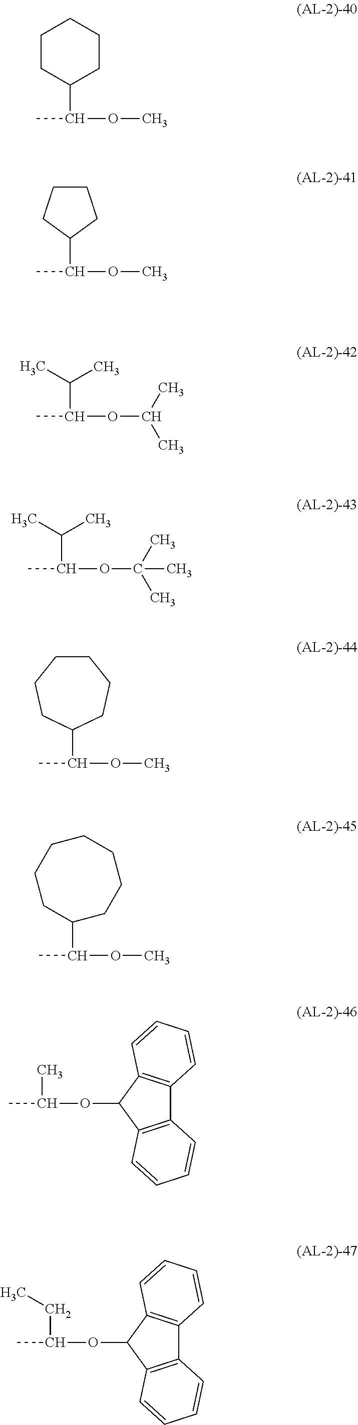

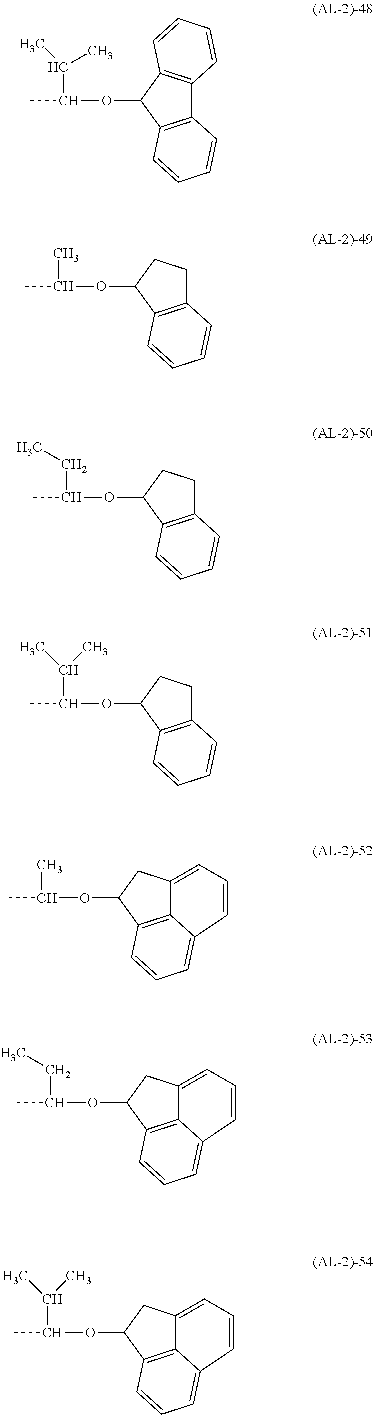

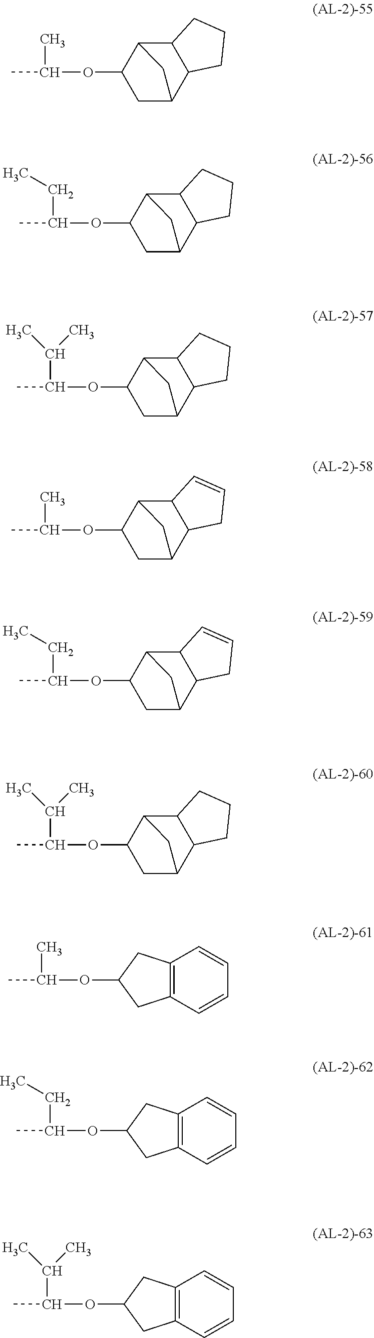

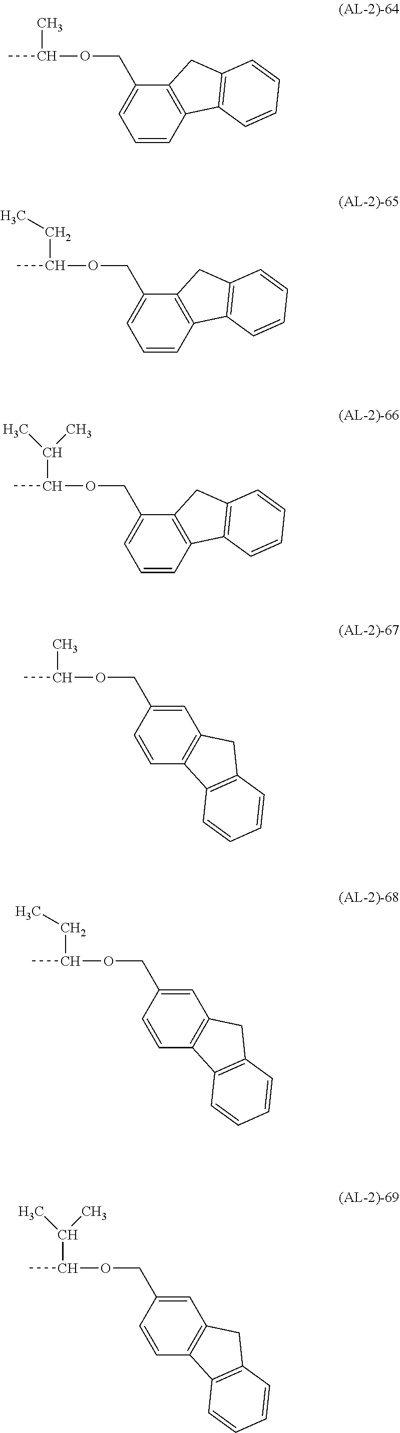

Of the acid labile groups having formula (AL-2), examples of cyclic groups include a tetrahydrofuran-2-yl group, a 2-methyltetrahydrofuran-2-yl group, a tetrahydropyran-2-yl group, and a 2-methyltetrahydropyran-2-yl group.

Examples of the acid labile group include groups having the following formula (AL-2a) or (AL-2b). With these acid labile groups, the base polymer may be crosslinked between molecules or within the molecule.

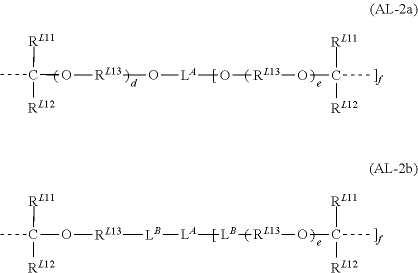

wherein the broken line denotes a point of attachment.

In formula (AL-2a) or (AL-2b), R^{L11} and R^{L12} are each independently a hydrogen atom or a C₁-C₈ saturated hydrocarbyl group. The saturated hydrocarbyl group may be straight, branched, or cyclic. R^{L11} and R^{L12} may bond together to form a ring with the carbon atom to which they are attached, and in this case, R^{L11} and R^{L12} are each independently a C₁-C₈ alkanediyl group. R^{L13} is each independently a C₁-C₁₀ saturated hydrocarbylene group. The saturated hydrocarbylene group may be straight, branched, or cyclic. d and e are each independently an integer of 0 to 10, preferably an integer of 0 to 5, and f is an integer of 1 to 7, preferably an integer of 1 to 3.

In formula (AL-2a) or (AL-2b), L^{A} is a C₁-C₅₀ (f+1)-valent aliphatic saturated hydrocarbon group, a C₃-C₅₀ (f+1)-valent alicyclic saturated hydrocarbon group, a C₆-C₅₀ (f+1)-valent aromatic hydrocarbon group, or a C₃-C₅₀ (f+1)-valent heterocyclic group. Some of —CH₂— in these groups may be substituted with a group containing a heteroatom, and some of the hydrogen atoms in these groups may be substituted with a hydroxy group, a carboxy group, an acyl group, or a fluorine atom. L^{A} is preferably a C₁-C₂₀ saturated hydrocarbylene group, a saturated hydrocarbon group such as a trivalent saturated hydrocarbon group or a tetravalent saturated hydrocarbon group, a C₆-C₃₀ arylene group, or the like. The saturated hydrocarbon group may be straight, branched, or cyclic. L^{B} is —C(═O)—O—, —N(H)—C(═O)—O—, or —N(H)—C(═O)—N(H)—.

Examples of the crosslinking acetal groups having formula (AL-2a) or (AL-2b) include groups having the following formulae (AL-2)-70 to (AL-2)-77.

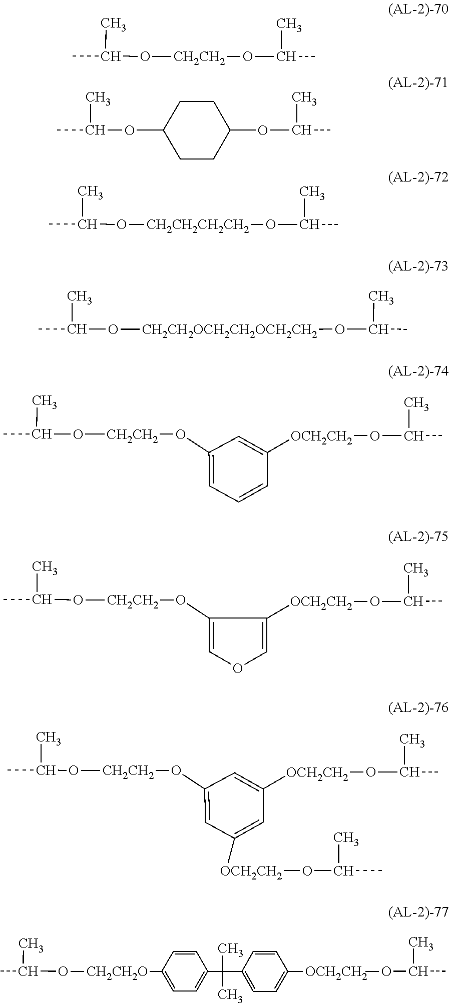

wherein the broken line denotes a point of attachment.

In formula (AL-3), R^{L5}, R^{L6}, and R^{L7} are each independently a C₁-C₂₀ hydrocarbyl group, which may contain a heteroatom such as an oxygen atom, a sulfur atom, a nitrogen atom, or a fluorine atom. The hydrocarbyl group may be saturated or unsaturated and straight, branched, or cyclic. Specific examples thereof include a C₁-C₂₀ alkyl group, a C₃-C₂₀ cyclic saturated hydrocarbyl group, a C₂-C₂₀ alkenyl group, a C₃-C₂₀ cyclic unsaturated hydrocarbyl group, and a C₆-C₁₀ aryl group. A pair of R^{L5} and R^{L6}, R^{L5} and R^{L7}, or R^{L6} and R^{L7} may bond together to form a C₃-C₂₀ alicyclic ring with the carbon atom to which they are attached.

Examples of the group having formula (AL-3) include a tert-butyl group, a 1,1-diethylpropyl group, a 1-ethylnorbornyl group, a 1-methylcyclopentyl group, a 1-ethylcyclopentyl group, a 1-isopropylcyclopentyl group, a 1-methylcyclohexyl group, a 2-(2-methyl)adamantyl group, a 2-(2-ethyl)adamantyl group, and a tert-pentyl group.

Examples of the group having formula (AL-3) include groups having the following formulae (AL-3)-1 to (AL-3)-19.

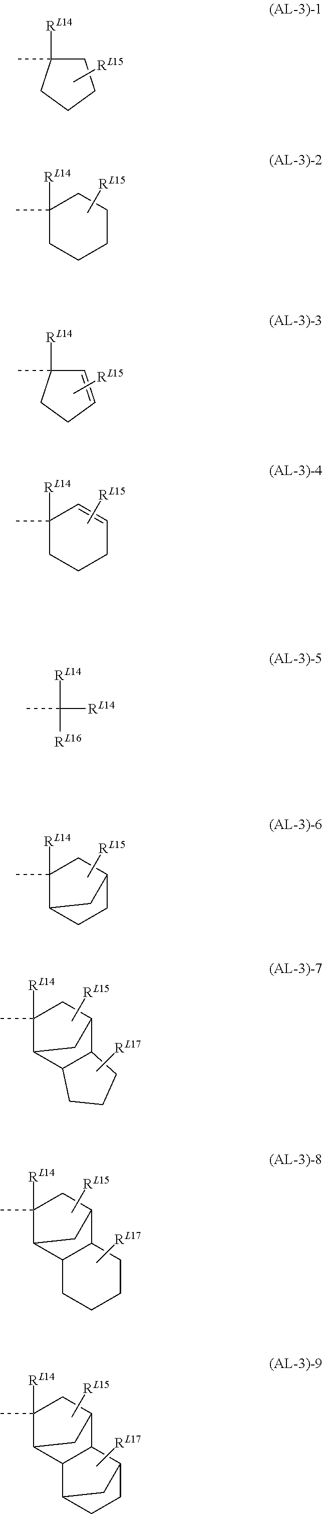

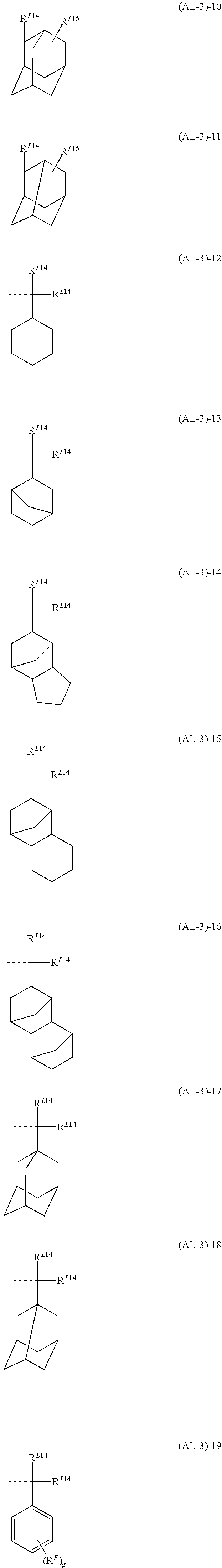

wherein the broken line denotes a point of attachment.

In formulae (AL-3)-1 to (AL-3)-19, R^{L14} is each independently a C₁-C₈ aliphatic hydrocarbyl group or a C₆-C₂₀ aryl group. R^{L15} and R^{L17} are each independently a hydrogen atom or a C₁-C₂₀ saturated hydrocarbyl group. R^{L16} is a C₆-C₂₀ aryl group. The saturated hydrocarbyl group may be straight, branched, or cyclic. The aryl group is preferably a phenyl group or the like. R^{F} is a fluorine atom, a trifluoromethyl group, or a nitro group. g is an integer of 0 to 5.

In addition to the acid labile group, acid labile groups containing an aromatic group described in JP 5565293, JP 5434983, JP 5407941, JP 5655756, and JP 5655755 can be also used.

The repeat unit b preferably has the following formula (b).

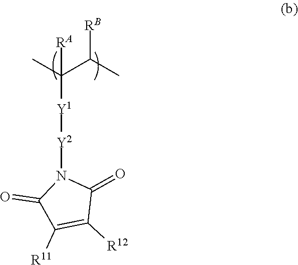

In formula (b), R^{A} is a hydrogen atom or a methyl group.

In formula (b), R^{B} is a hydrogen atom or a group that bonds together with Y¹ to form a C₈-C₁₄ ring with the carbon atom to which they are attached. At this time, examples of the ring include an indane ring and an acenaphthene ring.

In formula (b), Y¹ is a single bond, a phenylene group, a naphthylene group, an ester bond, or an ether bond.

In formula (b), Y² is a single bond or a C₁-C₁₂ saturated hydrocarbylene group, the saturated hydrocarbylene group may have at least one selected from an ester bond, an amide bond, an ether bond, a lactone ring, and a urethane bond. The saturated hydrocarbylene group may be straight, branched, or cyclic, and specific examples thereof include C₁-C₁₂ alkanediyl groups such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-1,1-diyl group, a butane-1,2-diyl group, a butane-1,3-diyl group, a butane-2,3-diyl group, a butane-1,4-diyl group, a 1,1-dimethylethane-1,2-diyl group, a pentane-1,5-diyl group, a 2-methylbutane-1,2-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; C₃-C₁₂ cyclic saturated hydrocarbylene groups such as a cyclopropanediyl group, a cyclobutanediyl group, a cyclopentanediyl group, a cyclohexanediyl group, an adamantanediyl group, and a norbornanediyl group; and groups obtained by combining these.

In formula (b), R¹¹ and R¹² are each independently a hydrogen atom or a C₁-C₁₀ saturated hydrocarbyl group, and the saturated hydrocarbyl group may contain an ether bond or a sulfide bond. The saturated hydrocarbyl group may be straight, branched, or cyclic, and specific examples thereof include C₁-C₁₀ alkyl groups such as a methyl group, an ethyl group, a n-propyl group, an isopropyl group, a n-butyl group, an isobutyl group, a sec-butyl group, a tert-butyl group, a n-pentyl group, a neopentyl group, a n-hexyl group, a n-heptyl group, a n-octyl group, a 2-ethylhexyl group, a n-nonyl group, and a n-decyl group; and C₁-C₁₀ cyclic saturated hydrocarbyl groups such as a cyclopentyl group and a cyclohexyl group. R¹¹ and R¹² may bond together to form a ring with the carbon atom to which they are attached. Examples of the ring that can be formed at this time include a cyclohexene ring and a norbornene ring.

Examples of the monomer from which repeat units b are derived are shown below, but not limited thereto. In the following formula, R^{A} is as defined above.

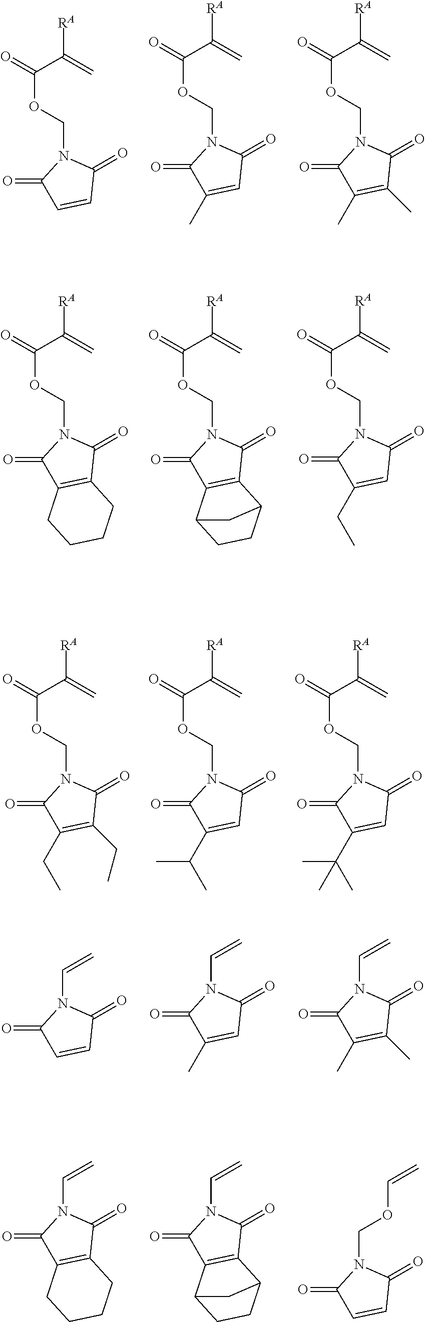

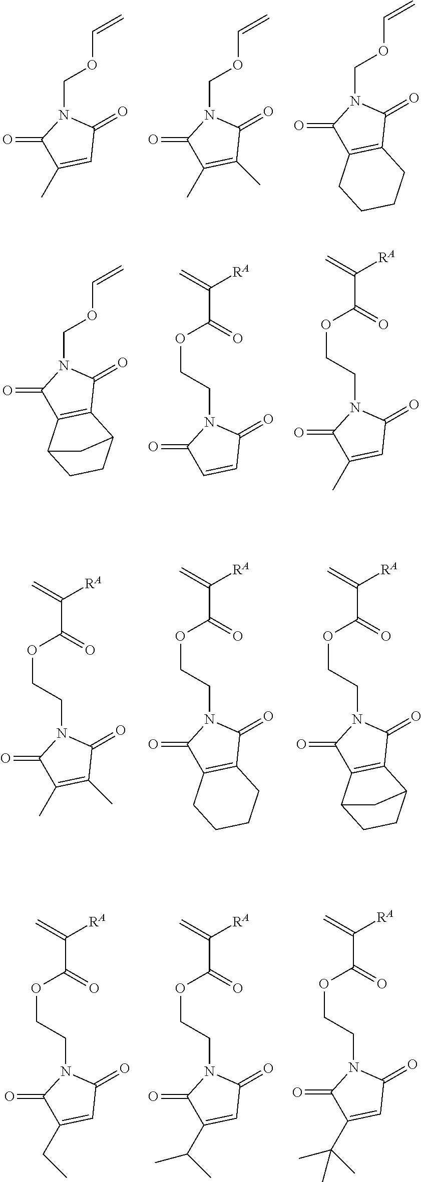

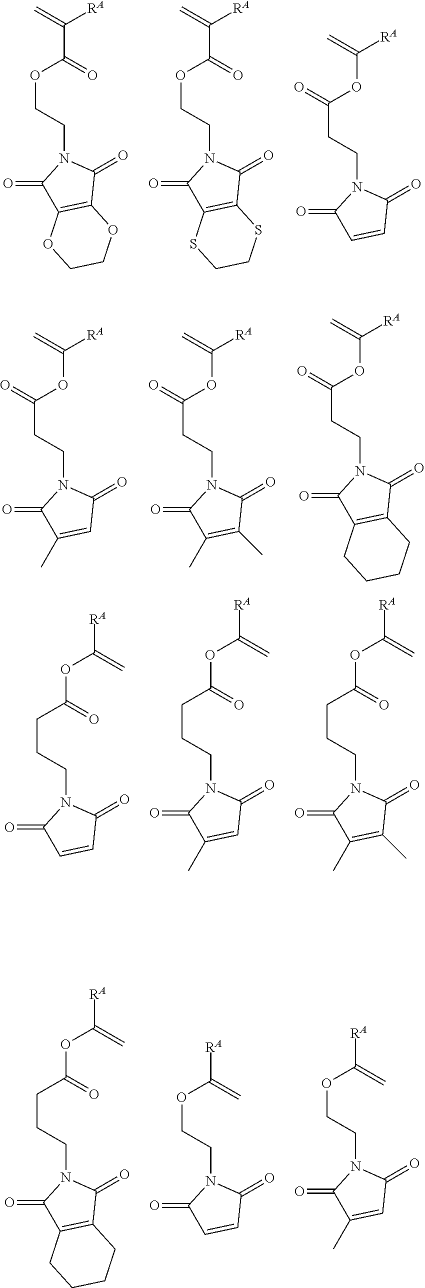

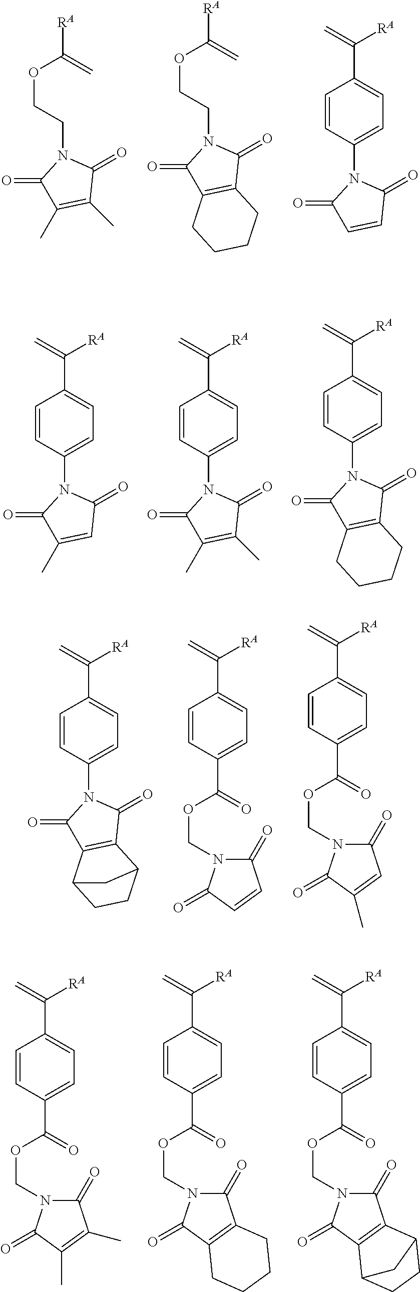

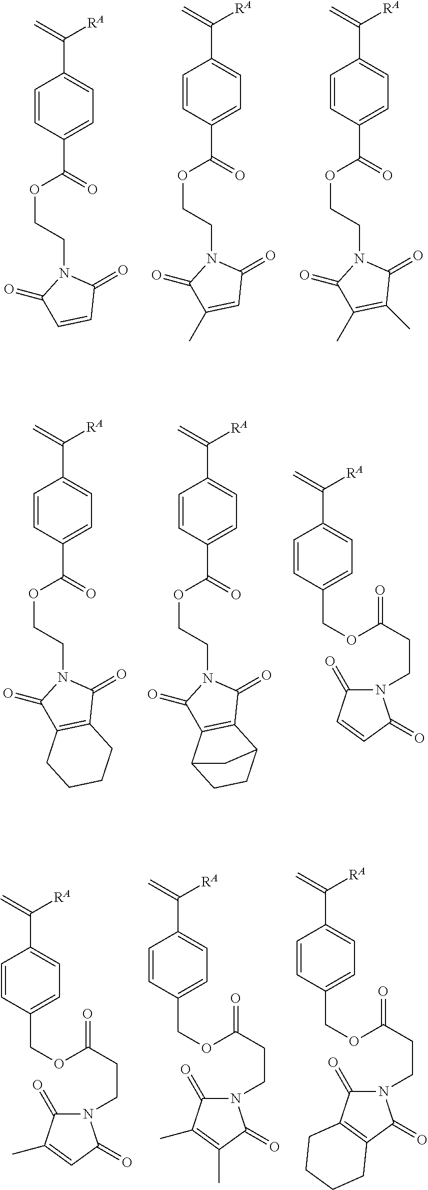

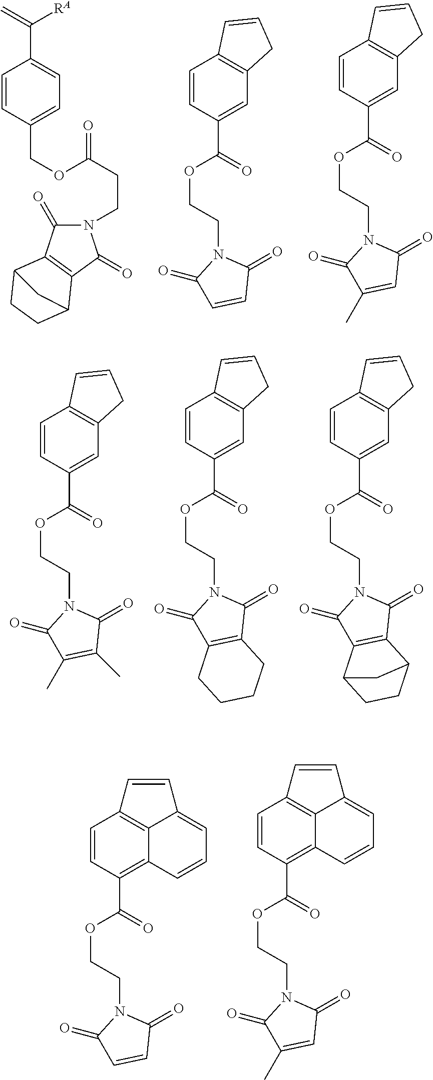

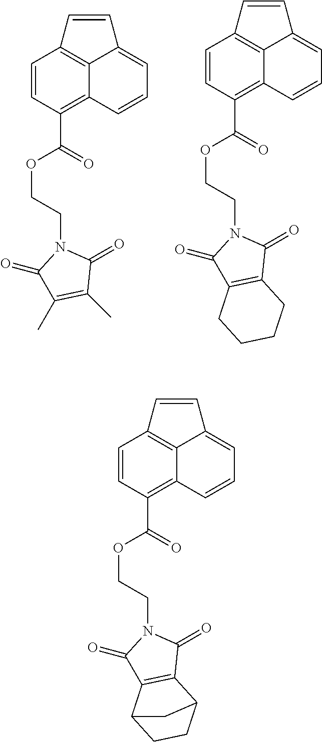

Examples of the method for obtaining the repeat units b include a method of polymerizing the monomer having a maleimide group, but a maleimide group may be introduced into the polymer after polymerization. Examples of the method include a method of reacting a maleimide group-containing compound having a hydroxy group, a carboxyl group, an epoxy group, or an isocyanate group with a polymer after polymerization having a hydroxy group, a carboxyl group, an epoxy group, or an isocyanate group.

The polymer A may further include repeat units c containing an adhesive group selected from a hydroxy group, a carboxy group, a lactone ring, a carbonate bond, a thiocarbonate bond, a carbonyl group, a cyclic acetal group, an ether bond, an ester bond, a sulfonate bond, a cyano group, an amide bond, —O—C(═O)—S—, and —O—C(═O)—NH—.

Examples of the monomer from which repeat units c are derived are shown below, but not limited thereto. In the following formula, R^{A} is as defined above.

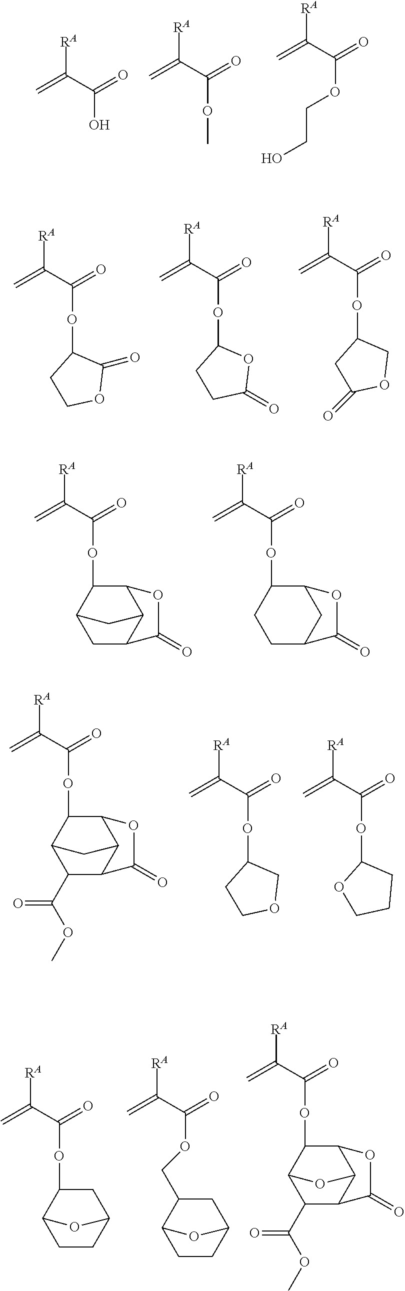

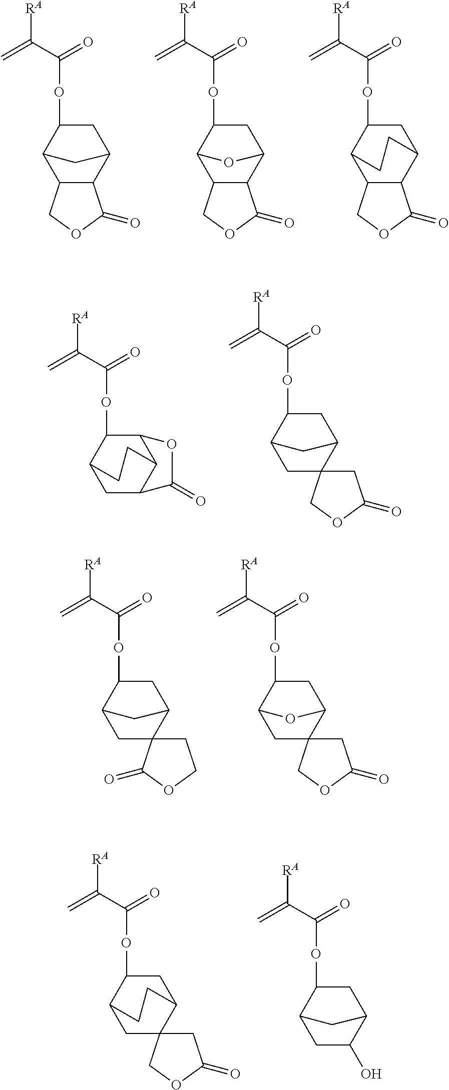

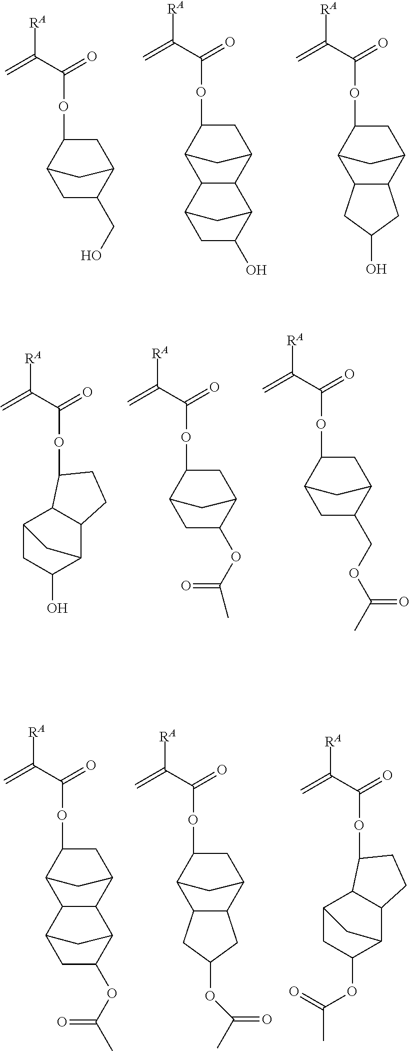

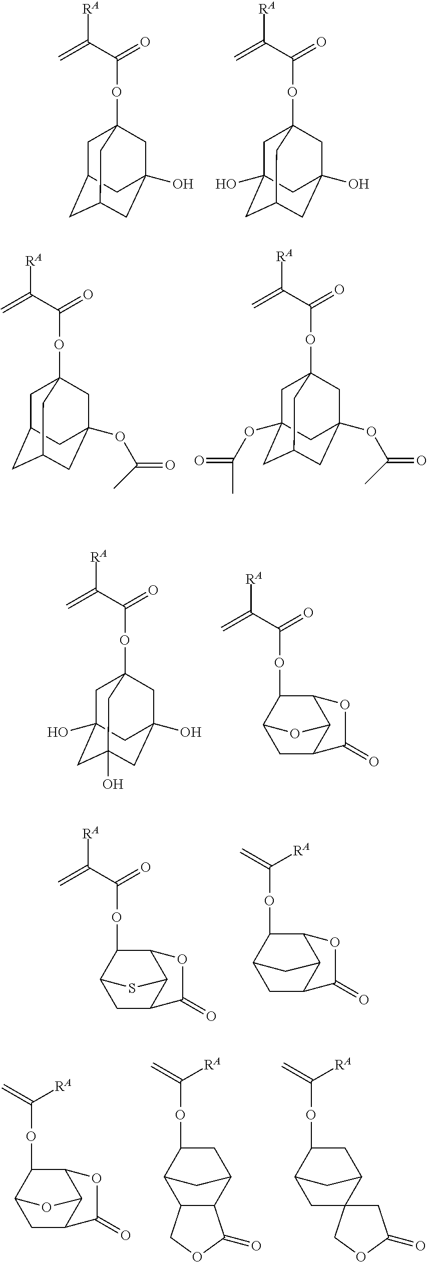

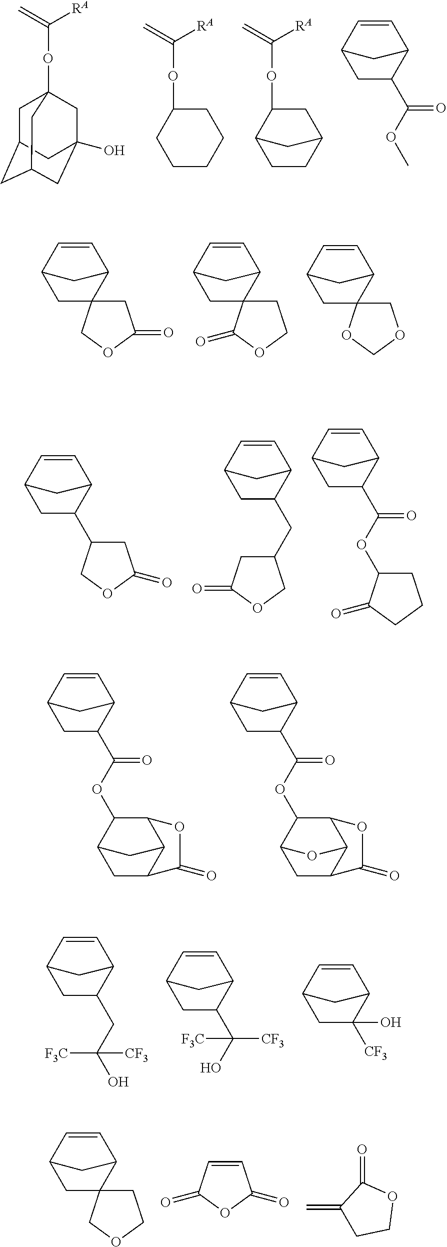

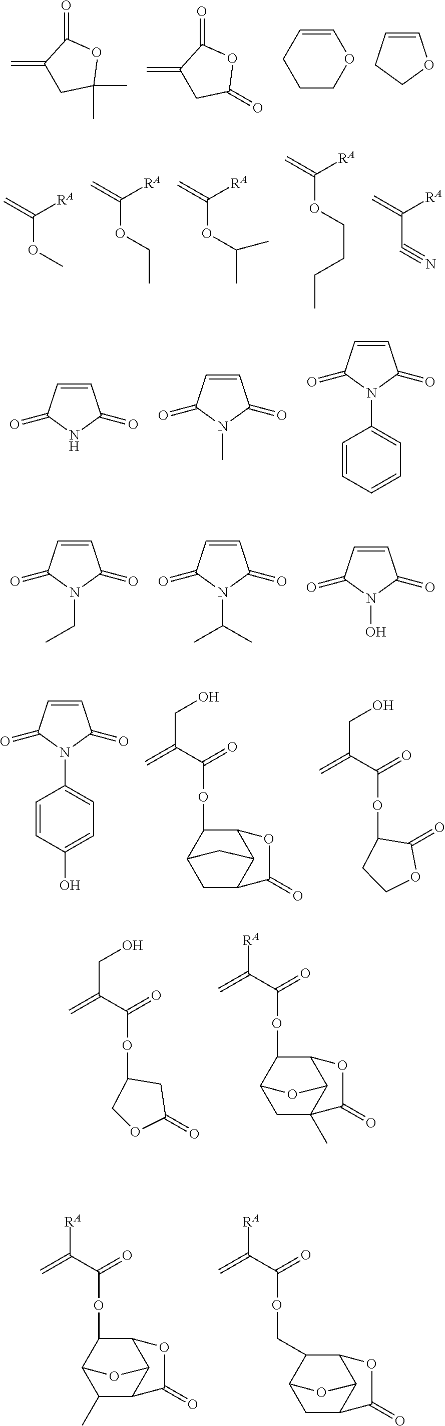

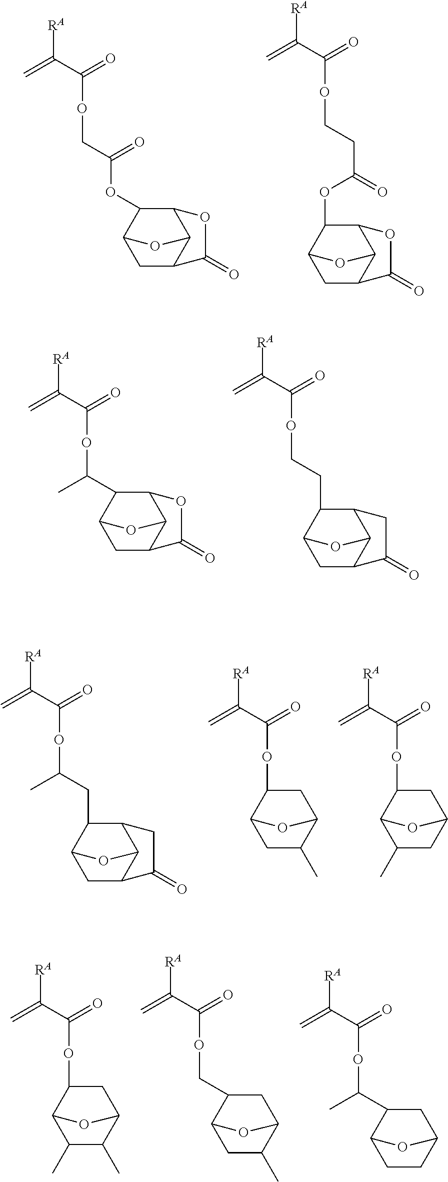

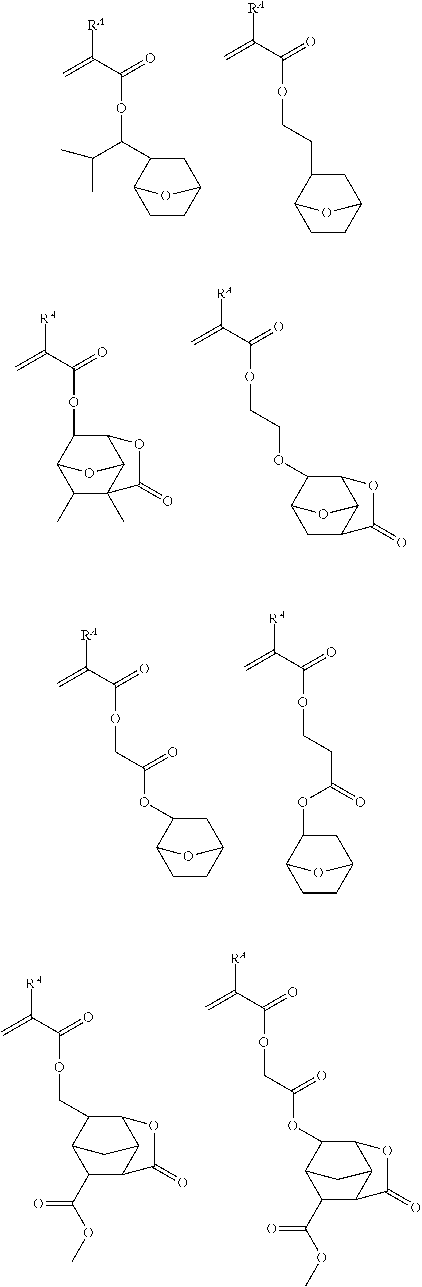

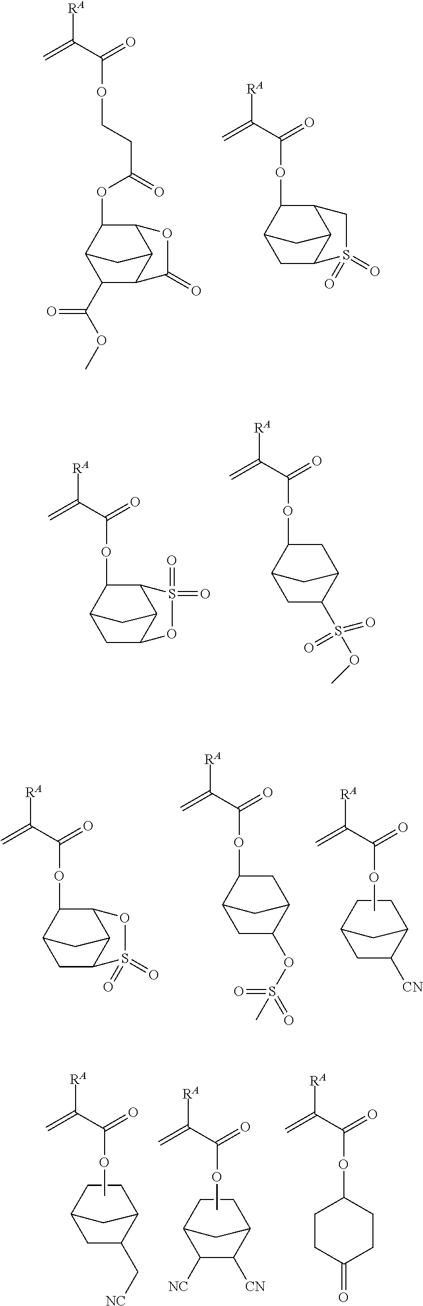

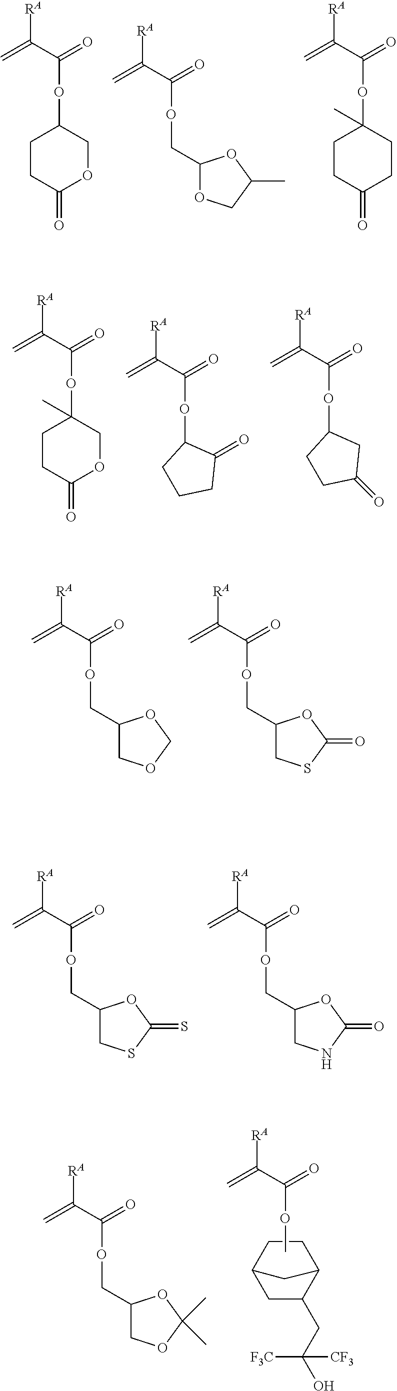

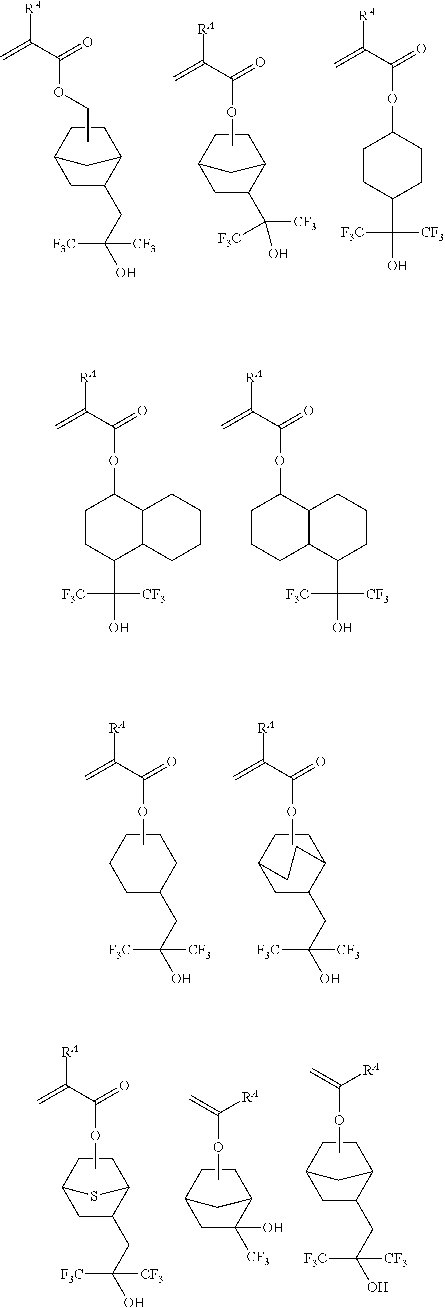

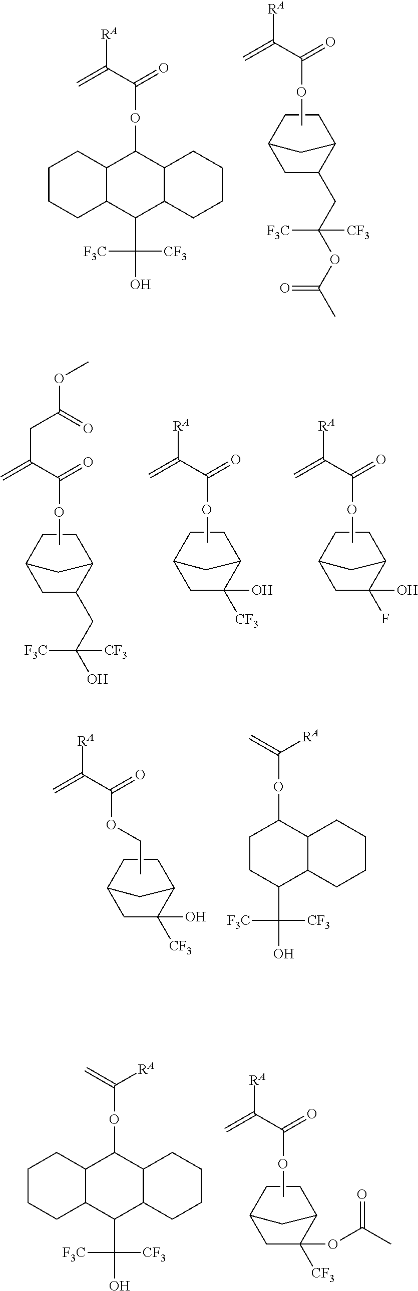

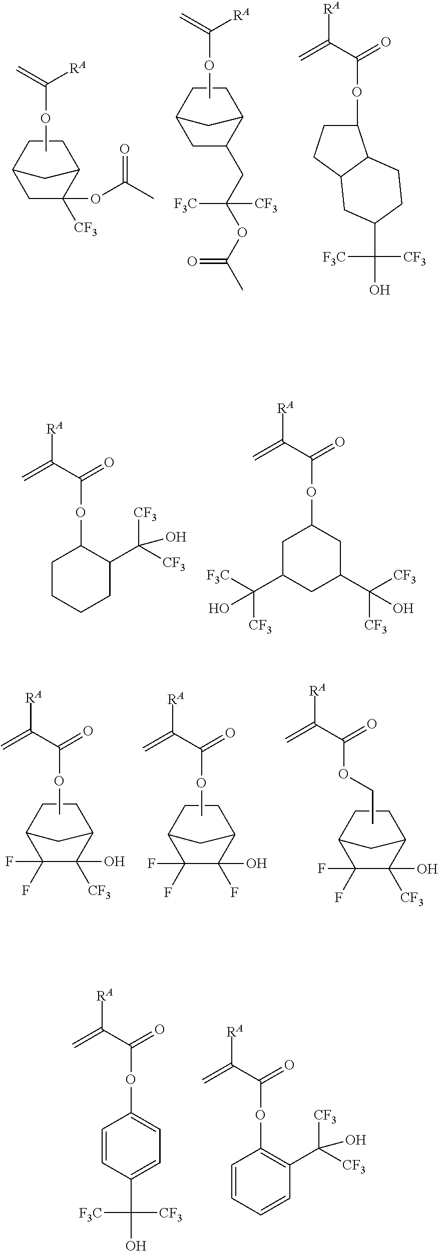

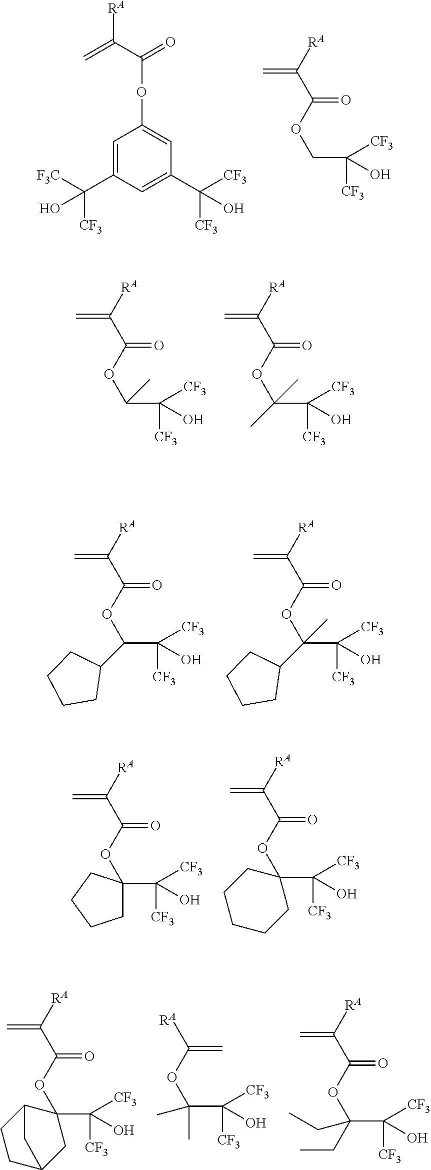

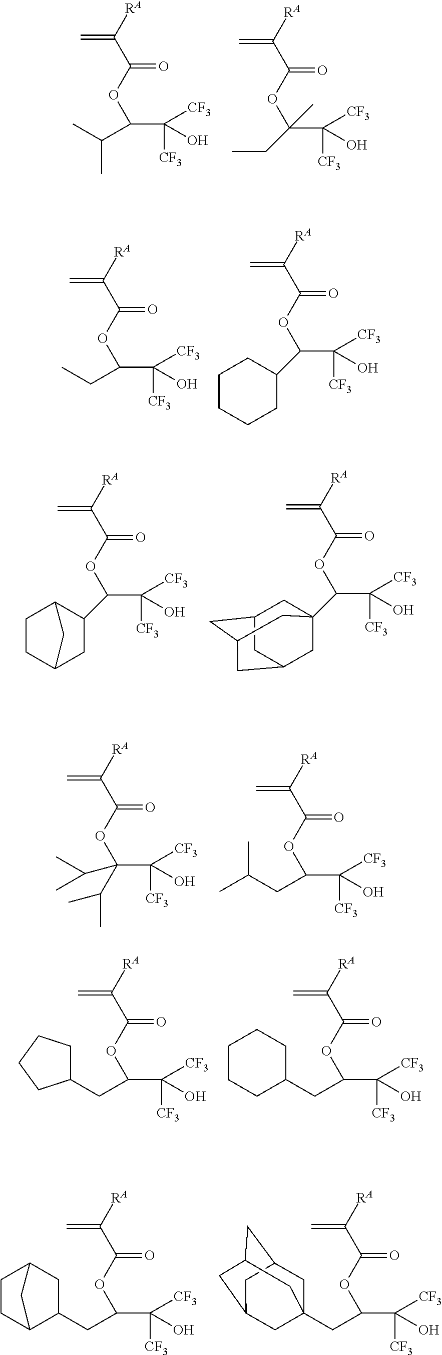

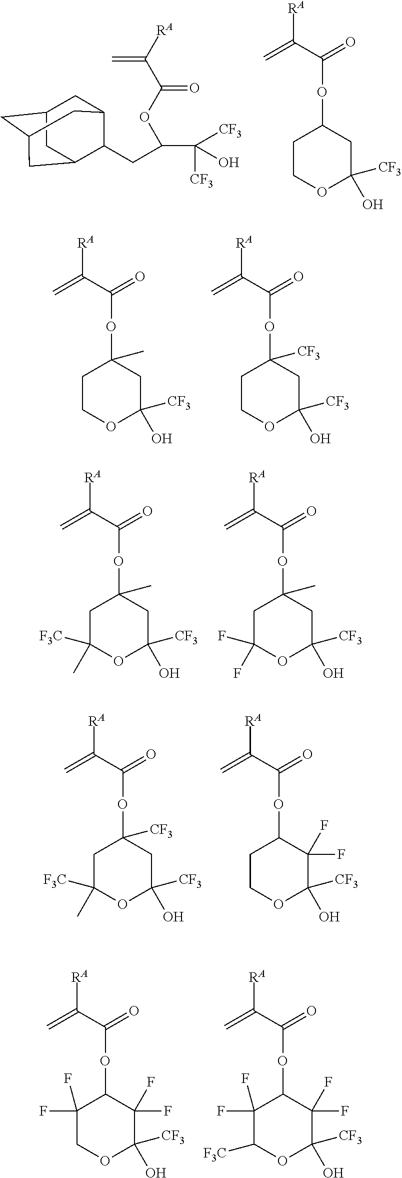

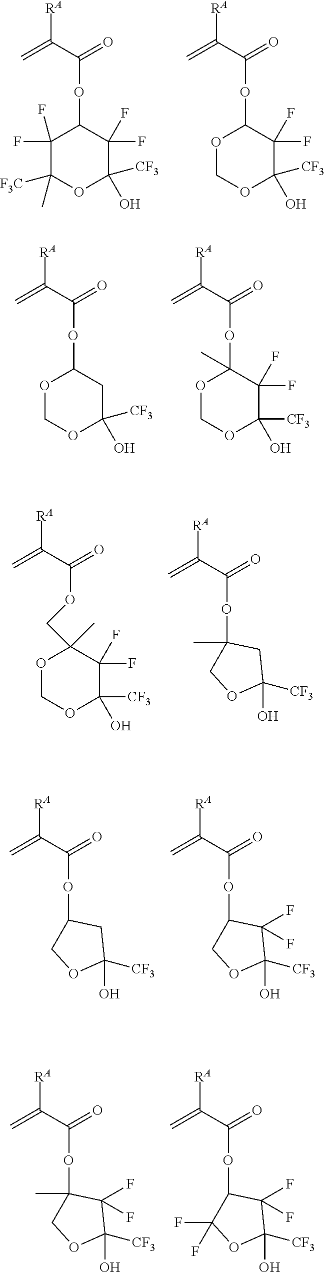

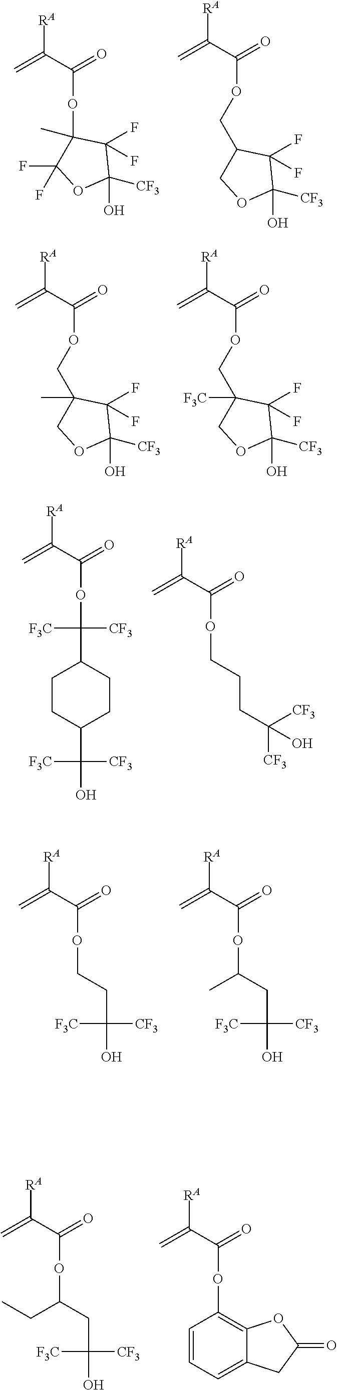

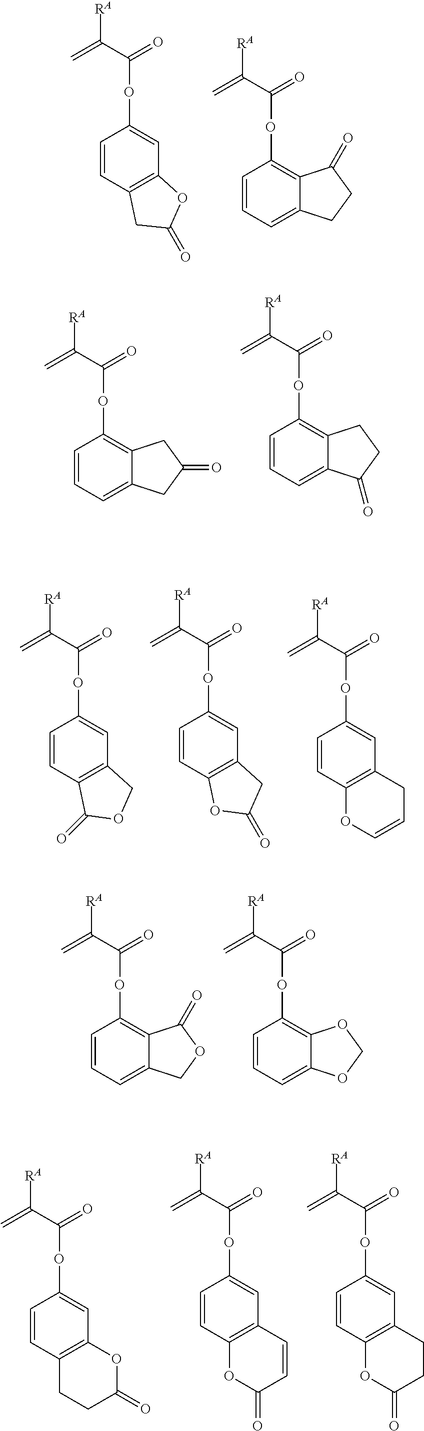

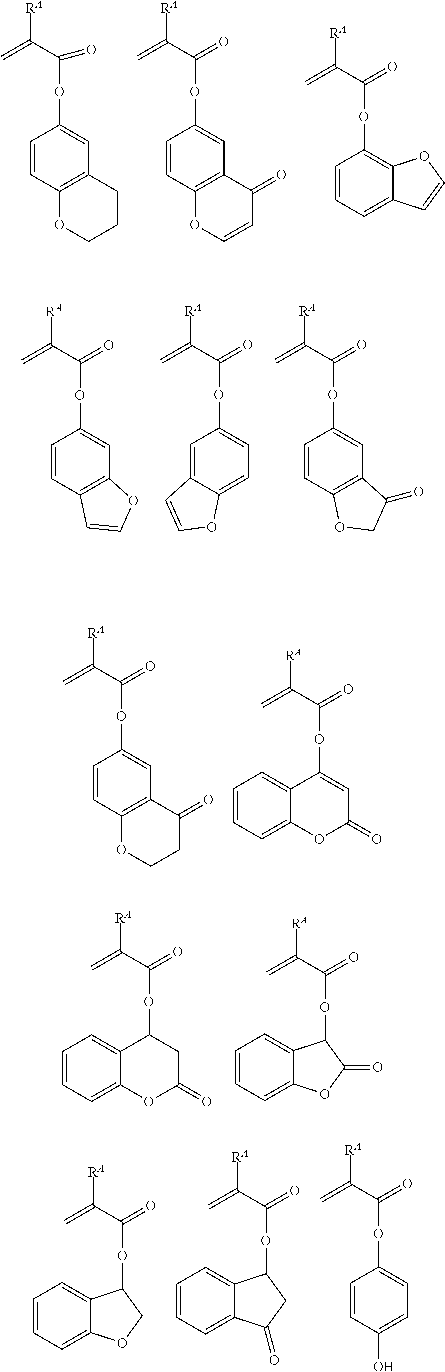

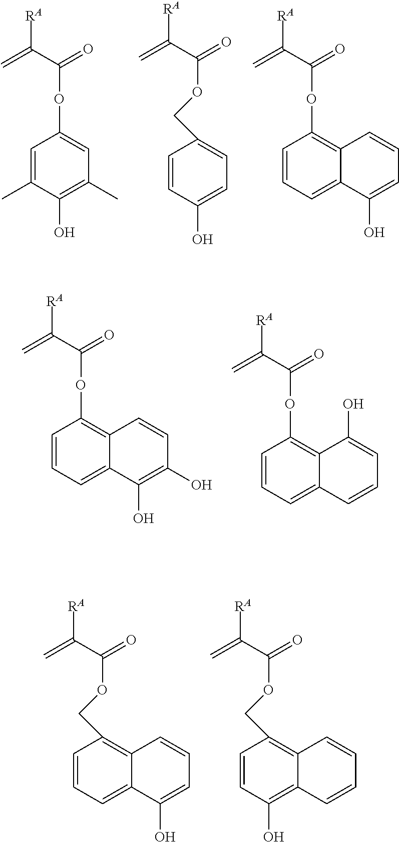

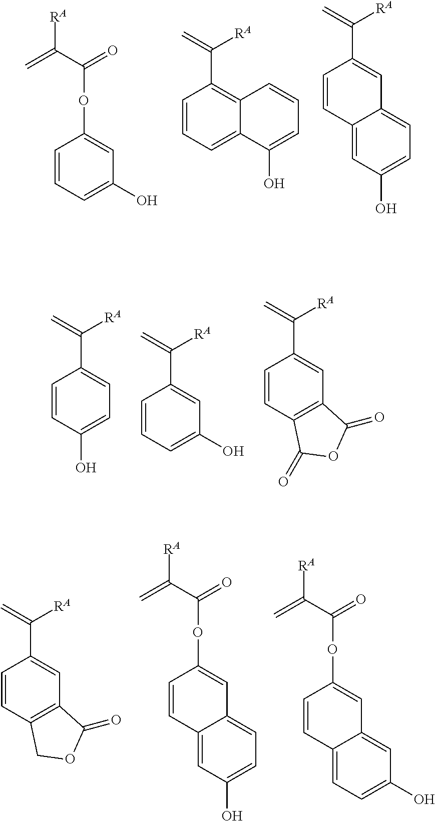

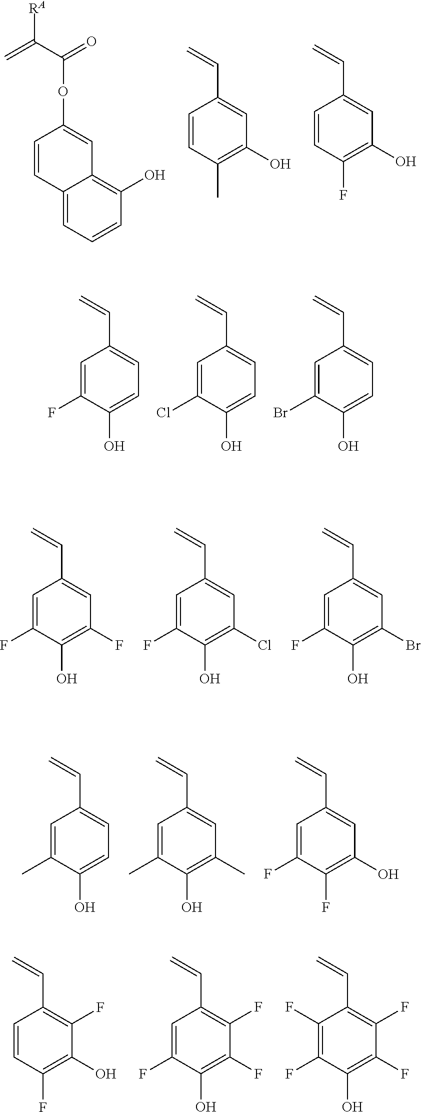

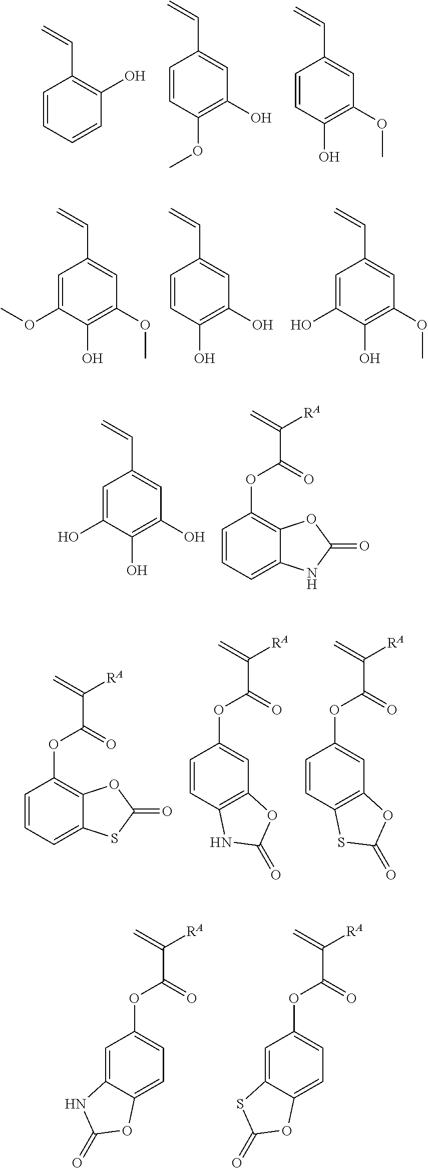

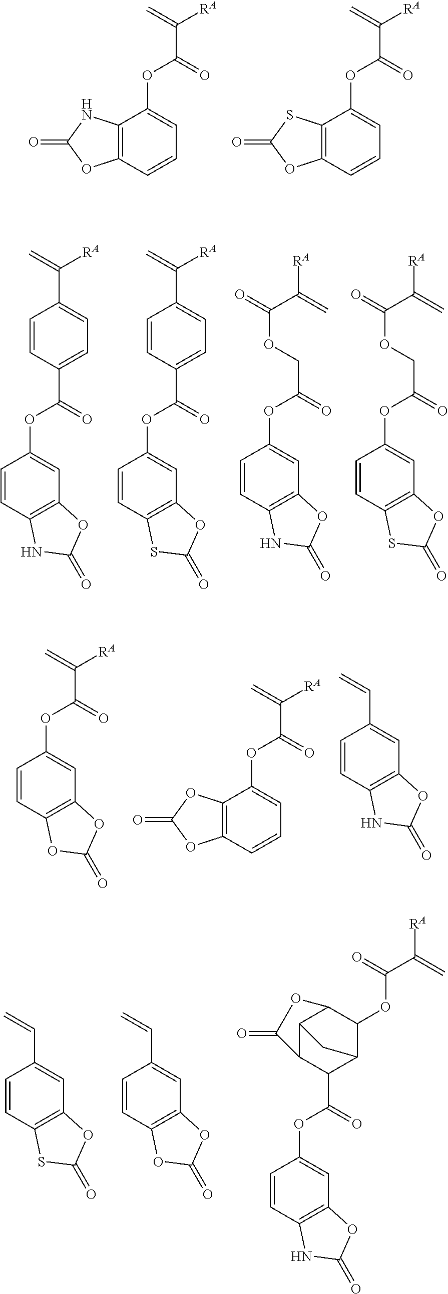

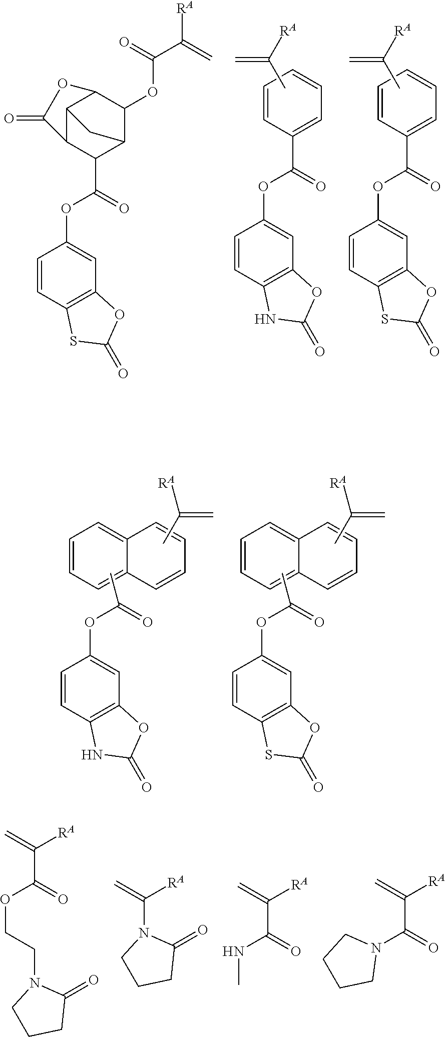

The polymer A may further include at least one selected from repeat units having the following formula (d1) (also referred to as repeat units d1, hereinafter), repeat units having the following formula (d2) (also referred to as repeat units d2, hereinafter), and repeat units having the following formula (d3) (also referred to as repeat units d3, hereinafter).

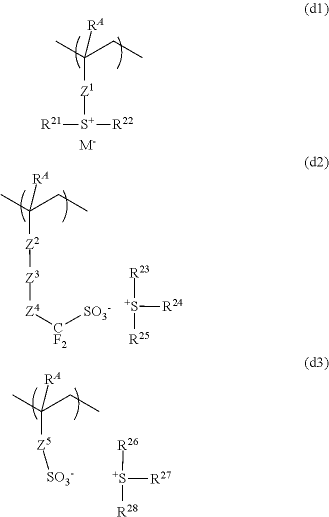

In formulae (d1) to (d3), R^{A} is each independently a hydrogen atom or a methyl group. Z¹ is a single bond, a C₁-C₆ aliphatic hydrocarbylene group, a phenylene group, a naphthylene group, or a C₇-C₁₈ group obtained by combining the foregoing, or —O—Z¹¹—, —C(═O)—O—Z¹¹—, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, a bromine atom, or an iodine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group. The aliphatic hydrocarbylene group represented by Z¹, Z¹¹, Z³¹, and Z⁵¹ may be saturated or unsaturated and straight, branched, or cyclic.

In formulae (d1) to (d3), R²¹ to R²⁸ are each independently a halogen atom, or a C₁-C₂₀ hydrocarbyl group which may contain a heteroatom. Examples of the halogen atom include a fluorine atom, a chlorine atom, a bromine atom, and an iodine atom. The hydrocarbyl group may be saturated or unsaturated and straight, branched, or cyclic. Specific examples thereof are as exemplified above for R¹⁰¹ to R¹⁰⁵ in the description of formulae (1-1) and (1-2) described below.

A pair of R²³ and R²⁴ or R²⁶ and R²⁷ may bond together to form a ring with the sulfur atom to which they are attached. In this case, examples of the ring are as will be exemplified later for the ring that R¹⁰¹ and R¹⁰² in the description of formula (1-1) described below may bond together to form with the sulfur atom to which they are attached.

In formula (d1), M⁻ is a non-nucleophilic counter ion. Examples of the non-nucleophilic counter ion include halide ions such as chloride ions and bromide ions; fluoroalkylsulfonate ions such as triflate ions, 1,1,1-trifluoroethanesulfonate ions, and nonafluorobutanesulfonate ions; arylsulfonate ions such as tosylate ions, benzenesulfonate ions, 4-fluorobenzenesulfonate ions, and 1,2,3,4,5-pentafluorobenzenesulfonate ions; alkylsulfonate ions such as mesylate ions and butanesulfonate ions; imide ions such as bis(trifluoromethylsulfonyl)imide ions, bis(perfluoroethylsulfonyl)imide ions, and bis(perfluorobutylsulfonyl)imide ions; and methide ions such as tris(trifluoromethylsulfonyl)methide ions and tris(perfluoroethylsulfonyl)methide ions.

Examples of the non-nucleophilic counter ion represented by M⁻ further include sulfonate ions having fluorine substituted at α-position of the following formula (d1-1) and sulfonate ions having fluorine substituted at α-position and trifluoromethyl at β-position of the following formula (d1-2).

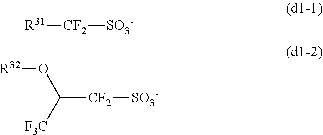

In formula (d1-1), R³¹ is a hydrogen atom or a C₁-C₂₀ hydrocarbyl group which may contain an ether bond, an ester bond, a carbonyl group, a lactone ring, or a fluorine atom. The hydrocarbyl group may be saturated or unsaturated and straight, branched, or cyclic. Specific examples thereof are as will be exemplified later for the hydrocarbyl group represented by R^{fa1} in formula (1A′) described below.

In formula (d1-2), R³² is a hydrogen atom, or a C₁-C₃₀ hydrocarbyl group or C₂-C₃₀ hydrocarbylcarbonyl group, which may contain an ether bond, an ester bond, a carbonyl group, or a lactone ring. The hydrocarbyl moiety of the hydrocarbyl group and the hydrocarbylcarbonyl group may be saturated or unsaturated and straight, branched, or cyclic. Specific examples thereof are as will be exemplified later for the hydrocarbyl group represented by R^{fa1} in formula (1A′) described below.

Examples of the cation of the monomer from which repeat units d1 are derived are shown below, but not limited thereto. In the following formula, R^{A} is as defined above.

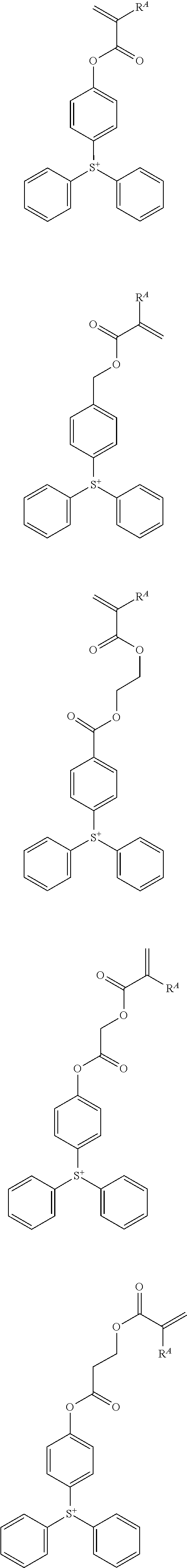

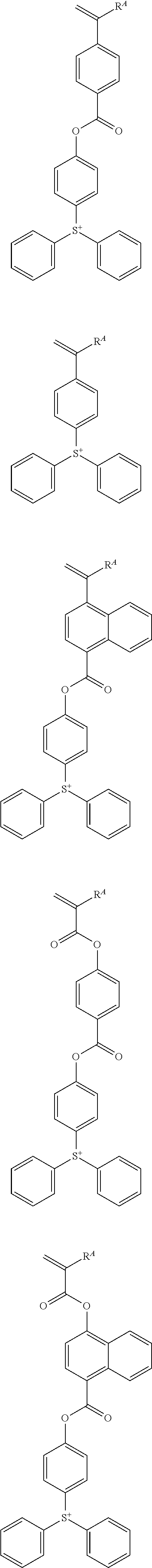

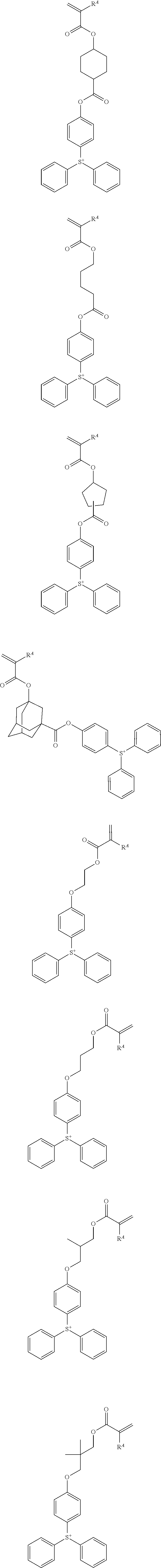

Specific examples of the cation of the monomer from which repeat units d2 or d3 are derived are as exemplified above for the cation of the sulfonium salt having formula (A-1) in JP-A 2022-173075.

Examples of the anion of the monomer from which repeat units d2 are derived are shown below, but not limited thereto. In the following formula, R^{A} is as defined above.

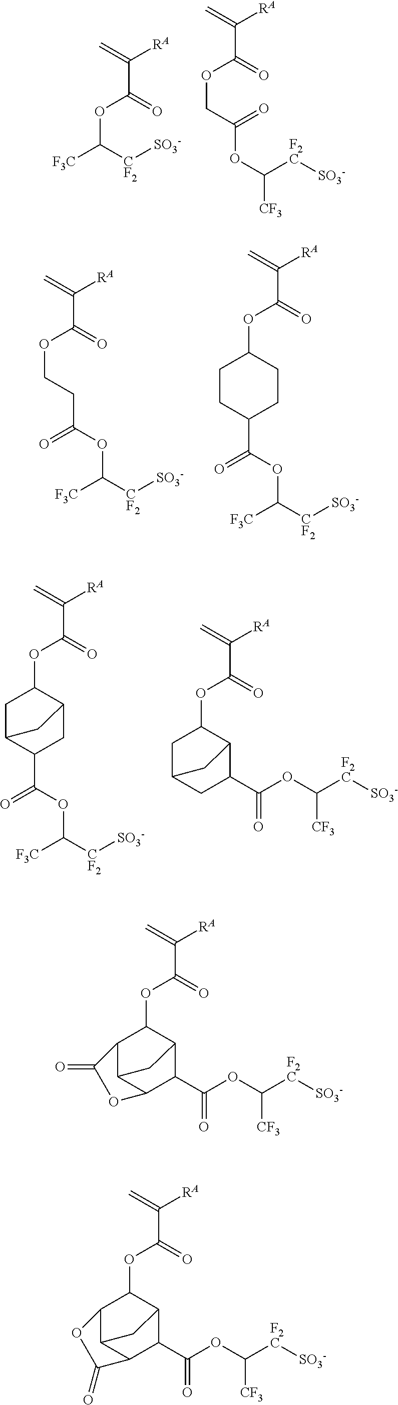

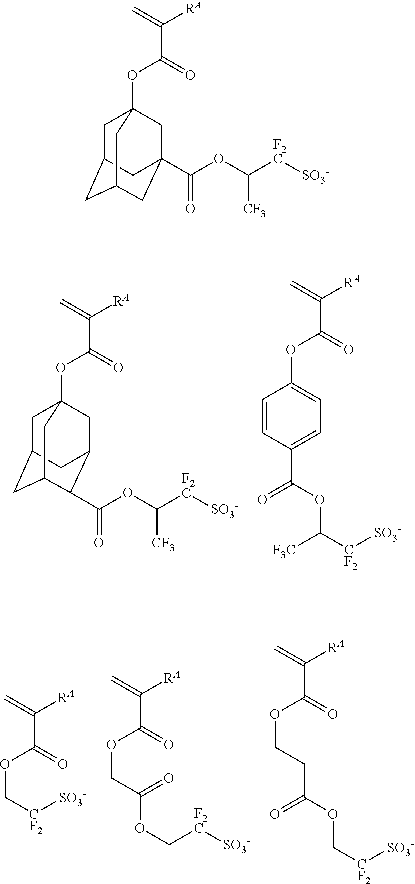

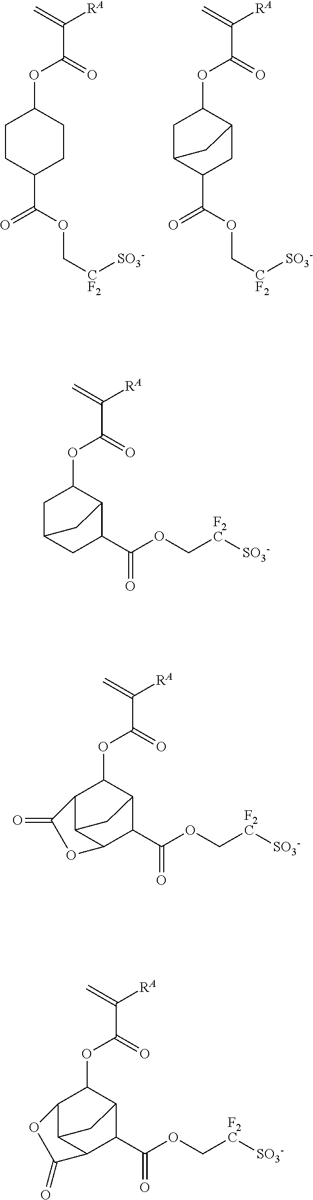

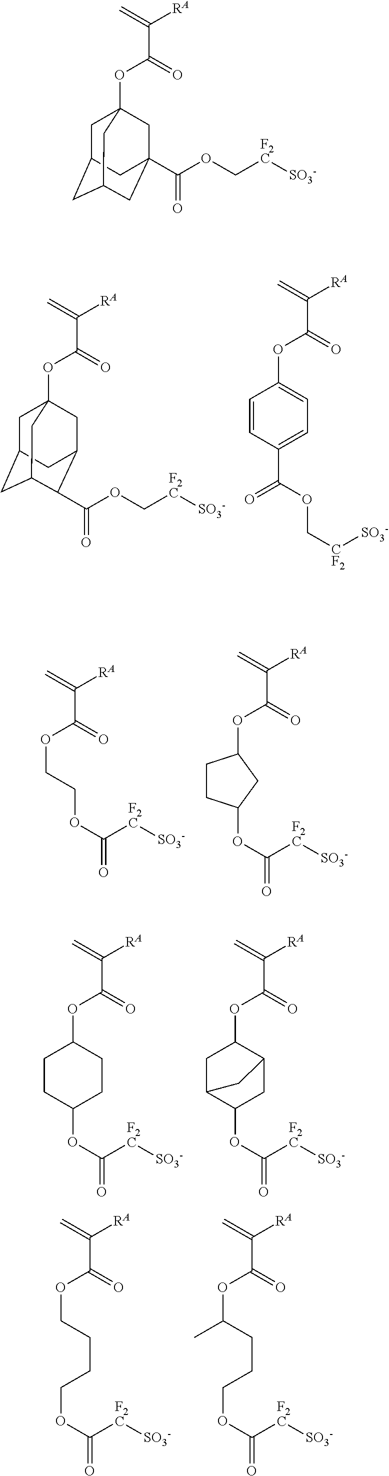

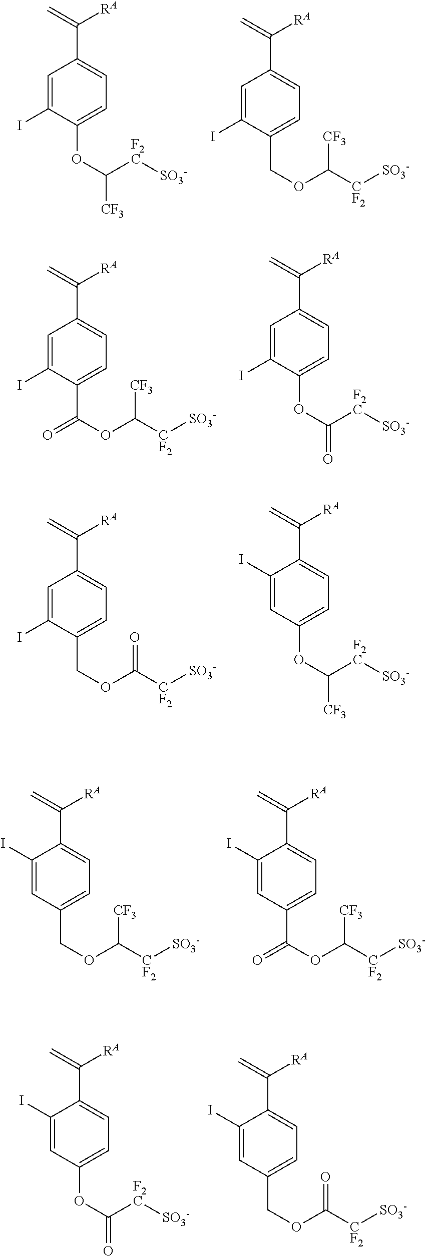

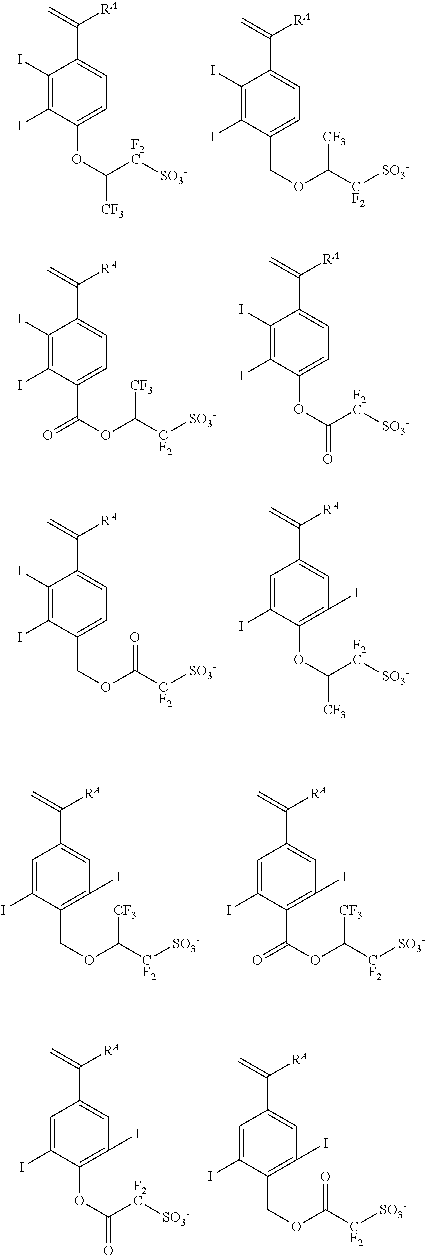

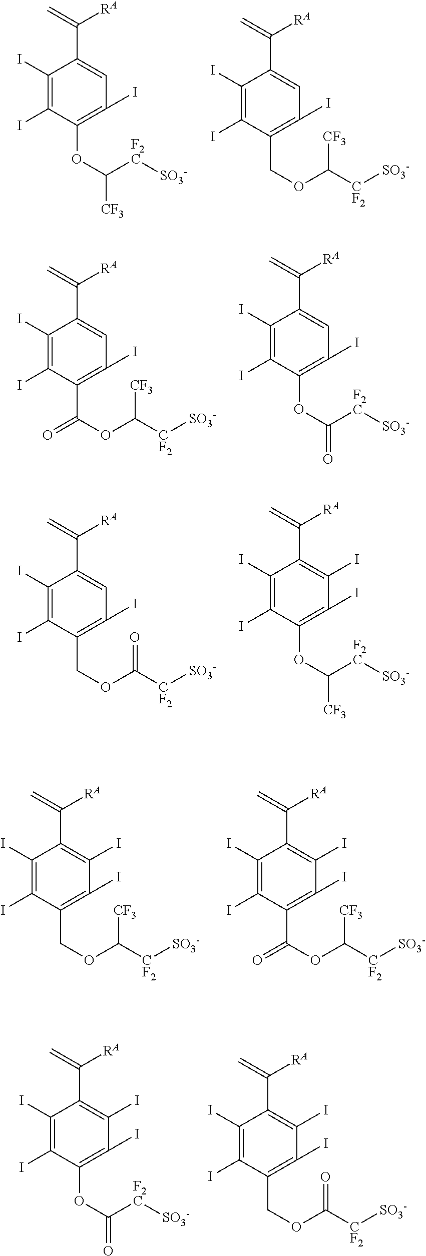

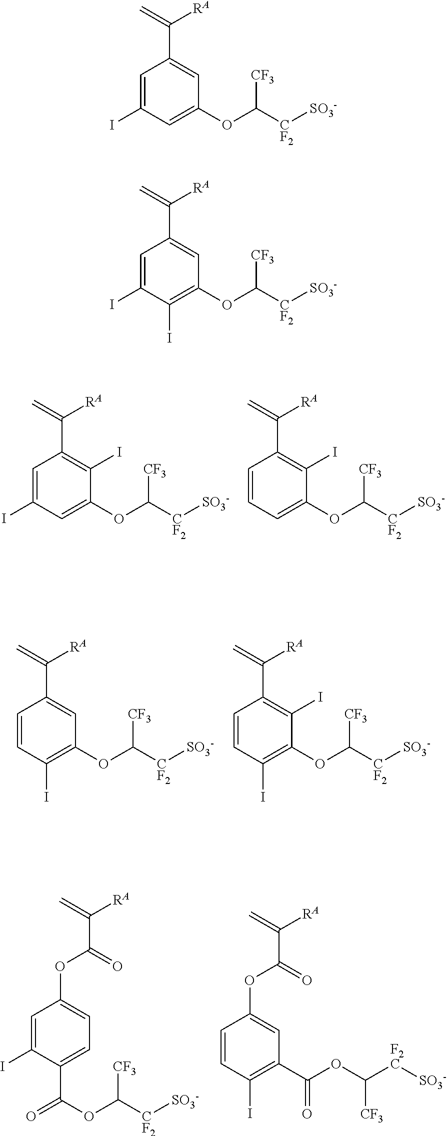

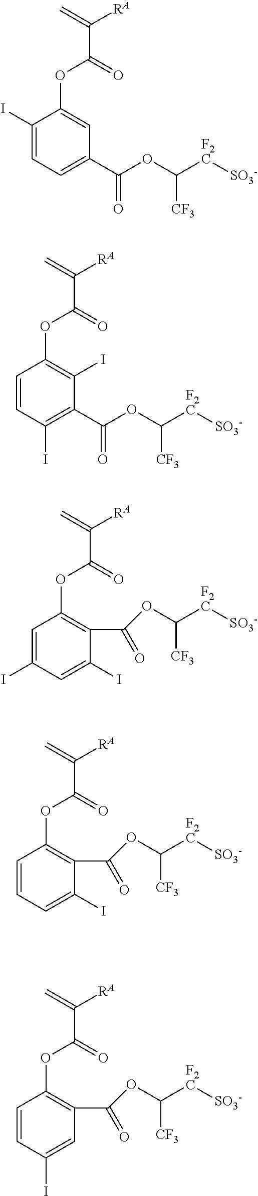

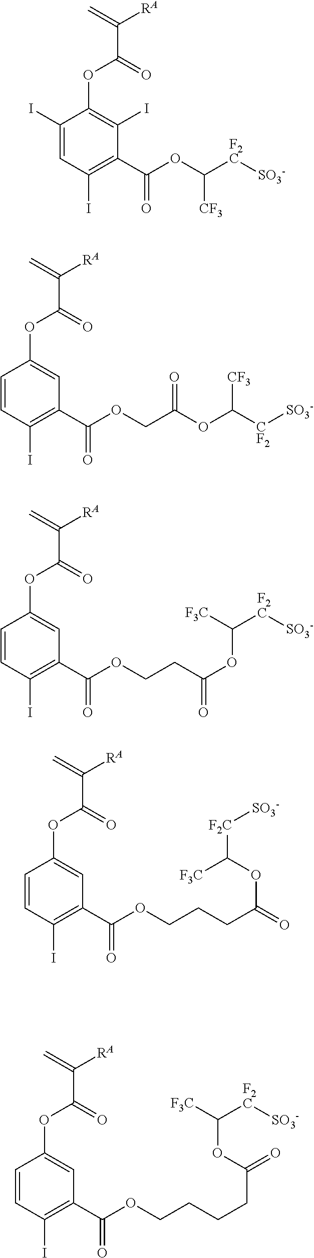

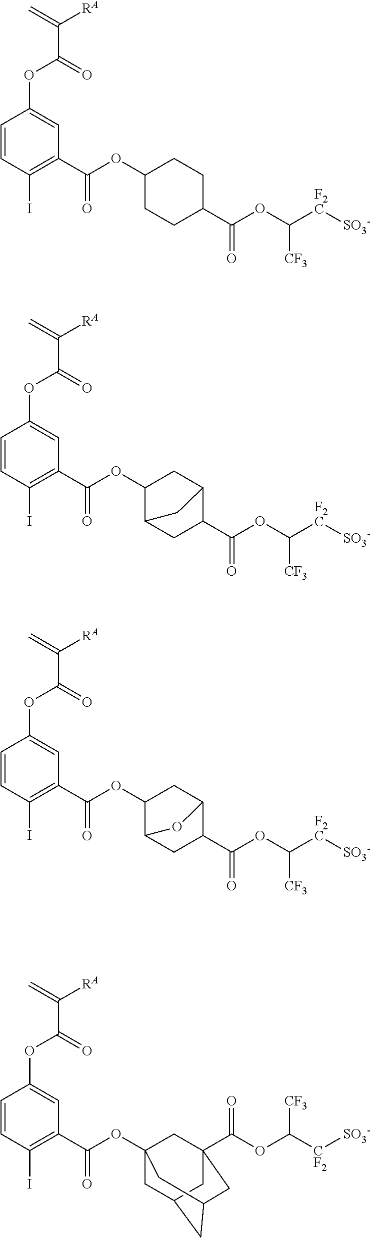

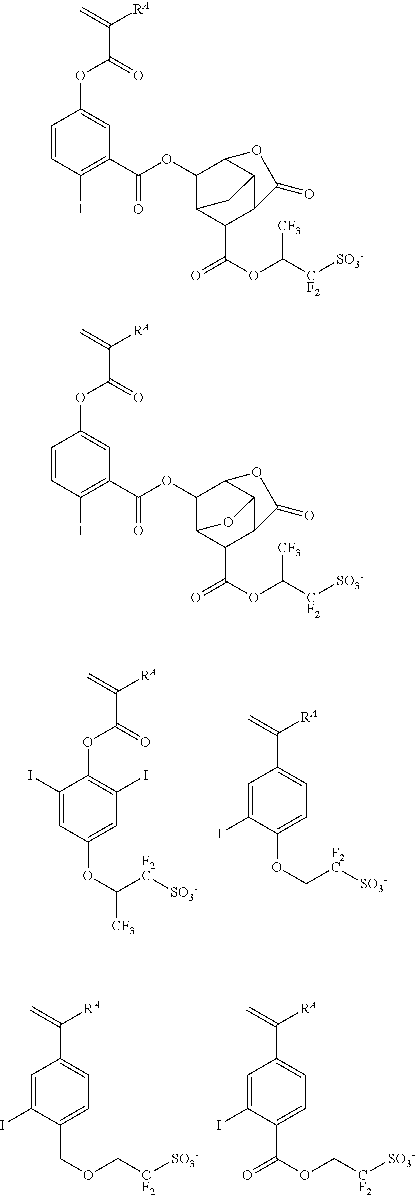

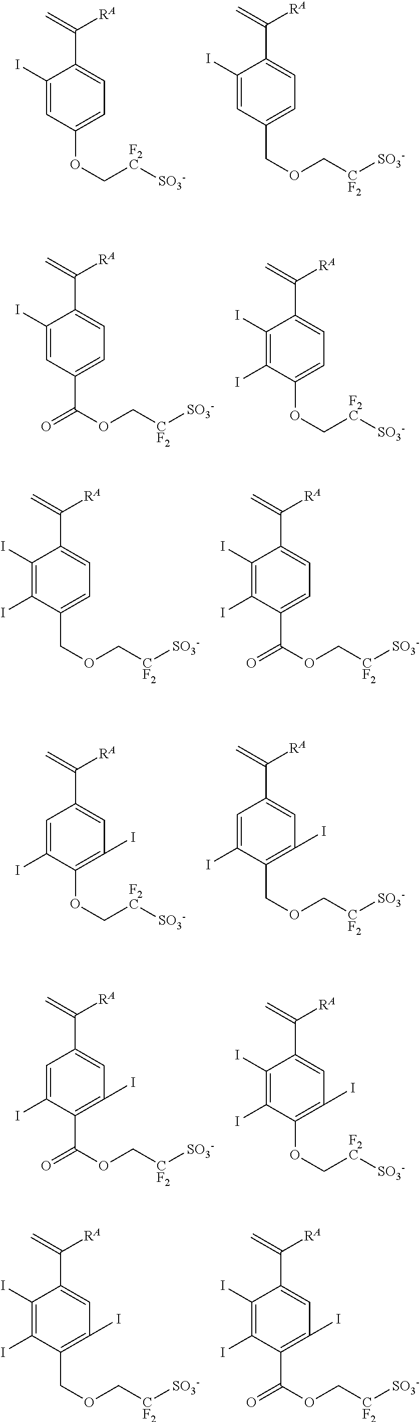

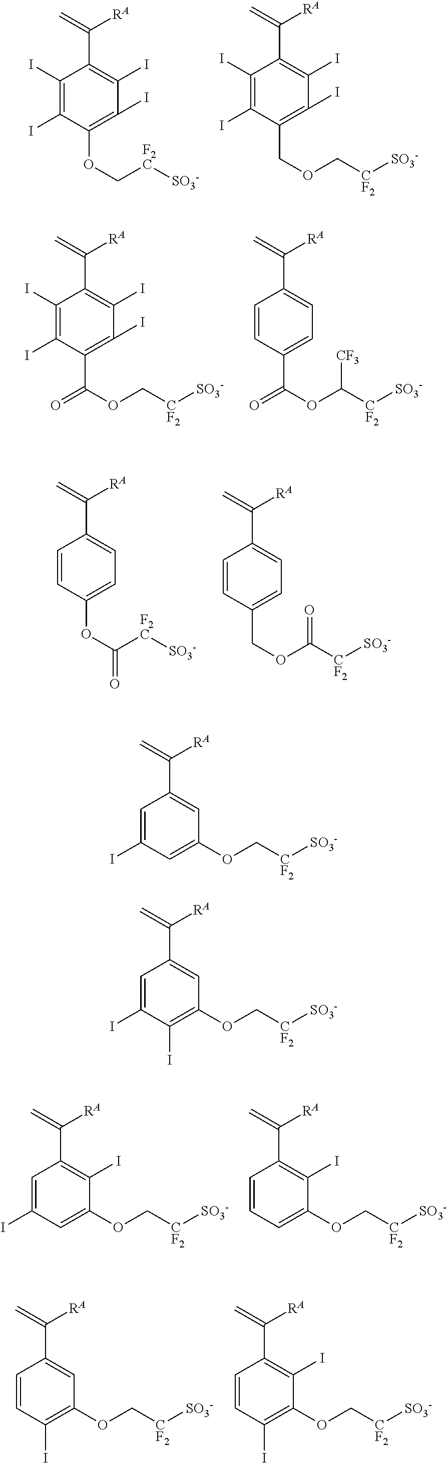

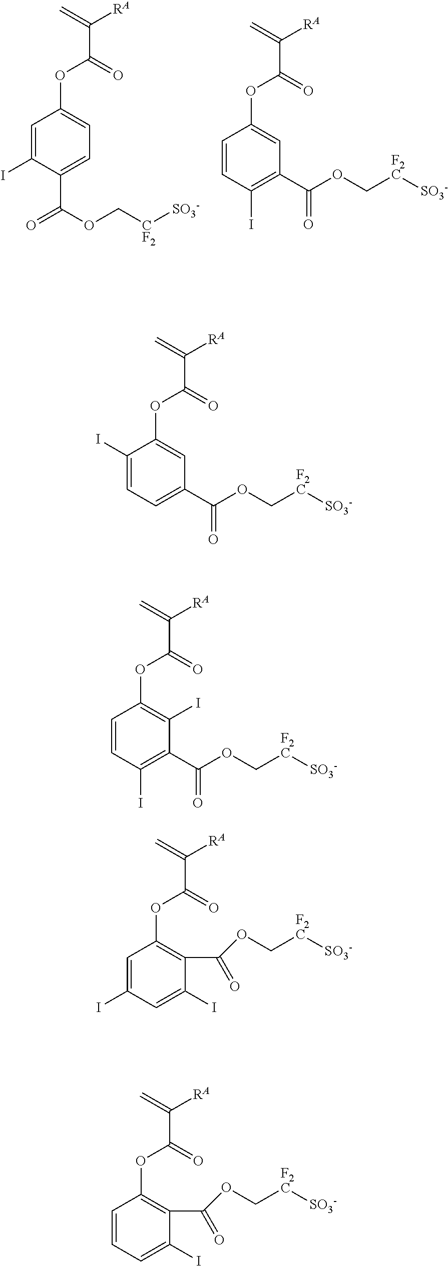

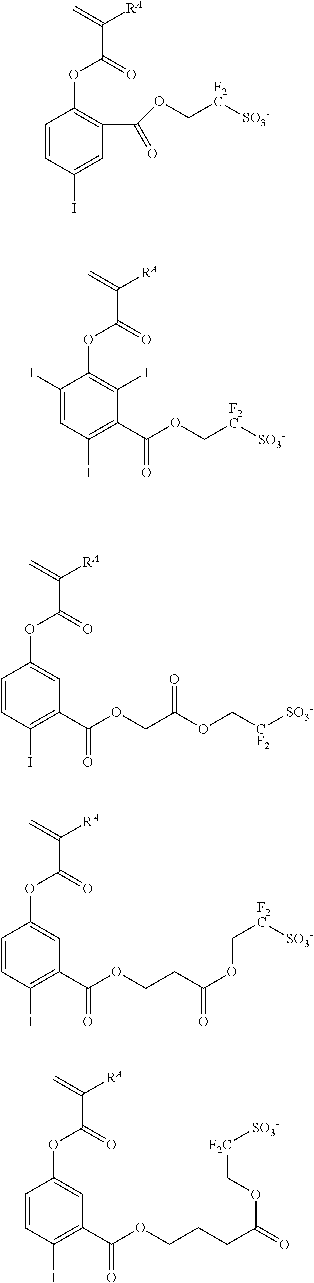

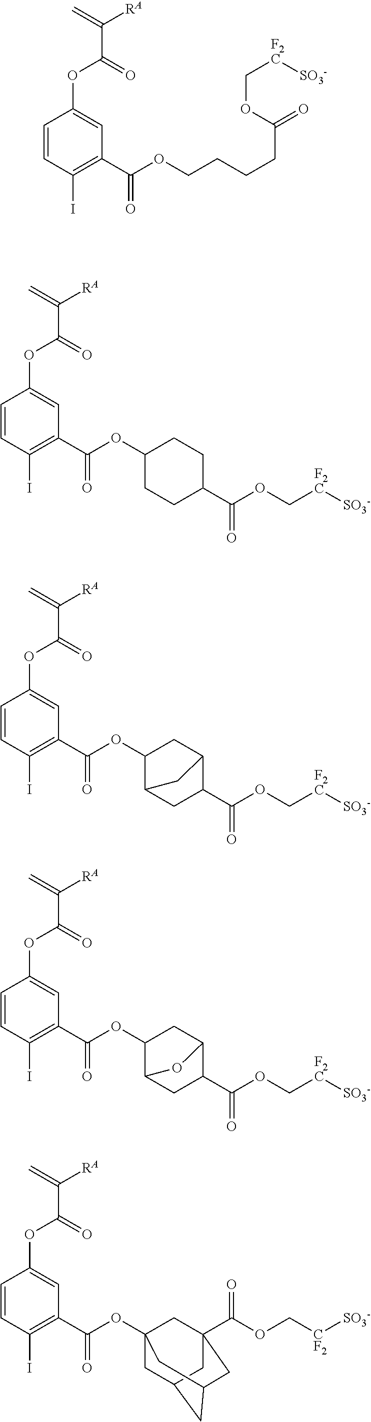

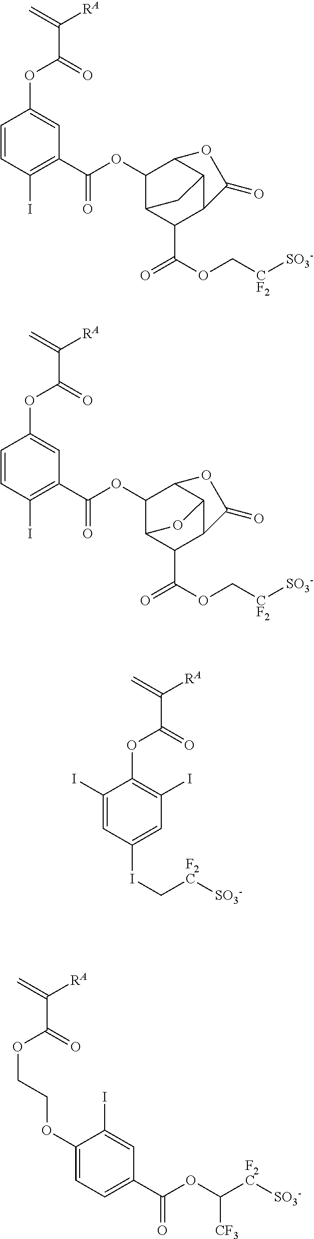

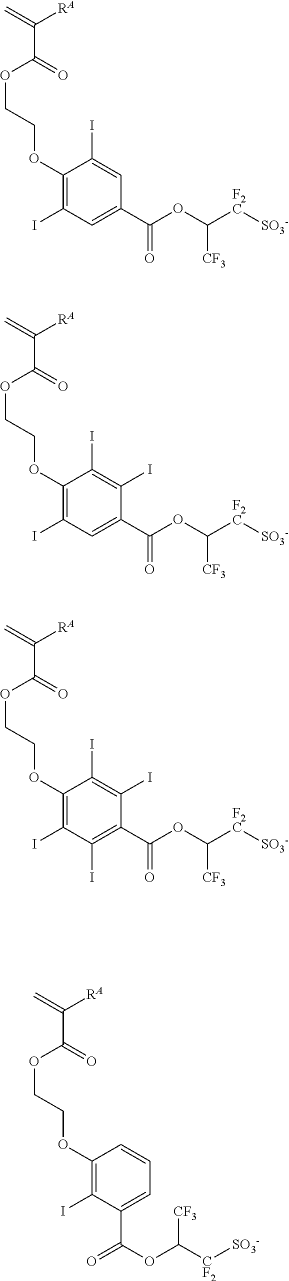

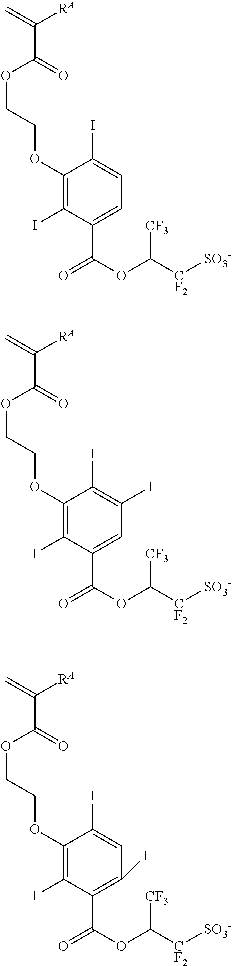

Examples of the anion of the monomer from which repeat units d3 are derived are shown below, but not limited thereto. In the following formula, R^{A} is as defined above.

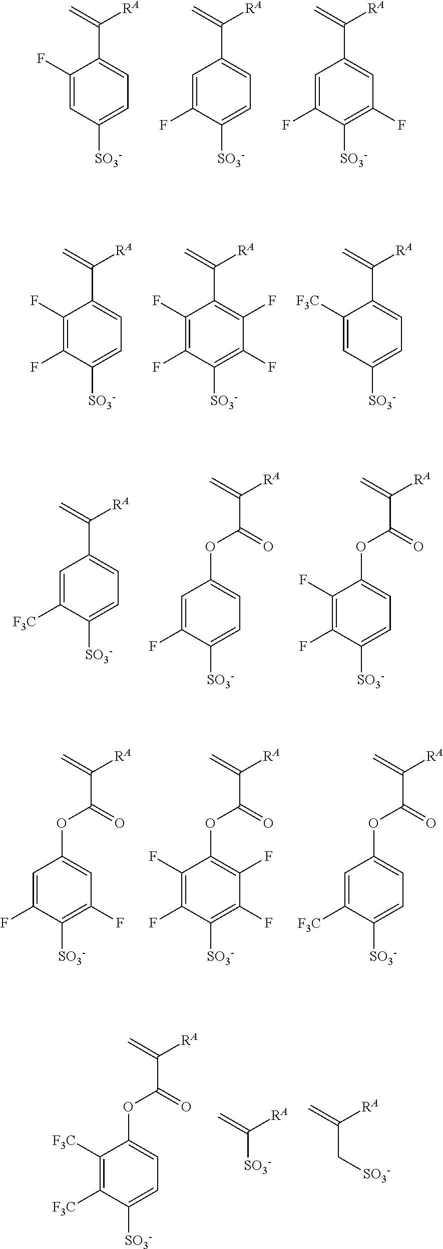

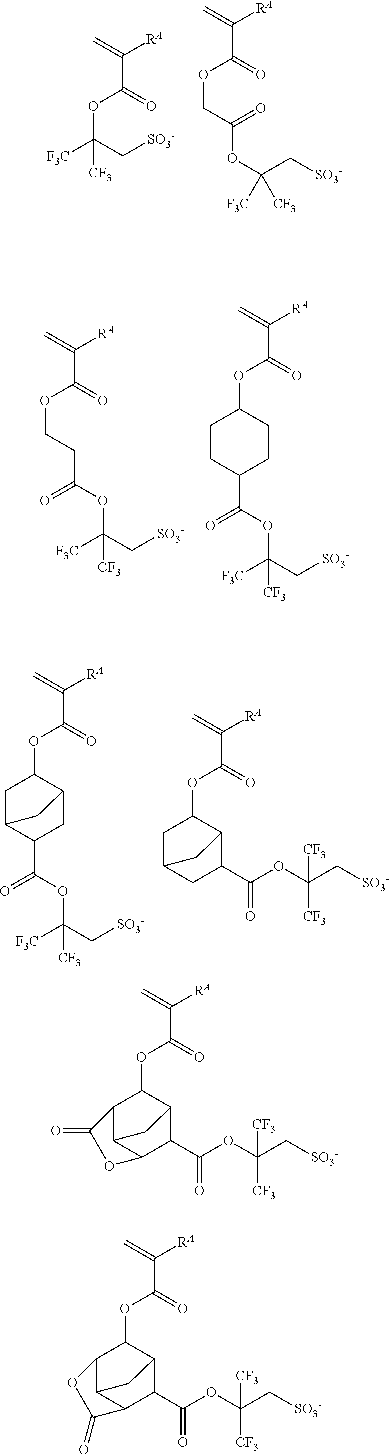

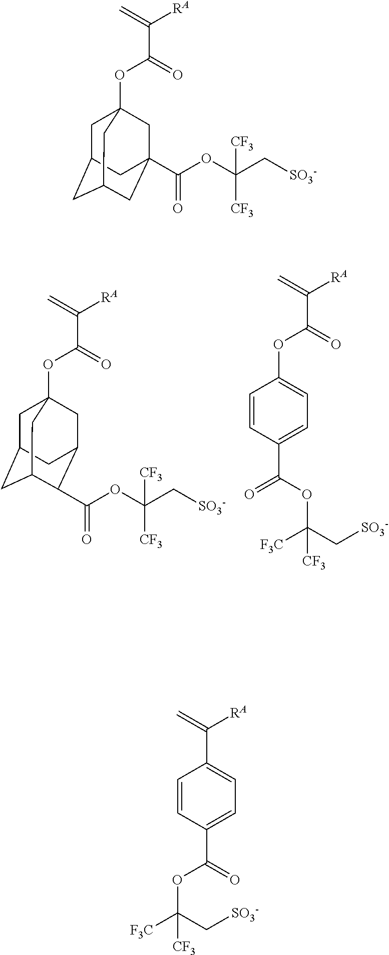

The repeat units d1 to d3 function as acid generators. The attachment of an acid generator to the polymer main chain is effective in restraining acid diffusion, thereby preventing a reduction of resolution due to blur by acid diffusion. Edge roughness or CDU is improved since the acid generator is uniformly distributed. In the case of using the base polymer including the repeat units d1 to d3 (that is, a polymer-bound acid generator), the blending of an acid generator of addition type described below may be omitted.

The polymer A may include a repeat unit e containing an iodine atom. Examples of the monomer from which repeat units e are derived are shown below, but not limited thereto. In the following formula, R^{A} is as defined above.

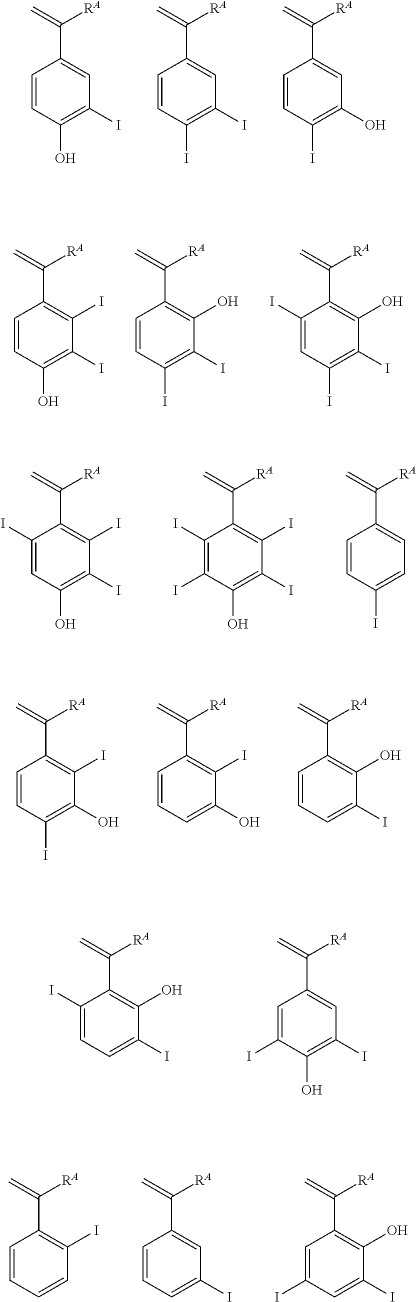

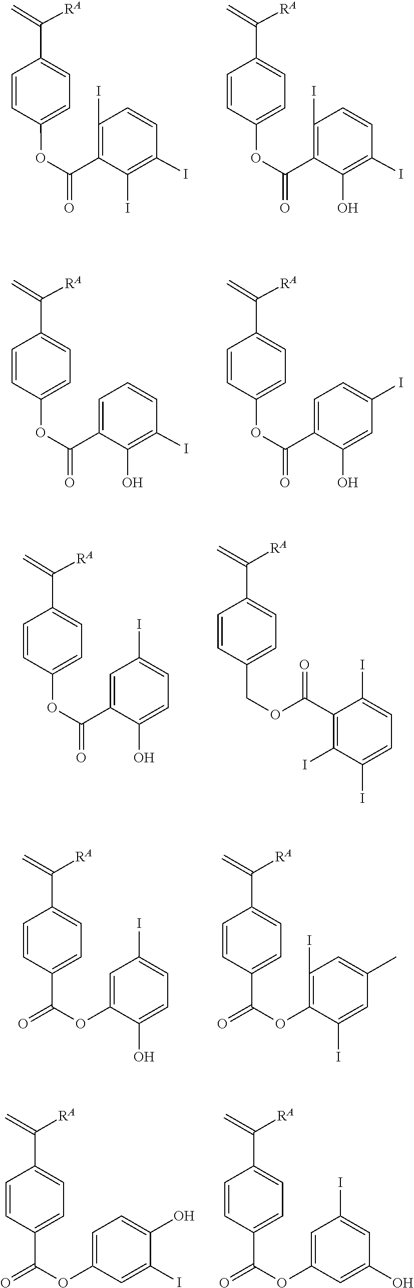

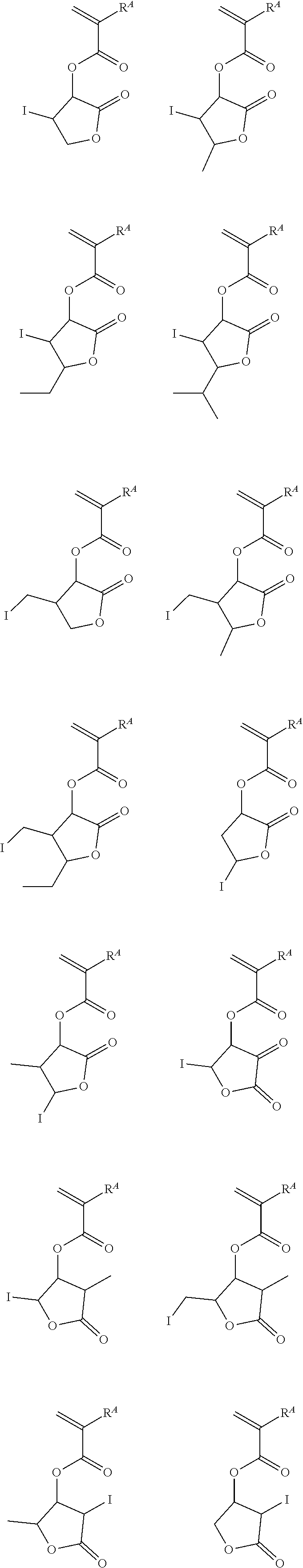

The polymer A may include repeat units f other than the repeat units described above. Examples of the repeat units f include those derived from styrene, vinylnaphthalene, indene, acenaphthylene, coumarin, coumarone, and the like.

In the polymer A, a fraction of repeat units a1, a2, b, c, d1, d2, d3, e, and f is: preferably 0<a1<1.0, 0≤a2≤0.9, 0<b<1.0, 0.1≤a1+b≤1.0, 0≤c≤0.9, 0≤d1≤0.5, 0≤d2≤0.5, 0≤d3≤0.5, 0≤d1+d2+d3≤0.5, 0≤e≤0.5, and 0≤f≤0.5; more preferably 0.2≤a1≤0.9, 0≤a2≤0.7, 0.05≤b≤0.7, 0.2≤a1+b≤1.0, 0≤c≤0.8, 0≤d1≤0.4, 0≤d2≤0.4, 0≤d3≤0.4, 0≤d1+d2+d3≤0.4, 0≤e≤0.4, and 0≤f≤0.4; and further preferably 0.3≤a1≤0.8, 0≤a2≤0.6, 0.08≤b≤0.6, 0.3≤a1+b≤1.0, 0≤c≤0.7, 0≤d1≤0.3, 0≤d2≤0.3, 0≤d3≤0.3, 0≤d1+d2+d3≤0.3, 0≤e≤0.3, and 0≤f≤0.3. Provided that a1+a2+b+c+d1+d2+d3+e+f=1.0.

For synthesizing the base polymer, for example, monomers from which the foregoing repeat units are derived are heated in an organic solvent with a radical polymerization initiator, and as necessary a chain transfer agent, added thereto to perform polymerization. The polymerization initiator and the chain transfer agent may be added at the start of polymerization, may be added during polymerization, or may be gradually added during polymerization. After a polymer having no maleimide group is synthesized, a maleimide group may be introduced into the side chain using a known reaction.

The weight average molecular weight (Mw) of the base polymer in terms of polystyrene by gel permeation chromatography (GPC) using THF as a solvent is preferably 1000 to 500000 and more preferably 2000 to 30000. If the Mw is in the above range, the heat resistance of the resist film and the solubility of the resist film in an alkaline developer are favorable.

If a base polymer has a wide molecular weight distribution (Mw/Mn) is wide in the base polymer, since a low-molecular-weight or high-molecular-weight polymer is present, foreign matter may be observed on the pattern or pattern profile may be degraded after exposure. Since the influences of Mw and Mw/Mn become stronger as the pattern rule becomes finer, the Mw/Mn of the base polymer preferably has narrow dispersity of 1.0 to 2.0, especially 1.0 to 1.5, in order to obtain a resist composition suitable for micropatterning to a small feature size.

The base polymer may contain two or more of the polymers which differ in compositional ratio, molecular weight distribution, or molecular weights, or may contain the polymer and a polymer having no repeat unit b.

### [Other Components]

The resist composition of the present invention preferably further contains an organic solvent, an acid generator, a quencher, a crosslinker, a surfactant, and the like in appropriate combination according to the purpose. By forming the resist composition in this manner, the dissolution rate of the polymer in the developer decreases due to the catalytic reaction in exposed areas, so that a resist composition capable of forming an extremely high-contrast negative tone pattern can be obtained. Therefore, the resist film has a high dissolution contrast, resolution, exposure latitude, and excellent process adaptability, provides more excellent etching resistance while having a good pattern profile after exposure, and minimal proximity bias because of restrained acid diffusion. By virtue of these advantages, the composition is fully useful in commercial application and suited as a resist composition for the fabrication of VLSIs. In particular, if a chemically amplified negative resist composition containing an acid generator and using acid catalytic reaction is used, it is possible to have higher sensitivity, and various characteristics are further excellent, which is extremely useful.

The organic solvent is not particularly limited as long as each component described above and each component described below can be dissolved. Examples of the organic solvent include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as 7-butyrolactone, which are described in JP-A 2008-111103, paragraphs [0144] to [0145].

When the resist composition of the present invention contains the organic solvent, the content thereof is preferably 50 to 10000 parts by weight and more preferably 100 to 5000 parts by weight per 100 parts by weight of the base polymer. The organic solvent may be used alone or in admixture of two or more kinds thereof.

Examples of the acid generator include a compound (photoacid generator) capable of generating a strong acid in response to actinic ray or radiation. The strong acid as used herein refers to a compound having a sufficient acidity to induce deprotection reaction of an acid labile group on the base polymer.

The component of the photoacid generator may be any compound capable of generating an acid upon exposure to high-energy radiation. Suitable photoacid generators include sulfonium salts, iodonium salts, sulfonyldiazomethane, N-sulfonyloxyimide, and oxime-O-sulfonate acid generators. Specific examples of the photoacid generator include those described in JP-A 2008-111103, paragraphs [0122] to [0142].

As the photoacid generator, sulfonium salts having the following formula (1-1) and iodonium salts having the following formula (1-2) can also be suitably used.

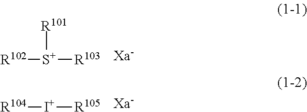

In formulae (1-1) to (1-2), R¹⁰¹ to R¹⁰⁵ are each independently a halogen atom, or a C₁-C₂₀ hydrocarbyl group which may contain a heteroatom.

Examples of the halogen atom represented by R¹⁰¹ to R¹⁰⁵ include a fluorine atom, a chlorine atom, a bromine atom, and an iodine atom.

The C₁-C₂₀ hydrocarbyl group represented by R¹⁰¹ to R¹⁰⁵ may be saturated or unsaturated and straight, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining these.

Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a mercapto group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

A pair of R¹⁰¹ and R¹⁰² may bond together to form a ring with a sulfur atom to which they are attached. In this case, the ring preferably has the following structure.

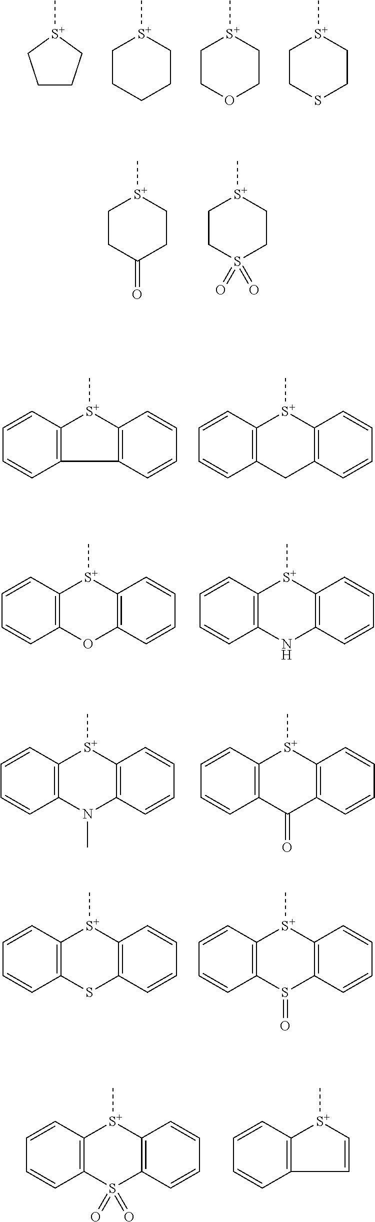

wherein the broken line denotes a point of attachment to R¹⁰³.

Specific examples of the cation of the sulfonium salt having formula (1-1) are as exemplified above for the cation of the sulfonium salt having formula (A-1) in JP-A 2022-173075. Specific examples of the cation of the iodonium salt having formula (1-2) are as exemplified above for the cation of the iodonium salt having formula (A-2) in JP-A 2022-173075.

In formulae (1-1) and (1-2), Xa⁻ is a non-nucleophilic counter ion.

As the photoacid generator, sulfonium salts having the following formula (1-3) can also be suitably used.

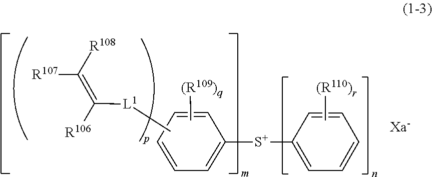

In formula (1-3), m and n are integers satisfying 1≤m≤3, 0≤n≤2, and m+n=3. p is 1 or 2, q is an integer of 0 to 4, and r is an integer of 0 to 5.

In formula (1-3), L¹ is a single bond, an ester bond, an ether bond, an amide bond, a urethane bond, or a C₁-C₁₀ alkylene group, and some of —CH₂— in the alkylene group may be substituted with an ester bond, an ether bond, an amide bond, or a urethane bond.

In formula (1-3), R¹⁰⁶ to R¹⁰⁸ are each independently a hydrogen atom, a halogen atom, or a C₁-C₄₀ saturated hydrocarbyl group, and some or all of the hydrogen atoms in the saturated hydrocarbyl group may be substituted with a fluorine atom or a hydroxy group. The saturated hydrocarbyl group may be straight, branched, or cyclic.

In formula (1-3), R¹⁰⁹ and R¹¹⁰ are each independently a halogen atom, a cyano group, a nitro group, a mercapto group, a sulfo group, a C₁-C₁₀ saturated hydrocarbyl group, or a C₇-C₂₀ aralkyl group, and the saturated hydrocarbyl group and the aralkyl group may contain an oxygen atom, a sulfur atom, a nitrogen atom, or a halogen atom. Two R¹⁰⁹ or two R¹⁰⁶ may bond together to form a ring with the benzene ring to which they are attached, and R¹⁰⁹ and R¹¹⁰ may bond together to form a ring with the benzene rings to which they are attached and the intervening sulfur atom.

In formula (1-3), Xa⁻ is a non-nucleophilic counter ion.

Specific examples of the cation of the sulfonium salt having formula (1-3) are as exemplified above for the cation of the sulfonium salt having formula (A) in JP-A 2023-010602.

Examples of the non-nucleophilic counter ion represented by Xa⁻ in formulae (1-1) to (1-3) include anions having the following formulae (1A) to (1D).

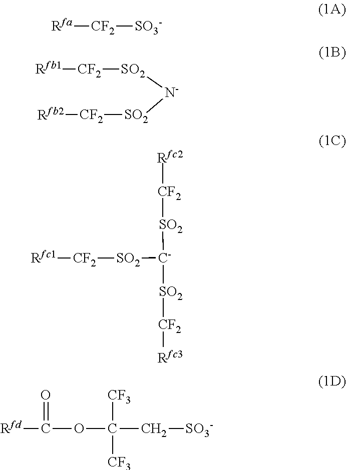

In formula (1A), R^{fa} is a fluorine atom, or a C₁-C₄₀ hydrocarbyl group which may contain a heteroatom. The hydrocarbyl group may be saturated or unsaturated and straight, branched, or cyclic. Specific examples thereof are as will be exemplified later for the hydrocarbyl group represented by R^{fa1} in formula (1A′) described below.

The anion having formula (1A) preferably has the following formula (1A′).

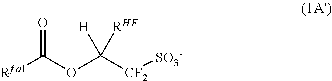

In formula (2A′), R^{HF} is a hydrogen atom or a trifluoromethyl group and preferably a trifluoromethyl group. R^{fa1} is a C₁-C₃₈ hydrocarbyl group which may contain a heteroatom. The heteroatom is preferably an oxygen atom, a nitrogen atom, a sulfur atom, a halogen atom, or the like, and more preferably an oxygen atom. The hydrocarbyl group is particularly preferably a C₆-C₃₀ hydrocarbyl group from the viewpoint of obtaining a high resolution in fine pattern formation.

The hydrocarbyl group represented by R^{fa1} may be saturated or unsaturated and straight, branched, or cyclic. Specific examples thereof include C₁-C₃₈ alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; C₃-C₃₈ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanyl group, and a dicyclohexylmethyl group; C₂-C₃₈ unsaturated aliphatic hydrocarbyl groups such as an allyl group and a 3-cyclohexenyl group; C₆-C₃₈ aryl groups such as a phenyl group, a 1-naphthyl group, and a 2-naphthyl group; C₇-C₃₈ aralkyl groups such as a benzyl group and a diphenylmethyl group; and groups obtained by combining these.

Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like. Examples of the heteroatom-containing hydrocarbyl group include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

With respect to the synthesis of the sulfonium salt having an anion of formula (1A′), reference is made to JP-A 2007-145797, JP-A 2008-106045, JP-A 2009-7327, JP-A 2009-258695, and the like. Also useful are the sulfonium salts described in JP-A 2010-215608, JP-A 2012-41320, JP-A 2012-106986, JP-A 2012-153644, and the like.

Examples of the anion having formula (1A) are as exemplified for the anion having formula (1A) in JP-A 2018-197853.

In formula (1B), R^{fb1} and R^{fb2} are each independently a fluorine atom, or a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (1A′). Preferably, R^{fb1} and R^{fb2} each are a fluorine atom or a straight C₁-C₄ fluorinated alkyl group. A pair of R^{fb1} and R^{fb2} may bond together to form a ring with the group (—CF₂—SO₂—N—SO₂—CF₂—) to which they are attached, and in this case, the group obtained by bonding the pair of R^{fb1} and R^{fb2} to each other is preferably a fluorinated ethylene group or a fluorinated propylene group.

In formula (1C), R^{fc1}, R^{fc2}, and R^{fc3} are each independently a fluorine atom, or a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (1A′). Preferably, R^{fc1}, R^{fc2}, and R^{fc3} each are a fluorine atom or a straight C₁-C₄ fluorinated alkyl group. A pair of R^{fc1} and R^{fc2} may bond together to form a ring with the group (—CF₂—SO₂—C⁻—SO₂—CF₂—) to which they are attached, and in this case, the group obtained by bonding the pair of R^{fc1} and R^{fc2} to each other is preferably a fluorinated ethylene group or a fluorinated propylene group.

In formula (1D), R^{fd} is a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (2A′).

With respect to the synthesis of the sulfonium salt having an anion of formula (1D), reference is made to JP-A 2010-215608 and JP-A 2014-133723.

Examples of the anion having formula (1D) are as exemplified for the anion having formula (1D) in JP-A 2018-197853.

The photoacid generator having the anion of formula (1D) has a sufficient acidity to cleave acid labile groups in the base polymer because it is free of a fluorine atom at α-position of the sulfo group, but has two trifluoromethyl groups at β-position. Thus, it can be used as a photoacid generator.

Other examples of the non-nucleophilic counter ion include an anion having an aromatic ring substituted with an iodine atom or a bromine atom. Examples of such an anion include those having the following formula (1E).

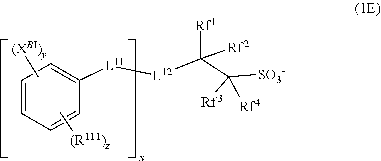

In formula (1E), x is an integer satisfying 1≤x≤3. y and z are integers satisfying 1≤y≤5, 00≤z≤3, and 1≤y+z≤5. y is preferably an integer satisfying 1≤y≤3 and more preferably 2 or 3. z is preferably an integer satisfying 0≤z≤2.

In formula (1E), X^{BI} is an iodine atom or a bromine atom, and may be the same or different when x and/or y is 2 or more.

In formula (1E), L¹¹ is a single bond, an ether bond, an ester bond, or a C₁-C₆ saturated hydrocarbylene group which may contain an ether bond or an ester bond. The saturated hydrocarbylene group may be straight, branched, or cyclic.

In formula (1E), L¹² is a single bond or a C₁-C₂₀ divalent linking group when x is 1, and a C₁-C₂₀ (x+1)-valent linking group which may contain an oxygen atom, a sulfur atom, or a nitrogen atom when x is 2 or 3.

In formula (1E), R¹¹¹ is a hydroxy group, a carboxy group, a fluorine atom, a chlorine atom, a bromine atom, an amino group, a C₁-C₂₀ hydrocarbyl group, C₁-C₂₀ hydrocarbyloxy group, C₂-C₂₀ hydrocarbylcarbonyl group, C₂-C₁₀ hydrocarbyloxycarbonyl group, C₂-C₂₀ hydrocarbylcarbonyloxy group, or C₁-C₂₀ hydrocarbylsulfonyloxy group, which may contain a fluorine atom, a chlorine atom, a bromine atom, a hydroxy group, an amino group, or an ether bond, or —N(R^{111A})(R^{111B}), —N(R^{111C})—C(═O)—R^{111D} or —N(R^{111C})—C(═O)—O—R^{111D}. R^{111A} and R^{111B} are each independently a hydrogen atom or a C₁-C₆ saturated hydrocarbyl group. R^{111C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{111D} is a C₁-C₁₆ aliphatic hydrocarbyl group, a C₆-C₁₂ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated and straight, branched, or cyclic. The hydrocarbyl group, the hydrocarbyloxy group, the hydrocarbylcarbonyl group, the hydrocarbyloxycarbonyl group, the hydrocarbylcarbonyloxy group, and hydrocarbylsulfonyloxy group may be straight, branched, or cyclic. When x and/or z is 2 or more, respective R¹¹¹ may be the same as or different from each other.

Of these, R¹¹¹ is preferably a hydroxy group, —N(R^{111C})—C(═O)—R^{111D}, —N(R^{111C})—C(═O)—O—R^{111D}, a fluorine atom, a chlorine atom, a bromine atom, a methyl group, a methoxy group, or the like.

In formula (1E), R^{f1} to R^{f4} are each independently a hydrogen atom, a fluorine atom, or a trifluoromethyl group, and at least one of R^{f1} to R^{f4} is a fluorine atom or a trifluoromethyl group. Rf¹ and Rf², taken together, may form a carbonyl group. Preferably, both Rf³ and Rf⁴ are a fluorine atom.

Examples of the anion having formula (1E) are as exemplified for the anion of the sulfonium salt or iodonium salt having formula (4-1) or (4-2) in JP-A 2022-191163.

Other examples of the non-nucleophilic counter ion include those having the following formula (1F).

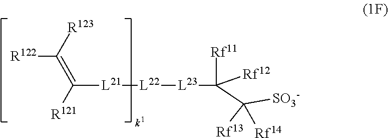

In formula (1F), k¹ is an integer satisfying 0≤k¹≤4.

In formula (1F), L²¹ is a single bond, an ester bond, an ether bond, an amide bond, or a urethane bond.

In (1F), L²² is a C₁-C₄₀ hydrocarbyl group which may contain a heteroatom when k¹ is 0, a single bond or a C₁-C₄₀ hydrocarbylene group which may contain a heteroatom when k¹ is 1, and a C₁-C₄₀ (k¹+1)-valent hydrocarbon group which may contain a heteroatom when k¹ is 2, 3, or 4.

The C₁-C₄₀ hydrocarbyl group, the C₁-C₄₀ hydrocarbylene group, and the C₁-C₄₀ (k¹+1)-valent hydrocarbon group represented by L²² may be saturated or unsaturated and straight, branched, or cyclic. Specific examples of the C₁-C₄₀ hydrocarbyl group include C₁-C₄₀ alkyl groups such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; C₃-C₄₀ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; C₂-C₄₀ unsaturated hydrocarbyl groups such as an allyl group, a 3-cyclohexenyl group, and a tetracyclododecenyl group; C₆-C₄₀ aryl groups such as a phenyl group, a 1-naphthyl group, and a 2-naphthyl group; C₇-C₄₀ aralkyl groups such as a benzyl group and a diphenylmethyl group; C₂₀-C₄₀ hydrocarbyl groups having a steroid skeleton, which may contain a heteroatom; and groups obtained by combining these. Specific examples of the C₁-C₄₀ hydrocarbylene group include those groups exemplified above for the hydrocarbyl group from which one hydrogen atom is further removed, and specific examples of the C₁-C₄₀ (k¹+1)-valent hydrocarbon group include those groups exemplified above for the hydrocarbyl group from which k¹ number of hydrogen atoms are further removed.

Some or all of the hydrogen atoms in the hydrocarbyl group, the hydrocarbylene group, and the (k¹+1)-valent hydrocarbon group may be substituted with a group containing a heteroatom such as an oxygen atom, a sulfur atom, a nitrogen atom, or a halogen atom, some of —CH₂— in the hydrocarbyl group, the hydrocarbylene group, and the (k¹+1)-valent hydrocarbon group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

In formula (1F), L²³ is a single bond, an ether bond, or an ester bond.

In formula (1F), R¹²¹ to R¹²³ are each independently a hydrogen atom, a halogen atom, or a C₁-C₄₀ saturated hydrocarbyl group, and some or all of the hydrogen atoms in the saturated hydrocarbyl group may be substituted with a fluorine atom or a hydroxy group.

The C₁-C₄₀ saturated hydrocarbyl group represented by R¹²¹ to R¹²³ may be straight, branched, or cyclic, and specific examples thereof include C₁-C₄₀ alkyl groups such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; and C₆-C₄₀ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group.

In formula (1F), Rf¹¹ to Rf¹⁴ are each independently a hydrogen atom, a fluorine atom, or a trifluoromethyl group, and at least one of Rf¹¹ to Rf¹⁴ is a fluorine atom or a trifluoromethyl group. Rf¹¹ and Rf¹², taken together, may form a carbonyl group.

Specific examples of the anion having formula (1F) are as exemplified above for the anion of the sulfonium salt having formula (A) in JP-A 2023-010602.

Other examples of the non-nucleophilic counter ion include those having the following formula (1G).

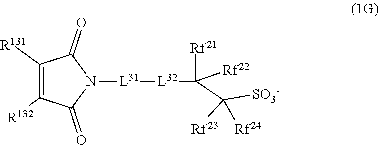

In formula (1G), L³¹ is a single bond or a C₁-C₂₀ hydrocarbylene group. The hydrocarbylene group may contain an oxygen atom, a sulfur atom, a nitrogen atom, or a halogen atom.

The C₁-C₂₀ hydrocarbylene group represented by L³¹ may be saturated or unsaturated and straight, branched, or cyclic. Specific examples thereof include C₁-C₂₀ alkanediyl groups such as a methanediyl group, an ethane-1,1-diyl group, an ethane-1,2-diyl group, a propane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; C₃-C₂₀ cyclic saturated hydrocarbylene groups such as a cyclopentanediyl group, a cyclohexanediyl group, a norbornanediyl group, and an adamantanediyl group; C₂-C₂₀ unsaturated aliphatic hydrocarbylene groups such as a vinylene group and a propene-1,3-diyl group; C₆-C₂₀ arylene groups such as a phenylene group and a naphthylene group; and groups obtained by combining these. Some or all of the hydrogen atoms in the hydrocarbylene group may be substituted with a group containing an oxygen atom, a sulfur atom, a nitrogen atom, or a halogen atom, some of —CH₂— in the hydrocarbylene group may be substituted with a group containing an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

In formula (1G), L³² is an ester bond or a C₁-C₈ alkanediyl group.

In formula (1G), R¹³¹ and R¹³² are each independently a hydrogen atom or a C₁-C₁₀ saturated hydrocarbyl group. The saturated hydrocarbyl group may be straight, branched, or cyclic, and specific examples thereof include C₁-C₁₀ alkyl groups such as a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, a nonyl group, and a decyl group; and C₃-C₁₀ cyclic saturated hydrocarbyl group such as a cyclopentyl group and a cyclohexyl group. R¹³¹ and R¹³² may bond together to form a ring with the carbon atom to which they are attached. The ring formed at this time is preferably a 5-membered ring or a 6-membered ring.

In formula (1G), Rf²¹ to Rf²⁴ are each independently a hydrogen atom, a fluorine atom, or a trifluoromethyl group, and at least one of Rf²¹ to R^{f4} is a fluorine atom or a trifluoromethyl group. Rf²¹ and Rf²², taken together, may form a carbonyl group.

Specific examples of the anion having formula (1G) are as exemplified above for the anion of the sulfonium salt having formula (A) in JP-A 2023-020941.

When the resist composition of the present invention contains the acid generator, the content thereof is preferably 0.01 to 100 parts by weight and more preferably 0.1 to 80 parts by weight per 100 parts by weight of the base polymer. The acid generator may be used alone or in combination of two or more kinds thereof.

Examples of the quencher include conventional basic compounds. The quencher refers to a compound capable of trapping the acid generated by the acid generator in the resist composition to prevent the acid from diffusing to the unexposed area. Examples of the conventional basic compounds include primary, secondary, and tertiary aliphatic amines, mixed amines, aromatic amines, heterocyclic amines, nitrogen-containing compounds with a carboxy group, nitrogen-containing compounds with a sulfonyl group, nitrogen-containing compounds with a hydroxy group, nitrogen-containing compounds with a hydroxyphenyl group, alcoholic nitrogen-containing compounds, amides, imides, and carbamates. In particular, primary, secondary, and tertiary amine compounds, specifically amine compounds having a hydroxy group, an ether bond, an ester bond, a lactone ring, a cyano group, or a sulfonate bond as described in JP-A 2008-111103, paragraphs [0146] to [0164], compounds having a carbamate group as described in JP 3790649, and the like are preferred. Addition of such a basic compound can be effective for further suppressing the diffusion rate of acid in the resist film or correcting the pattern profile.

Examples of the quencher include onium salts such as sulfonium, iodonium and ammonium salts of sulfonic acids which are not fluorinated at α-position as described in JP-A 2008-158339, and similar onium salts of carboxylic acid. While an α-fluorinated sulfonic acid, imide acid, and methide acid are necessary to deprotect the acid labile group of carboxylic acid ester, and an α-non-fluorinated sulfonic acid and a carboxylic acid are released by salt exchange with an α-non-fluorinated onium salt. An α-non-fluorinated sulfonic acid and a carboxylic acid function as a quencher because they do not induce deprotection reaction.

Examples of such a quencher include a compound having the following formula (2) (an onium salt of α-non-fluorinated sulfonic acid) and a compound having the following formula (3) (an onium salt of carboxylic acid).

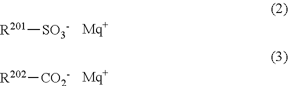

In formula (2), R²⁰¹ is a hydrogen atom or a C₁-C₄₀ hydrocarbyl group which may contain a heteroatom, exclusive of the hydrocarbyl group in which the hydrogen atom bonded to the carbon atom at α-position of the sulfo group is substituted with a fluorine atom or a fluoroalkyl group.

The C₁-C₄₀ hydrocarbyl group may be saturated or unsaturated and straight, branched, or cyclic. Specific examples thereof include C₁-C₄₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; C₂-C₄₀ alkenyl groups such as a vinyl group, an allyl group, a propenyl group, a butenyl group, and a hexenyl group; C₃-C₄₀ cyclic unsaturated aliphatic hydrocarbyl groups such as a cyclohexenyl group; C₆-C₄₀ aryl groups such as a phenyl group, a naphthyl group, an alkylphenyl group (such as a 2-methylphenyl group, a 3-methylphenyl group, a 4-methylphenyl group, a 4-ethylphenyl group, a 4-tert-butylphenyl group, or a 4-n-butylphenyl group), a dialkylphenyl group (such as a 2,4-dimethylphenyl group or a 2,4,6-triisopropylphenyl group), an alkylnaphthyl group (such as a methylnaphthyl group or an ethylnaphthyl group), and a dialkylnaphthyl group (such as a dimethylnaphthyl group or a diethylnaphthyl group); and C₇-C₄₀ aralkyl groups such as a benzyl group, a 1-phenylethyl group, and a 2-phenylethyl group.

Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a cyano group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like. Examples of the hydrocarbyl group containing a heteroatom include heteroaryl groups such as a thienyl group; alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, a n-propoxynaphthyl group, and a n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group, and a 2-(2-naphthyl)-2-oxoethyl group.

In formula (3), R²⁰² is a C₁-C₄₀ hydrocarbyl group which may contain a heteroatom. Examples of the hydrocarbyl group represented by R²⁰² are as exemplified above for the hydrocarbyl group represented by R²⁰¹. Other specific examples thereof include fluorinated alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group; and fluorinated aryl groups such as a pentafluorophenyl group and a 4-trifluoromethylphenyl group.

In formulae (2) and (3), Mq⁺ is an onium cation. The onium cation is preferably sulfonium cations, iodonium cations, or ammonium cations, and more preferably sulfonium cations or iodonium cations. Examples of the sulfonium cations are as exemplified above for the cation of the sulfonium salt having formula (1-1) and the cation of the sulfonium salt having formula (1-3). Examples of the iodonium cations are as exemplified above for the cation of the sulfonium salt having formula (1-2).

Other examples of the quencher include a sulfonium salt containing an anion having the following formula (4).

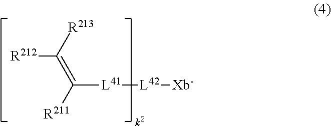

In formula (4), k² is an integer satisfying 0≤k²≤4.

In formula (4), X⁻ is —SO₃⁻, —CO₂⁻, —N⁻—SO₂—R^{F}, or —O⁻. R^{F} is a fluorine atom or a C₁-C₃₀ fluorinated hydrocarbyl group, and the fluorinated hydrocarbyl group may contain at least one selected from a hydroxy group, a carboxy group, a carbonyl group, an ether bond, an ester bond, and an amide bond.

In formula (4), L⁴¹ is a single bond, an ester bond, an ether bond, an amide bond, or a urethane bond.

In formula (4), L⁴² is a C₁-C₄₀ hydrocarbyl group which may contain a fluorine atom or a heteroatom when k² is 0 and X⁻ is —CO₂⁻, a C₁-C₄₀ hydrocarbyl group which may contain a hydrogen atom or a heteroatom when k² is 0 and X⁻ is —N—SO₂—R^{F}, a C₁-C₄₀ hydrocarbyl group which may contain a heteroatom when k² is 0 and X⁻ is —SO₃⁻ or —O⁻, a single bond or a C₁-C₄₀ hydrocarbylene group which may contain a heteroatom when k² is 1, and a C₁-C₄₀ (k²+1)-valent hydrocarbon group which may contain a heteroatom when k² is 2, 3, or 4. However, when X⁻ is —SO₃⁻, X² is not fluorinated at α- and β-positions of —SO₃⁻, and when X⁻ is —O⁻, the carbon atom to which —O⁻ is attached is not a carbon atom on an aromatic ring.

The C₁-C₄₀ hydrocarbyl group, the C₁-C₄₀ hydrocarbylene group, and the C₁-C₄₀ (k²+1)-valent hydrocarbon group represented by L⁴² may be saturated or unsaturated and straight, branched, or cyclic. Specific examples thereof are as exemplified above for the C₁-C₄₀ hydrocarbyl group, the C₁-C₄₀ hydrocarbylene group, and the C₁-C₄₀ (k¹+1)-valent hydrocarbon group represented by L²² in formula (1F).

Some or all of the hydrogen atoms in the hydrocarbyl group, the hydrocarbylene group, and the (k²+1)-valent hydrocarbon group may be substituted with a group containing a heteroatom such as an oxygen atom, a sulfur atom, a nitrogen atom, or a halogen atom, some of —CH₂— in the hydrocarbyl group, the hydrocarbylene group, and the (k²+1)-valent hydrocarbon group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

In formula (A), R²¹¹ to R²¹³ are each independently a hydrogen atom, a halogen atom, or a C₁-C₄₀ saturated hydrocarbyl group, some or all of the hydrogen atoms in the saturated hydrocarbyl group may be substituted with a fluorine atom or a hydroxy group, some of —CH₂— in the saturated hydrocarbyl group may be substituted with an ether bond or an ester bond, and some of the carbon-carbon bonds in the saturated hydrocarbyl group may be a double bond. The saturated hydrocarbyl group may be straight, branched, or cyclic, and specific examples thereof include are as exemplified above for the C₁-C₄₀ saturated hydrocarbyl group represented by R¹²¹ to R¹²³ in formula (1F).

Specific examples of the anion having formula (4) are as exemplified above for the anion of the sulfonium salt having formula (A) in JP-A 2023-013979.

Examples of the cation of the sulfonium salt having an anion of formula (4) are as exemplified above for the cation of the sulfonium salt having formula (1-1) or the cation of the sulfonium salt having formula (1-3).

Other examples of the quencher include a sulfonium salt containing an anion having the following formula (5).

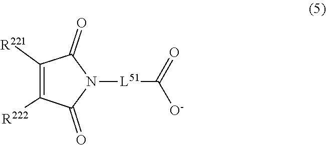

In formula (5), L⁵¹ is a single bond or a C₁-C₂₀ hydrocarbylene group. The hydrocarbylene group may contain an oxygen atom, a sulfur atom, a nitrogen atom, or a halogen atom. The hydrocarbylene group may be saturated or unsaturated and straight, branched, or cyclic. Specific examples thereof are as exemplified above for the C₁-C₂₀ hydrocarbylene group represented by L³¹ in formula (1G).

In formula (5), R²²¹ and R²²² are each independently a hydrogen atom or a C₁-C₁₀ saturated hydrocarbyl group. R²²¹ and R²²² may bond together to form a ring with the carbon atom to which they are attached. The saturated hydrocarbyl group may be straight, branched, or cyclic, and specific examples thereof include are as exemplified above for the C₁-C₁₀ saturated hydrocarbyl group represented by R¹³¹ and R¹³² in formula (1G).

Specific examples of the anion having formula (5) are as exemplified above for the anion of the sulfonium salt having formula (1) in JP-A 2023-002462.

Examples of the cation of the sulfonium salt having an anion of formula (5) are as exemplified above for the cation of the sulfonium salt having formula (1-1) or the cation of the sulfonium salt having formula (1-3).

Examples of the quencher further include quenchers of polymer type as described in JP-A 2008-239918. The polymeric quencher segregates at the surface of the resist film and thus enhances the rectangularity of resist pattern. When a protective film is applied as is often the case in the immersion lithography, the polymeric quencher is also effective for preventing a film thickness loss of resist pattern or rounding of pattern top.

When the resist composition of the present invention contains the quencher, the content thereof is preferably 0 to 30 parts by weight and more preferably 0 to 20 parts by weight per 100 parts by weight of the base polymer. The quencher may be used alone or in combination of two or more kinds thereof.

Inclusion of the surfactant can further improve or control the coating characteristics of the resist composition. Specific examples of the surfactant include those described in JP-A 2008-111103, paragraphs [0165] to [0166]. When the resist composition of the present invention contains the surfactant, the content thereof is preferably 0 to 10 parts by weight and more preferably 0.0001 to 5 parts by weight per 100 parts by weight of the base polymer.

Inclusion of the crosslinker can further increase a difference in dissolution rate between exposed and unexposed areas of the resist film. However, there is also a risk that the swelling of the resist film in the developer increases. Specific examples of the crosslinker include those described in JP-A 2020-027297, paragraphs [0170] to [0177]. When the resist composition of the present invention contains the crosslinker, the content thereof is preferably 0 to 30 parts by weight and more preferably 0 to 20 parts by weight per 100 parts by weight of the base polymer.

The resist composition of the present invention may contain a water repellency improver in order to improve the water repellency of the resist film. The water repellency improver can be used in the topcoatless immersion lithography. The water repellency improver is preferably polymers having a fluoroalkyl group, polymers of specific structure having a 1,1,1,3,3,3-hexafluoro-2-propanol residue, or the like, and is more preferably those described in JP-A 2007-297590, JP-A 2008-111103, and the like. The water repellency improver should be soluble in the organic solvent developer. The water repellency improver of specific structure having a 1,1,1,3,3,3-hexafluoro-2-propanol residue is well soluble in the developer. As the water repellency improver, a polymer including repeat units having an amino group or amine salt is highly effective for preventing evaporation of acid during post exposure bake (PEB) and preventing any hole pattern opening failure after development. When the resist composition of the present invention contains the water repellency improver, the content thereof is preferably 0 to 20 parts by weight and more preferably 0.5 to 10 parts by weight per 100 parts by weight of the base polymer. The water repellency improver may be used alone or in combination of two or more kinds thereof.

The resist composition of the present invention may further contain an acetylene alcohol. Examples of the acetylene alcohol include those described in JP-A 2008-122932, paragraphs [0179] to [0182]. When the resist composition of the present invention contains the acetylene alcohol, the compounding amount thereof is preferably 0 to 5 parts by weight per 100 parts by weight of the base polymer. The acetylene alcohol may be used alone or in combination of two or more kinds thereof.

### [Pattern Forming Process]

When the resist composition of the present invention is used in the fabrication of various integrated circuits, well-known lithography processes can be applied. Examples of the pattern forming process include a process including the steps of applying the above-described resist composition onto a substrate to form a resist film on the substrate, exposing the resist film to high-energy radiation, and developing the exposed resist film in a developer.

The resist composition of the present invention is first applied onto a substrate on which an integrated circuit is to be formed (such as Si, SiO₂, SiN, SiON, TiN, WSi, BPSG, SOG, or organic antireflective coating) or a substrate on which a mask circuit is to be formed (such as Cr, CrO, CrON, CrN, MoSi2, SiO₂, Ta, MoSi laminated film, Ru, Ni, Co, W, Mo, V, and alloys thereof) by a suitable coating technique such as spin coating, roll coating, flow coating, dip coating, spray coating, or doctor coating so as to have a coating film thickness of 0.01 to 2 μm. The coating is prebaked on a hotplate preferably at 60 to 150° C. for 10 seconds to 30 minutes, more preferably at 80 to 120° C. for 30 seconds to 20 minutes to form a resist film.

The resist film is then exposed using high-energy radiation. Examples of the high-energy radiation include ultraviolet rays, far ultraviolet rays, EB, EUV having a wavelength of 3 to 15 nm, X-rays, soft X-rays, excimer laser light, γ-rays, and synchrotron radiation. When ultraviolet rays, far ultraviolet rays, EUV, X-rays, soft X-rays, excimer laser light, γ-rays, synchrotron radiation, or the like is used as the high-energy radiation, the resist film is exposed thereto directly or through a mask for forming a target pattern in an exposure dose of preferably about 1 to 200 mJ/cm², more preferably about 10 to 100 mJ/cm². When EB is used as the high-energy radiation, the resist film is exposed thereto directly or through a mask for forming a target pattern in an exposure dose of preferably about 0.1 to 800 μC/cm², more preferably about 0.5 to 500 μC/cm². The resist composition of the present invention is particularly suitable for micropatterning using i-rays, KrF excimer laser light, ArF excimer laser light, EB, EUV, X-rays, soft X-rays, γ-rays, or synchrotron radiation among the high-energy radiations, especially in micropatterning using EB or EUV.

After the exposure, PEB may or may not be performed on a hotplate in an oven preferably at 30 to 150° C. for 10 seconds to 30 minutes, more preferably at 50 to 120° C. for 30 seconds to 20 minutes.

After the exposure or PEB, organic solvent development is carried out to form a negative tone pattern. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents may be used alone or in admixture of two or more kinds thereof.

At the end of development, the resist film is rinsed. As a rinsing liquid, a solvent which is miscible with the developer and does not dissolve the resist film is preferred. As such a solvent, alcohols of 3 to 10 carbon atoms, ether compounds of 8 to 12 carbon atoms, alkanes, alkenes, and alkynes of 6 to 12 carbon atoms, and aromatic solvents are preferably used.

Examples of the alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of ether compounds of 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkene of 6 to 12 carbon atoms include hexene, heptene, octene, cyclohexene, methylcyclohexene, dimethylcyclohexene, cycloheptene, and cyclooctene. Examples of the alkyne of 6 to 12 carbon atoms include hexyne, heptyne, and octyne.

Examples of the aromatic solvents include toluene, toluene, ethylbenzene, isopropylbenzene, tert-butylbenzene, and mesitylene.

Rinsing is effective for minimizing the risks of resist pattern collapse and defect formation. However, rinsing is not essential, and if rinsing is omitted, the amount of solvent used can be reduced.

A hole pattern or a trench pattern after development can also be shrunk by thermal flow, RELACS® or DSA process. A hole pattern is shrunk by coating a shrink agent thereto, and baking such that the shrink agent may undergo crosslinking at the surface of the resist film as a result of the acid catalyst diffusing from the resist film during bake, and the shrink agent may attach to the sidewall of the hole pattern. The baking temperature is preferably 70 to 180° C. and more preferably 80 to 170° C., the baking time is preferably 10 to 300 seconds, the extra shrink agent is stripped, and the hole pattern is shrunk.

### EXAMPLES

Hereinafter, the present invention is specifically described with reference to Examples, and Comparative Examples, but the present invention is not limited to the following Examples. The weight average molecular weight (Mw) is a value measured in terms of polystyrene by GPC using THF as a solvent. Monomers M-1 to M-4 having a maleimide group, Monomers ALU-1 to ALU-6 having an acid labile group, and Monomers ADU-1 to ADU-5 having an adhesive group used in the following examples are as follows.

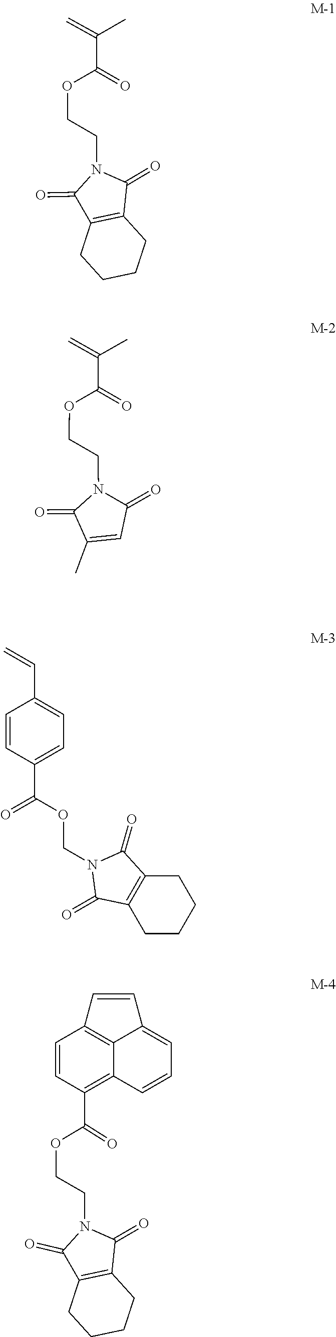 [SMILES: C=C(C)C(=O)OCCN1C(=O)C2=C(CCCC2)C1=O ; C=C(C)C(=O)OCCN1C(=O)C=C(C)C1=O ; C=Cc1ccc(C(=O)OCN2C(=O)C3=C(CCCC3)C2=O)cc1 ; O=C(OCCN1C(=O)C2=C(CCCC2)C1=O)c1ccc2c3c(cccc13)C=C2]

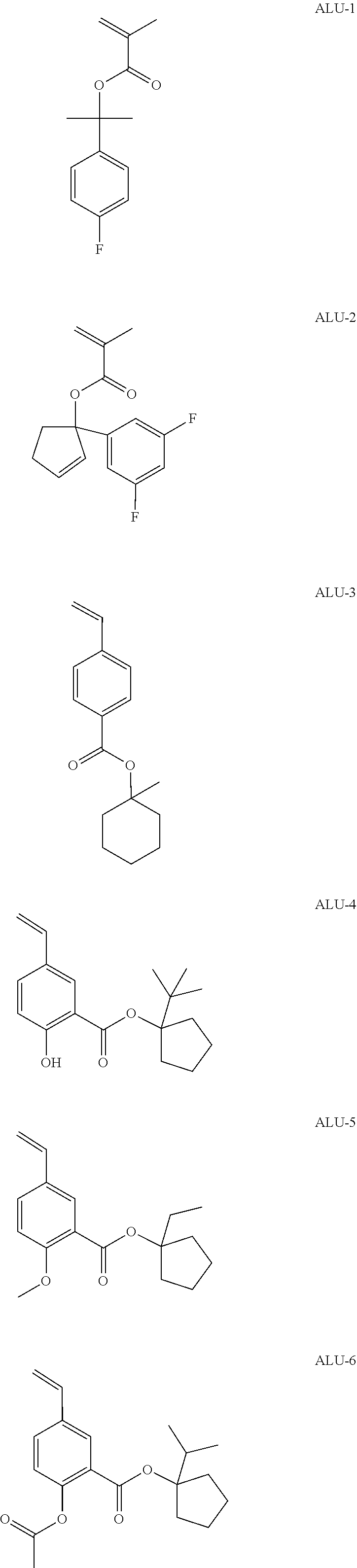 [SMILES: C=C(C)C(=O)OC(C)(C)c1ccc(F)cc1 ; C=C(C)C(=O)OC1(c2cc(F)cc(F)c2)C=CCC1 ; C=Cc1ccc(C(=O)OC2(C)CCCCC2)cc1 ; C=Cc1ccc(O)c(C(=O)OC2(C(C)(C)C)CCCC2)c1 ; C=Cc1ccc(OC)c(C(=O)OC2(CC)CCCC2)c1 ; C=Cc1ccc(OC(C)=O)c(C(=O)OC2(C(C)C)CCCC2)c1]

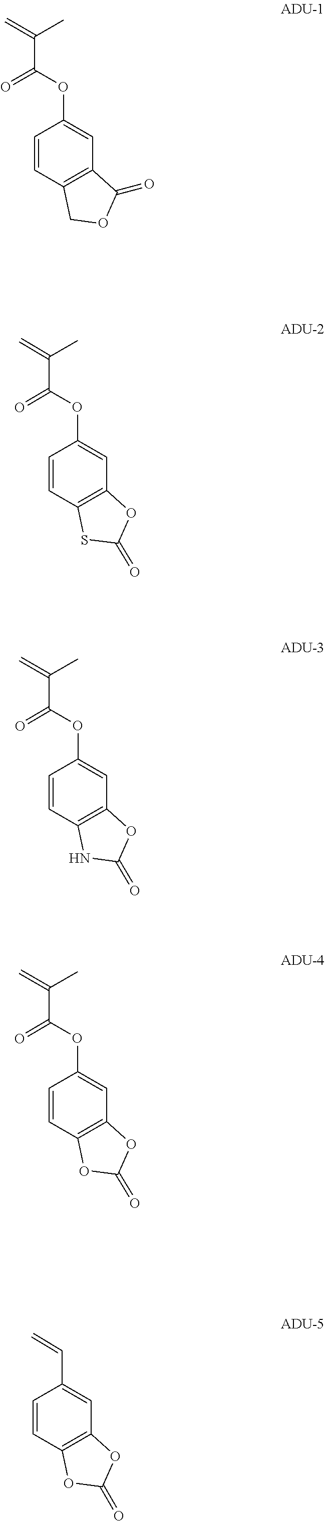 [SMILES: C=C(C)C(=O)Oc1ccc2c(c1)C(=O)OC2 ; C=C(C)C(=O)Oc1ccc2sc(=O)oc2c1 ; C=C(C)C(=O)Oc1ccc2[nH]c(=O)oc2c1 ; C=C(C)C(=O)Oc1ccc2oc(=O)oc2c1 ; C=Cc1ccc2oc(=O)oc2c1]

### [1] Synthesis of Polymer

### [Synthesis Example 1] Synthesis of Polymer P-1

A 2-L flask was charged with 9.8 g of 1-isopropyl-1-cyclopentyl methacrylate, 13.1 g of Monomer M-1, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of azobisisobutyronitrile (AIBN) was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-1. The composition of Polymer P-1 was confirmed by ¹³C-NMR and ¹H-NMR, and Mw and Mw/Mn were confirmed by GPC.

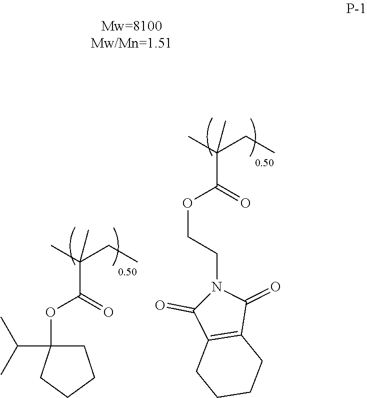

### [Synthesis Example 2] Synthesis of Polymer P-2

A 2-L flask was charged with 4.2 g of 1-methyl-1-cyclopentyl methacrylate, 5.6 g of Monomer ALU-1, 6.6 g of Monomer M-1, 3.0 g of 3-hydroxystyrene, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-2. The composition of Polymer P-2 was confirmed by ¹³C-NMR and ¹H-NMR, and Mw and Mw/Mn were confirmed by GPC.

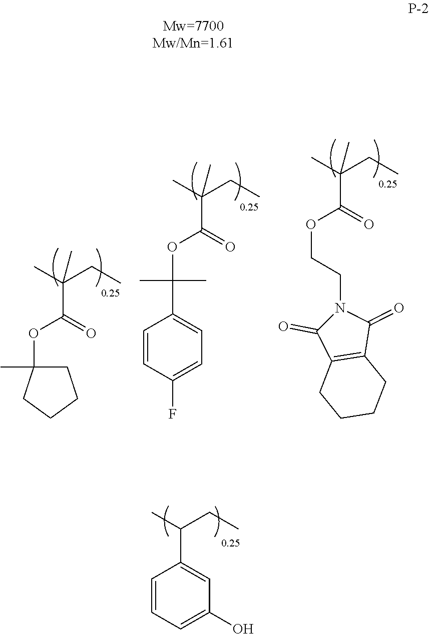

### [Synthesis Example 3] Synthesis of Polymer P-3

A 2-L flask was charged with 4.2 g of 1-methyl-1-cyclopentyl methacrylate, 6.6 g of Monomer ALU-2, 5.6 g of Monomer M-2, 4.3 g of 2-oxooxolan-3-yl methacrylate, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-3. The composition of Polymer P-3 was confirmed by ¹³C-NMR and ¹H-NMR, and Mw and Mw/Mn were confirmed by GPC.

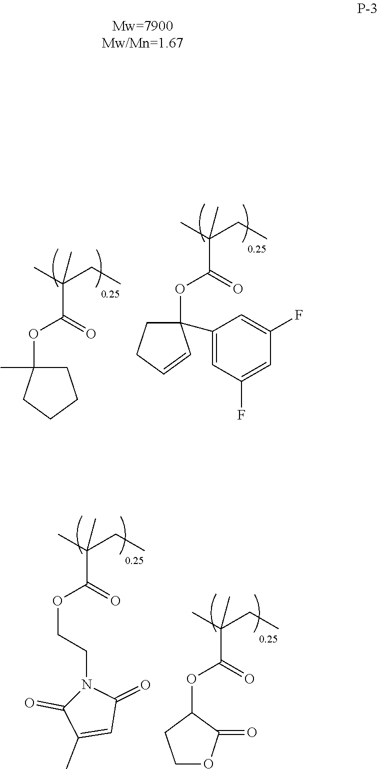

### [Synthesis Example 4] Synthesis of Polymer P-4

A 2-L flask was charged with 12.2 g of Monomer ALU-3, 7.8 g of Monomer M-3, 2.0 g of 3,4-dihydroxystyrene, 1.5 g of acenaphthylene, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-4. The composition of Polymer P-4 was confirmed by ¹³C-NMR and ¹H-NMR, and Mw and Mw/Mn were confirmed by GPC.

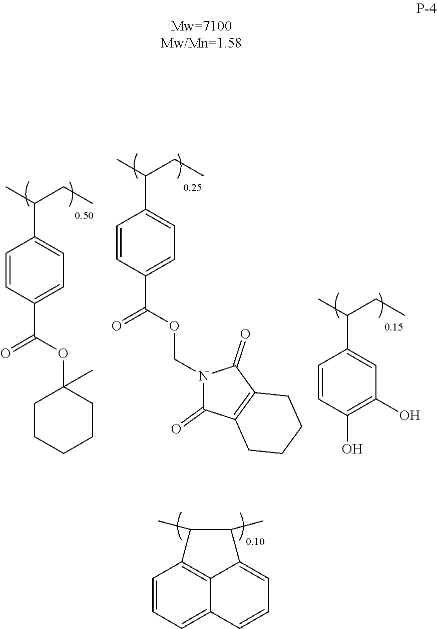

### [Synthesis Example 5] Synthesis of Polymer P-5

A 2-L flask was charged with 4.5 g of 1-ethynyl-1-cyclopentyl methacrylate, 6.6 g of Monomer ALU-2, 6.6 g of Monomer M-1, 5.5 g of Monomer ADU-1, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-5. The composition of Polymer P-5 was confirmed by ¹³C-NMR and ¹H-NMR, and Mw and Mw/Mn were confirmed by GPC.

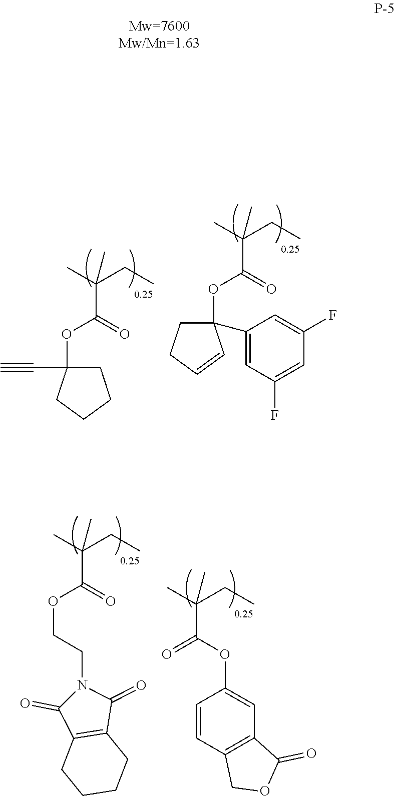

### [Synthesis Example 6] Synthesis of Polymer P-6

A 2-L flask was charged with 4.5 g of 1-ethynyl-1-cyclopentyl methacrylate, 6.6 g of Monomer ALU-2, 6.6 g of Monomer M-1, 5.9 g of Monomer ADU-2, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-6. The composition of Polymer P-6 was confirmed by ¹³C-NMR and ¹H-NMR, and Mw and Mw/Mn were confirmed by GPC.

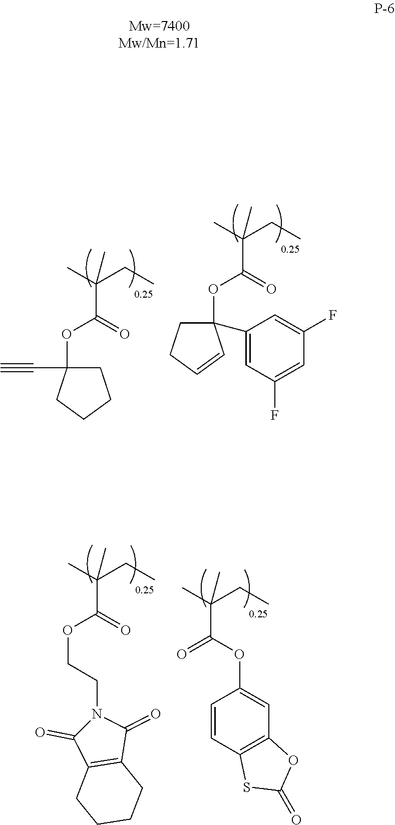

### [Synthesis Example 7] Synthesis of Polymer P-7

A 2-L flask was charged with 4.5 g of 1-ethynyl-1-cyclopentyl methacrylate, 6.6 g of Monomer ALU-2, 6.6 g of Monomer M-1, 9.3 g of 3,5-diiodo-4-hydroxystyrene, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-7. The composition of Polymer P-7 was confirmed by ¹³C-NMR and ¹H-NMR, and Mw and Mw/Mn were confirmed by GPC.

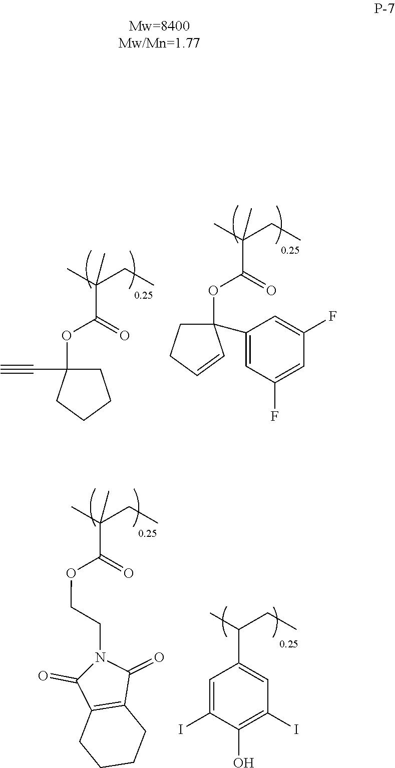

### [Synthesis Example 8] Synthesis of Polymer P-8

A 2-L flask was charged with 12.2 g of Monomer ALU-3, 3.7 g of Monomer M-4, 3.3 g of 3,4-dihydroxystyrene, 1.5 g of acenaphthylene, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-8. The composition of Polymer P-8 was confirmed by ¹³C-NMR and ¹H-NMR, and Mw and Mw/Mn were confirmed by GPC.

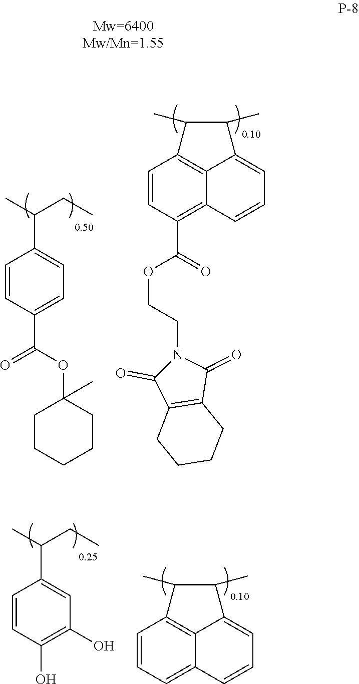

### [Synthesis Example 9] Synthesis of Polymer P-9

A 2-L flask was charged with 7.2 g of Monomer ALU-4, 6.6 g of Monomer ALU-2, 6.6 g of Monomer M-1, 5.5 g of Monomer ADU-3, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-9. The composition of Polymer P-9 was confirmed by ¹³C-NMR and ¹H-NMR, and Mw and Mw/Mn were confirmed by GPC.

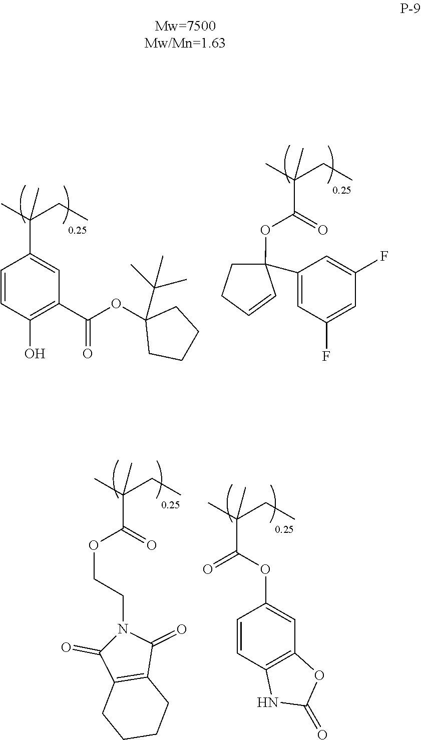

### [Synthesis Example 10] Synthesis of Polymer P-10

A 2-L flask was charged with 6.9 g of Monomer ALU-5, 6.6 g of Monomer ALU-2, 6.6 g of Monomer M-1, 5.5 g of Monomer ADU-4, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-10. The composition of Polymer P-10 was confirmed by ¹³C-NMR and ¹H-NMR, and Mw and Mw/Mn were confirmed by GPC.

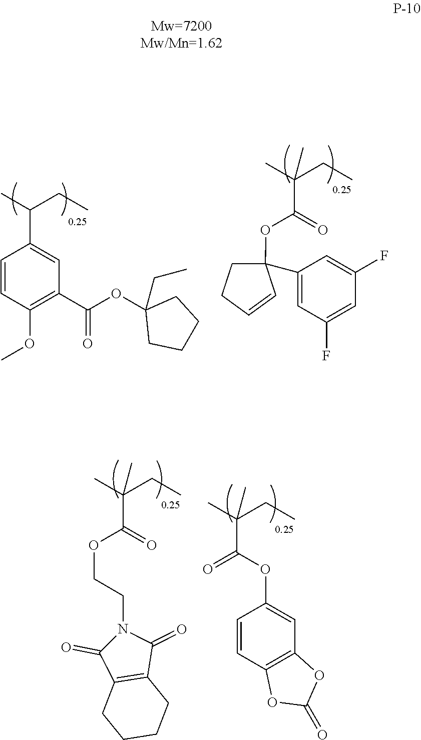

### [Synthesis Example 11] Synthesis of Polymer P-11

A 2-L flask was charged with 7.9 g of Monomer ALU-6, 6.6 g of Monomer ALU-2, 6.6 g of Monomer M-1, 5.2 g of Monomer ADU-5, and 40 g of THF as a solvent. The reactor was cooled at −70° C. in a nitrogen atmosphere, after which vacuum pumping and nitrogen blow were repeated three times. The reactor was warmed up to room temperature, whereupon 1.2 g of AIBN was added as a polymerization initiator, and the reactor was heated at 60° C. and held at the temperature for 15 hours for reaction. The reaction solution was concentrated to 1/2 and added to a mixed solvent of 1 L of methanol and 0.1 L of water, and thus a white solid was precipitated. The resulting white solid was collected by filtration and dried in vacuum at 60° C. to obtain Polymer P-11. The composition of Polymer P-11 was confirmed by ¹³C-NMR and ¹H-NMR, and Mw and Mw/Mn were confirmed by GPC.

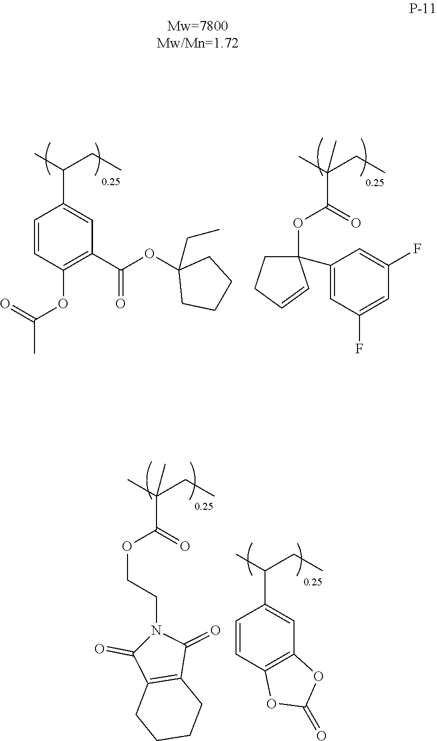

### [Comparative Synthesis Example 1] Comparative Polymer CP-1

Comparative Polymer CP-1 was synthesized by the same procedure as in Synthesis Example 1 except that 2-oxooxolan-3-yl methacrylate was used instead of Monomer M-1. The composition of Comparative Polymer CP-1 was confirmed by ¹³C-NMR and ¹H-NMR, and Mw and Mw/Mn were confirmed by GPC.

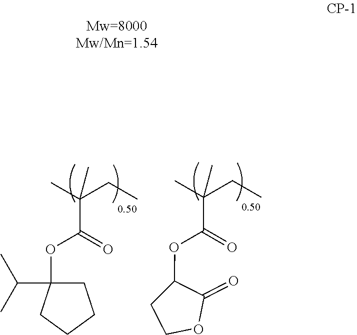

### [2] Preparation of Resist Compositions

### Examples 1 to 16 and Comparative Example 1

A resist composition was prepared by filtering a solution, which was obtained by dissolving each component at a composition shown in Table 1 in a solvent in which 50 ppm of a surfactant PolyFox PF-636 manufactured by OMNOVA Solutions Inc. as a surfactant was dissolved, through a filter having a size of 0.2 μm.

The components in Table 1 are as identified below.

### Organic Solvents:

PGMEA (propylene glycol monomethyl ether acetate)
EL (ethyl lactate)
DAA (diacetone alcohol)

Acid generators: PAG-1 to PAG-4

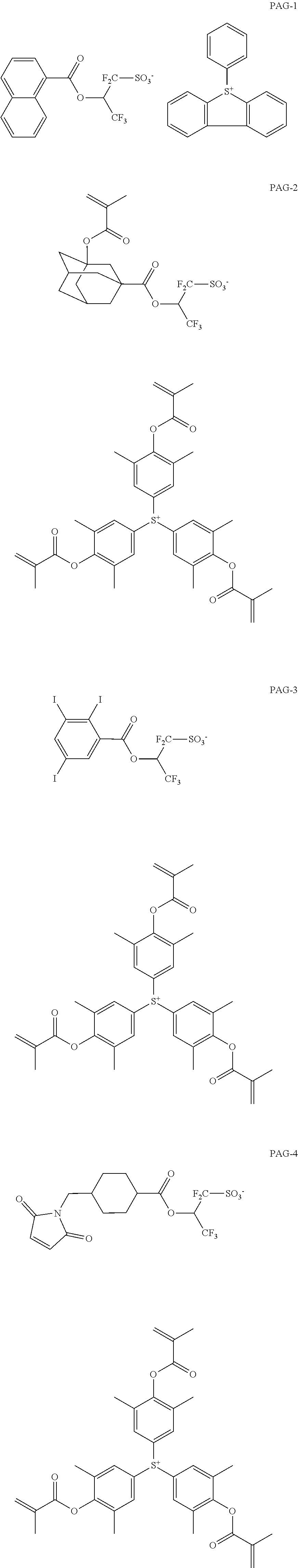

Quenchers: Q-1 to Q-4

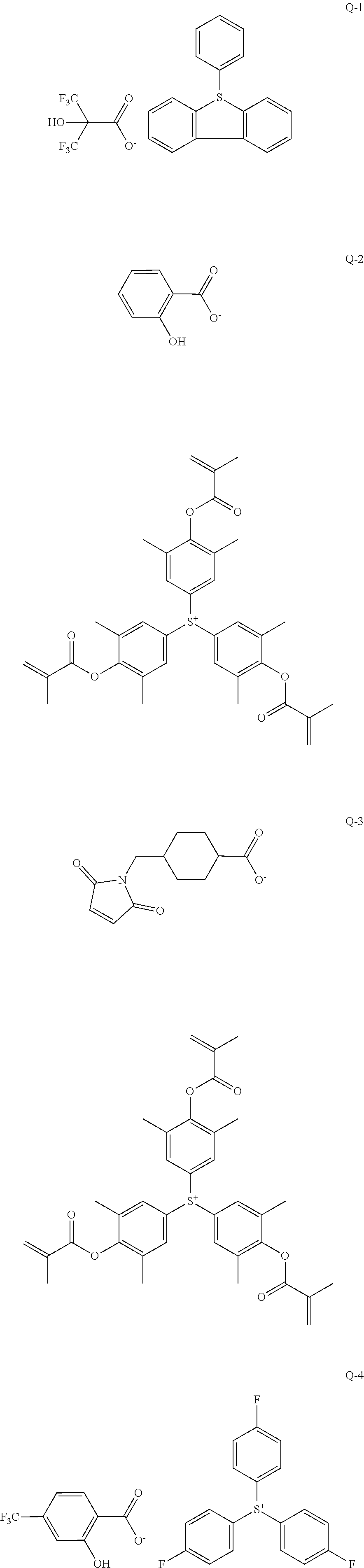

### [3] EB Lithography Test

DUV-42 manufactured by Nissan Chemical Corp. was applied onto a silicon substrate and baked at 200° C. for 60 seconds to form an antireflective coating (film thickness: 60 nm). Each resist composition shown in Table 1 was spin coated on the antireflective coating and prebaked on a hotplate at 105° C. for 60 seconds to prepare a resist film having a film thickness of 40 nm. On the other hand, using an EB lithography system ELS-F125 manufactured by Elionix Co., Ltd., the resist film was exposed imagewise to EB at an accelerating voltage of 125 kV and a current of 50 pA, and the resist film was subjected to PEB on a hotplate at the temperature shown in Table 1 for 60 seconds and then developed in 2-methylbutyl acetate for 30 seconds to form a 1:1 line-and-space negative tone pattern of 30 nm.

The formed pattern was observed using a length measuring SEM (CG5000) manufactured by Hitachi High Technologies Corp., and the exposure dose that provides a 1:1 line-and-space negative tone pattern of 30 nm was regarded as sensitivity to determine edge roughness (LWR). The results are also shown in Table 1.

TABLE 1

| | | | Acid | | | | | |
|---|---|---|---|---|---|---|---|---|
| | | Polymer | generator | Quencher | Organic solvent | PEB | Sensitivity | LER |
| | | (pbw) | (pbw) | (pbw) | (pbw) | (° C.) | (mc/cm²) | (nm) |
| Example | 1 | P-1 | PAG-1 | Q-1 | PGMEA (1500) | 90 | 350 | 3.2 |
| | | (100) | (12.8) | (4.72) | EL (1000) | | | |
| | 2 | P-2 | PAG-1 | Q-1 | PGMEA (1500) | 90 | 320 | 3.4 |
| | | (100) | (12.8) | (4.72) | EL (1000) | | | |
| | 3 | P-3 | PAG-1 | Q-1 | PGMEA (1500) | 80 | 360 | 3.0 |
| | | (100) | (12.8) | (4.72) | EL (1000) | | | |
| | 4 | P-1 (60) | PAG-1 | Q-1 | PGMEA (1500) | 90 | 340 | 3.1 |
| | | P-3 (40) | (12.8) | (4.72) | EL (1000) | | | |
| | 5 | P-4 | PAG-1 | Q-1 | PGMEA (1500) | 95 | 360 | 3.8 |
| | | (100) | (12.8) | (4.72) | EL (1000) | | | |
| | 6 | P-5 | PAG-1 | Q-1 | PGMEA (1500) | 90 | 350 | 3.3 |
| | | (100) | (12.8) | (4.72) | EL (1000) | | | |
| | 7 | P-6 | PAG-1 | Q-1 | PGMEA (1500) | 90 | 360 | 3.4 |
| | | (100) | (12.8) | (4.72) | EL (1000) | | | |
| | 8 | P-7 | PAG-1 | Q-1 | PGMEA (1500) | 90 | 310 | 3.4 |
| | | (100) | (12.8) | (4.72) | EL (1000) | | | |
| | 9 | P-8 | PAG-1 | Q-1 | PGMEA (1500) | 95 | 380 | 3.7 |
| | | (100) | (12.8) | (4.72) | EL (1000) | | | |
| | 10 | P-9 | PAG-1 | Q-1 | PGMEA (1500) | 90 | 320 | 3.5 |
| | | (100) | (12.8) | (4.72) | EL (1000) | | | |
| | 11 | P-10 | PAG-1 | Q-1 | PGMEA (1500) | 90 | 360 | 3.4 |
| | | (100) | (12.8) | (4.72) | EL (1000) | | | |
| | 12 | P-11 | PAG-1 | Q-1 | PGMEA (1500) | 90 | 370 | 3.3 |
| | | (100) | (12.8) | (4.72) | EL (1000) | | | |
| | 13 | P-2 | PAG-2 | Q-2 | PGMEA (1500) | 90 | 280 | 3.1 |
| | | (100) | (21.5) | (7.36) | EL (1000) | | | |
| | 14 | P-2 | PAG-3 | Q-2 | PGMEA (2000) | 90 | 260 | 3.1 |
| | | (100) | (26.2) | (7.36) | DAA (500) | | | |
| | 15 | P-2 | PAG-4 | Q-3 | PGMEA (1500) | 90 | 270 | 3.3 |
| | | (100) | (21.0) | (8.36) | EL (1000) | | | |
| | 16 | P-2 | PAG-2 | Q-4 | PGMEA (1500) | 90 | 280 | 3.3 |
| | | (100) | (21.5) | (5.22) | EL (1000) | | | |
| Comparative | 1 | CP-1 | PAG-1 | Q-1 | PGMEA (1500) | 90 | 410 | 4.2 |
| Example | | (100) | (12.8) | (4.72) | EL (1000) | | | |

From the results shown in Table 1, it was found that the resist composition of the present invention exhibited reduced LER.

Japanese Patent Application Nos. 2023-046978 and 2023-174063 are incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a base polymer containing a polymer including a repeat unit having a carboxy group substituted with an acid labile group and a repeat unit having a maleimide group in a side chain.

2. The resist composition according to claim 1, wherein the repeat unit having the carboxy group substituted with the acid labile group has the following formula (a1), and the repeat unit having the maleimide group in the side chain has the following formula (b): 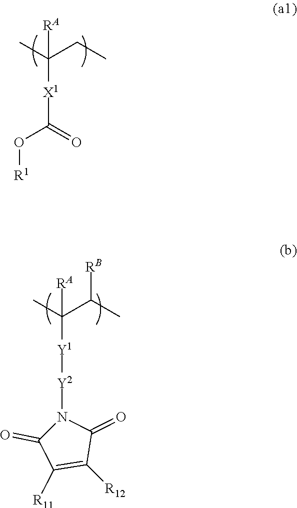
wherein R^{A} is each independently a hydrogen atom or a methyl group,
R^{B} is a hydrogen atom or a group that bonds together with Y¹ to form a C₈-C₁₄ ring with the carbon atom to which they are attached,
X¹ is a single bond, a phenylene group, a naphthylene group, or a C₁-C₁₆ linking group which contains at least one selected from an ester bond, an ether bond, and a lactone ring, the phenylene group, the naphthylene group, and the linking group may have at least one selected from a hydroxy group, a C₁-C₈ saturated hydrocarbyloxy group, and a C₂-C₈ saturated hydrocarbylcarbonyloxy group,
Y¹ is a single bond, a phenylene group, a naphthylene group, an ester bond, or an ether bond,
Y² is a single bond or a C₁-C₁₂ saturated hydrocarbylene group, the saturated hydrocarbylene group may have at least one selected from an ester bond, an amide bond, an ether bond, a lactone ring, and a urethane bond,
R¹ is an acid labile group,
R¹¹ and R¹² are each independently a hydrogen atom or a C₁-C₁₀ saturated hydrocarbyl group, the saturated hydrocarbyl group may contain an ether bond or a sulfide bond, and R¹¹ and R¹² may bond together to form a ring with the carbon atom to which they are attached.

3. The resist composition according to claim 1, further comprising an organic solvent.

4. The resist composition according to claim 1, further comprising an acid generator.

5. The resist composition according to claim 1, further comprising a quencher.

6. The resist composition according to claim 1, further comprising a surfactant.

7. A pattern forming process comprising the steps of: applying the resist composition according to claim 1 onto a substrate to form a resist film on the substrate; exposing the resist film to high-energy radiation; and developing the exposed resist film in an organic solvent developer.

8. The pattern forming process according to claim 7, wherein the organic solvent developer comprises one or more selected from 2-octanone, 2-nonanone, 2-heptanone, 3-heptanone, 4-heptanone, 2-hexanone, 3-hexanone, diisobutyl ketone, methylcyclohexanone,
acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate.

9. The pattern forming process according to claim 7, wherein the substrate is a photomask blank.

10. The pattern forming process according to claim 7, wherein the high-energy radiation is i-rays, ArF excimer laser light having a wavelength of 193 nm, KrF excimer laser light having a wavelength of 248 nm, an electron beam, or extreme ultraviolet having a wavelength of 3 to 15 nm.
